(19) United States
(12) Patent Application Publication
(10) Pub. No.: US 2026/0271289 A1
(43) Pub. Date: Sep. 10, 2026

(54) MEMORY DEVICE

(71) Applicant: Kioxia Corporation, Tokyo (JP)

(72) Inventors: Sota MATSUMOTO, Yokkaichi (JP); Emiko ADACHI, Yokkaichi (JP)

(73) Assignee: Kioxia Corporation, Tokyo (JP)

(21) Appl. No.: 19/239,161

(22) Filed: Jun. 16, 2025

(30) Foreign Application Priority Data
Mar. 10, 2025 (JP) 2025-037748

(51) Int. Cl. H10B 43/27; H10B 43/10

(52) U.S. Cl. CPC H10B 43/27; H10B 43/10

(57) ABSTRACT

A memory device according to one embodiment includes conductive layers, a memory pillar, contact plugs, and pillars. The conductive layers are arranged over first and second tiers. The contact plugs are respectively connected to the conductive layers. Each of the pillars is provided to pass through one or more conductive layers of the conductive layers. Each of the pillars includes first and second sub-pillars. The first sub-pillar has a portion that passes through the first tier. The second sub-pillar has a portion that passes through the second tier. The pillars include first and second pillars. A position of a boundary between the first sub-pillar and the second sub-pillar in the first pillar substantially coincides with a first boundary between the first tier and the second tier. A position of a boundary between the first sub-pillar and the second sub-pillar in the second pillar is separated from the first boundary.

### CROSS-REFERENCE TO RELATED APPLICATION

This application is based upon and claims the benefit of priority from Japanese Patent Application No. 2025-037748, filed Mar. 10, 2025, the entire contents of which are incorporated herein by reference.

### FIELD

Embodiments described herein relate generally to a memory device.

### BACKGROUND

A NAND flash memory capable of storing data in a nonvolatile manner is known.

### BRIEF DESCRIPTION OF DRAWINGS

FIG. 1 is a block diagram showing an example of an overall configuration of a memory system including a memory device according to a first embodiment.

FIG. 2 is a circuit diagram showing an example of a circuit configuration of a memory cell array included in the memory device according to the first embodiment.

FIG. 3 is a plan view showing an example of a planar layout of the memory cell array included in the memory device according to the first embodiment.

FIG. 4 is a cross-sectional view showing an example of a cross-sectional structure of the memory area of the memory cell array included in the memory device according to the first embodiment.

FIG. 5 is a cross-sectional view showing an example of a cross-sectional structure of a memory pillar included in the memory device according to the first embodiment.

FIG. 6 is a cross-sectional view showing an example of a cross-sectional structure of the contact area of the memory cell array included in the memory device according to the first embodiment.

FIG. 7 is a cross-sectional view showing an example of a cross-sectional structure of a contact plug included in the memory device according to the first embodiment.

FIG. 8 is a cross-sectional view showing an example of a cross-sectional structure of a contact plug included in the memory device according to the first embodiment.

FIG. 9 is a cross-sectional view showing an example of a cross-sectional structure of a support pillar included in the memory device according to the first embodiment.

FIG. 10 is a diagram showing an example of a relationship between a memory pillar and a member in the memory device according to the first embodiment.

FIG. 11 is a flowchart showing an example of a method of manufacturing the memory device according to the first embodiment.

FIGS. 12, 13, 14, 15, 16, 17, 18, 19, 20, 21, 22, 23, 24, 25, and 26 are cross-sectional views showing examples of cross-sectional structures in the manufacturing process of the memory device according to the first embodiment.

FIG. 27 is a cross-sectional view showing an example of a cross-sectional structure in the vicinity of a boundary of a layer stack in a process of manufacturing a memory device according to a first comparative example.

FIG. 28 is a cross-sectional view showing an example of a cross-sectional structure in the vicinity of a boundary of a layer stack in a process of manufacturing the memory device according to the first embodiment.

FIG. 29 is a cross-sectional view showing an example of a cross-sectional structure of the contact area of the memory cell array included in the memory device according to a modification of the first embodiment.

FIG. 30 is a cross-sectional view showing an example of a cross-sectional structure of the contact area of the memory cell array included in the memory device according to a second embodiment.

FIG. 31 is a cross-sectional view showing an example of a cross-sectional structure of a support pillar included in the memory device according to the second embodiment.

FIG. 32 is a flowchart showing an example of a method of manufacturing the memory device according to the second embodiment.

FIGS. 33, 34, 35, 36, 37, 38, and 39 are cross-sectional views showing examples of cross-sectional structures in the manufacturing process of the memory device according to the second embodiment.

FIG. 40 is a cross-sectional view showing an example of a cross-sectional structure of the memory area of the memory cell array included in the memory device according to a third embodiment.

FIG. 41 is a cross-sectional view showing an example of a cross-sectional structure of the contact area of the memory cell array included in the memory device according to the third embodiment.

FIG. 42 is a flowchart showing an example of a method of manufacturing the memory device according to the third embodiment.

FIGS. 43, 44, 45, 46, 47, 48, and 49 are cross-sectional views showing examples of cross-sectional structures in the manufacturing process of the memory device according to the third embodiment.

FIG. 50 is a cross-sectional view showing an example of a cross-sectional structure of the contact area of the memory cell array included in the memory device according to a fourth embodiment.

FIG. 51 is a flowchart showing an example of a method of manufacturing the memory device according to the fourth embodiment.

FIGS. 52, 53, 54, 55, 56, 57, 58, and 59 are cross-sectional views showing examples of cross-sectional structures in the manufacturing process of the memory device according to the fourth embodiment.

FIG. 60 is a cross-sectional view showing an example of a cross-sectional structure of the contact area of the memory cell array included in the memory device according to a fifth embodiment.

FIG. 61 is a flowchart showing an example of a method of manufacturing the memory device according to the fifth embodiment.

FIGS. 62, 63, 64, 65, 66, 67, 68, and 69 are cross-sectional views showing examples of cross-sectional structures in the manufacturing process of the memory device according to the fifth embodiment.

FIG. 70 is a cross-sectional view showing an example of a cross-sectional structure in the vicinity of a boundary of a layer stack in a process of manufacturing a memory device according to a second comparative example.

FIG. 71 is a cross-sectional view showing an example of a cross-sectional structure in the vicinity of a boundary of a layer stack in a process of manufacturing the memory device according to the fifth embodiment.

FIG. 72 is a cross-sectional view showing an example of a cross-sectional structure of the contact area of the memory cell array included in the memory device according to a sixth embodiment.

FIG. 73 is a flowchart showing an example of a method of manufacturing the memory device according to the sixth embodiment.

FIGS. 74, 75, 76, 77, 78, 79, 80, 81, 82, 83, and 84 are cross-sectional views showing examples of cross-sectional structures in the manufacturing process of the memory device according to the sixth embodiment.

FIG. 85 is a cross-sectional view showing an example of a cross-sectional structure of the contact area of the memory cell array included in the memory device according to a first modification of the sixth embodiment.

FIG. 86 is a cross-sectional view showing an example of a cross-sectional structure of the contact area of the memory cell array included in the memory device according to a second modification of the sixth embodiment.

FIG. 87 is a cross-sectional view showing an example of a cross-sectional structure in the vicinity of a boundary of a layer stack in the memory device according to the first embodiment.

FIG. 88 is a cross-sectional view showing an example of a cross-sectional structure in the vicinity of a boundary of a layer stack in the memory device according to the third embodiment.

### DETAILED DESCRIPTION

In general, according to one embodiment, a memory device includes a plurality of conductive layers, a memory pillar, a plurality of contact plugs, and a plurality of pillars. The conductive layers are provided in a first region and a second region arranged in a first direction. The conductive layers are provided apart from each other in a second direction intersecting the first direction in the first region and the second region, and arranged over a plurality of tiers including a first tier and a second tier. The memory pillar is provided to pass through the conductive layers in the second direction in the first region, in which a portion where the memory pillar and one of the conductive layers intersect each other functions as a memory cell. The contact plugs are respectively connected to the conductive layers in the second region. Each of the pillars is provided to pass through one or more conductive layers of the conductive layers in the second direction in the second region. Each of the pillars includes a first sub-pillar and a second sub-pillar. The first sub-pillar has a portion that passes through the first tier. The second sub-pillar has a portion that passes through the second tier. The pillars include a first pillar and a second pillar. A position of a boundary between the first sub-pillar and the second sub-pillar in the first pillar substantially coincides with a first boundary between the first tier and the second tier. A position of a boundary between the first sub-pillar and the second sub-pillar in the second pillar is separated from the first boundary.

Hereinbelow, embodiments are described with reference to the drawings. Each embodiment gives examples of a device and a method for embodying the technical idea of the invention. The drawings are schematic or conceptual ones. The dimensions, ratios, etc. of drawings are not necessarily the same as the actual ones. The illustration of the configuration is omitted as appropriate. The hatching added to the plan view is not necessarily related to the material or characteristics of the component. In the present specification, components having substantially the same function and configuration are marked with the same reference signs. The numerals, characters, etc. added to reference signs are referred to by the same reference signs, and are used to distinguish between similar elements.

### <1> First Embodiment

A memory device 1 according to the first embodiment is a type of three-dimensional stacked NAND flash memory having a structure in which memory cell transistors MT are three-dimensionally stacked on a semiconductor substrate. Hereinafter, details of the memory device 1 according to the first embodiment will now be described.

### <1-1> Configuration

First, a configuration of the memory device 1 according to the first embodiment is described.

### <1-1-1> Overall Configuration of the Memory Device 1

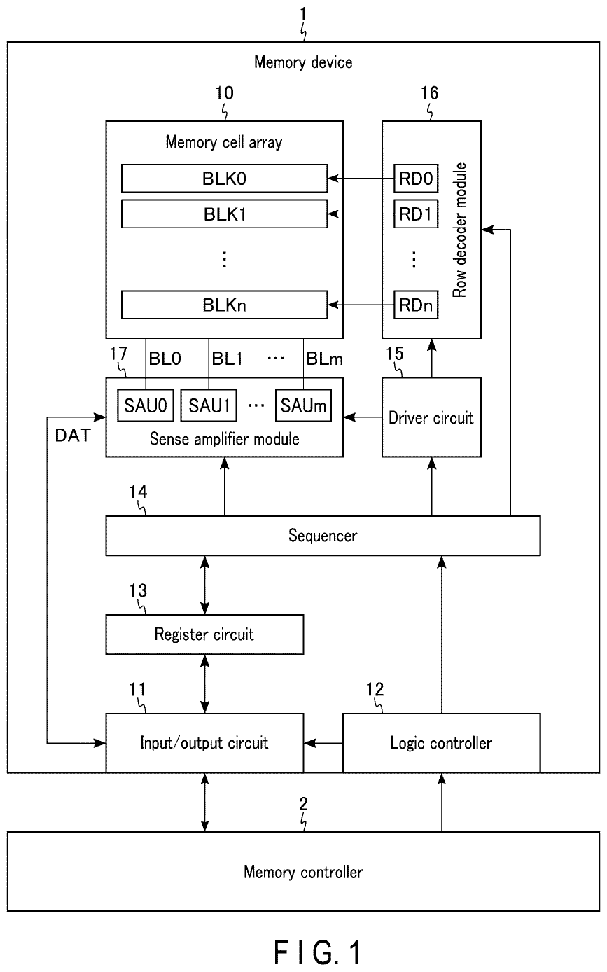

FIG. 1 is a block diagram showing an example of an overall configuration of a memory system including the memory device 1 according to the first embodiment. As shown in FIG. 1, the memory device 1 is controlled by a memory controller 2 in the outside. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or more). The block BLK is a set of a plurality of memory cells. The block BLK corresponds to, for example, a unit of data erasure. The block BLK includes a plurality of pages. The page corresponds to a unit in which reads and writes of data are executed. Although illustration is omitted, the memory cell array 10 is provided with a plurality of bit lines BL0 to BLm (“m” is an integer of 1 or more) and a plurality of word lines WL. Each memory cell is associated with, for example, one bit line BL and one word line WL.

The input/output circuit 11 is an interface circuit that takes charge of transmission and reception of input/output signals with the memory controller 2. The input/output signal includes, for example, data DAT, status information, address information, a command, etc. The input/output circuit 11 can input and output data DAT between the sense amplifier module 17 and the memory controller 2. The input/output circuit 11 can output, to the memory controller 2, status information transferred from the register circuit 13. The input/output circuit 11 can output, to the register circuit 13, each of address information and a command transferred from the memory controller 2.

The logic controller 12 controls each of the input/output circuit 11 and the sequencer 14 based on a control signal inputted from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 orders the input/output circuit 11 to input or output an input/output signal.

The register circuit 13 temporarily stores status information, address information, and a command. The status information is updated based on the control of the sequencer 14, and is transferred to the input/output circuit 11. The address information includes a block address, a page address, a column address, and the like. The command includes orders regarding various operations of the memory device 1.

The sequencer 14 controls the entire operation of the memory device 1. The sequencer 14 executes a read operation, a write operation, an erase operation, or the like based on a command and address information stored in the register circuit 13.

The driver circuit 15 generates voltage used in a read operation, a write operation, an erase operation, or the like. Then, the driver circuit 15 supplies the generated voltage to the row decoder module 16, the sense amplifier module 17, or the like.

The row decoder module 16 is a circuit used to select a block BLK to be operated and transfer voltage to a wiring line such as a word line WL. The row decoder module 16 includes a plurality of row decoders RD0 to RDn. The row decoders RD0 to RDn are associated with the blocks BLK0 to BLKn, respectively, and are used to select the block BLK. Each row decoder RD transfers voltage generated by the driver circuit 15 to various wiring lines provided in the memory cell array 10.

The sense amplifier module 17 is a circuit used to transfer voltage to each bit line BL and read data. The sense amplifier module 17 includes a plurality of sense amplifier units SAU0 to SAUm. The sense amplifier units SAU0 to SAUm are associated with the bit lines BL0 to BLm, respectively. Each sense amplifier unit SAU includes a sense amplifier capable of determining data based on the voltage of the associated bit line BL, a latch circuit that temporarily holds data, etc.

A combination of the memory device 1 and the memory controller 2 may constitute one semiconductor device. Examples of such a semiconductor device include a memory card such as an SD™ card, an SSD (solid-state drive), and the like. The memory device 1 may include a plurality of memory cell arrays 10. The memory device 1 may include a row decoder module 16 and a sense amplifier module 17 for each memory cell array 10. A set of the memory cell array 10, the row decoder module 16, and the sense amplifier module 17 is referred to as, for example, a “plane”. That is, the memory device 1 may include a plurality of planes.

### <1-1-2> Circuit Configuration of the Memory Cell Array 10

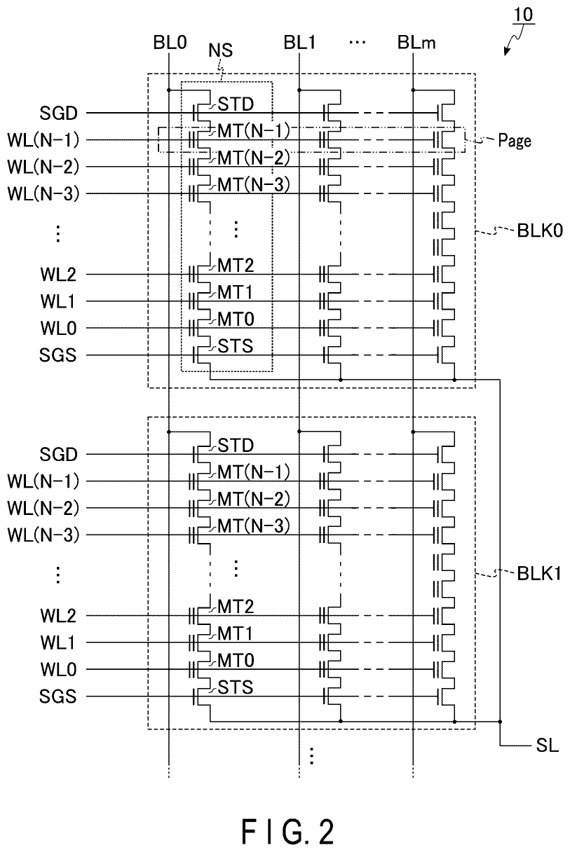

FIG. 2 is a circuit diagram showing an example of a circuit configuration of the memory cell array 10 included in the memory device 1 according to the first embodiment. FIG. 2 shows two blocks BLK0 and BLK1 among the blocks BLK included in the memory cell array 10. As shown in FIG. 2, in the memory cell array 10, select gate lines SGD and SGS and word lines WL0 to WL(N−1) (N is an integer of 2 or more) are provided for each block BLK. Bit lines BL0 to BLm and a source line SL are shared by, for example, a plurality of blocks BLK.

Each block BLK includes a plurality of NAND strings NS. The NAND strings NS are individually associated with the bit lines BL0 to BLm. Each NAND string NS is connected between the associated bit line BL and the source line SL. Each NAND string NS includes, for example, N memory cell transistors MT0 to MT(N−1) and select transistors STD and STS. Each memory cell transistor MT is a memory cell including a control gate and a charge storage layer, and holds (stores) data in a nonvolatile manner. Each of the select transistors STD and STS is used to select the block BLK.

In each NAND string NS, the select transistor STD, the memory cell transistors MT(N−1) to MT0, and the select transistor STS are connected in series in this order. Specifically, the drain end and the source end of the select transistor STD are connected to the associated bit line BL and the drain end of the memory cell transistor MT(N−1), respectively. The drain end and the source end of the select transistor STS are connected to the source end of the memory cell transistor MT0 and the source line SL, respectively.

Each select gate line SGD is connected to the gate end of each of the select transistors STD included in the associated block BLK. The select gate line SGS is connected to the gate end of each of the select transistors STS included in the associated block BLK. The word lines WL0 to WL(N−1) are connected to the control gate ends of the memory cell transistors MT0 to MT(N−1) included in the associated block BLK, respectively.

The “page” corresponds to a set of memory cell transistors MT connected to a common word line WL in the same block BLK. The set of memory cell transistors MT connected to a common word line WL in the same block BLK can have a storage capacity of two-page data or more according to the number of bits stored in the memory cell transistors MT.

The circuit configuration of the memory cell array 10 may be another circuit configuration. For example, a plurality of independently controllable select gate lines SGD may be provided in each block BLK. In this case, each block BLK is configured such that selection can be performed in units of a plurality of units individually associated with the select gate lines SGD.

In the following, for the memory device 1 according to the first embodiment, a case where each NAND string NS includes ten memory cell transistors MT0 to MT9 connected to ten word lines WL0 to WL9, respectively, (that is, a case where N=10) is described as an example.

### <1-1-3> Structure of the Memory Device 1

A structure of the memory device 1 according to the first embodiment will now be described.

In the drawings referred to below, a three-dimensional orthogonal coordinate system is used. The X direction corresponds to the extending direction of the word line WL, for example. The Y direction corresponds to the extending direction of the bit line BL, for example. The Z direction corresponds to a vertical direction with respect to a substrate of the memory device 1. The “up and down” is defined based on a direction along the Z direction. The up direction corresponds to a direction away from the reference configuration (for example, source line SL). The down direction corresponds to a direction approaching to the reference configuration (for example, source line SL). The XY plane (cross section) corresponds to a plane (cross section) parallel to each of the X direction and the Y direction. The YZ cross section corresponds to a cross section parallel to each of the Y direction and the Z direction. The XZ cross section corresponds to a cross section parallel to each of the X direction and the Z direction. The “XY cross-sectional area” corresponds to a cross-sectional area of the object in the XY cross section.

In the memory device 1, the memory cell array 10 includes a plurality of wiring layers (for example, word lines WL0 to WL9 and select gate lines SGD and SGS) stacked apart from each other in the Z direction. Hereinafter, a plurality of wiring layers (conductive layers) stacked apart from each other in the Z direction is also referred to as “stacked wiring lines”. As a method of forming the stacked wiring lines, a method of forming a structure corresponding to each wiring layer with a sacrificial member, removing the sacrificial member to form a void, and filling the void with a conductive material is known. Hereinafter, a method of forming the stacked wiring lines by replacing the sacrificial member with the conductive material in this manner is referred to as “WL replacement”.

### (1: Planar Layout of the Memory Cell Array 10)

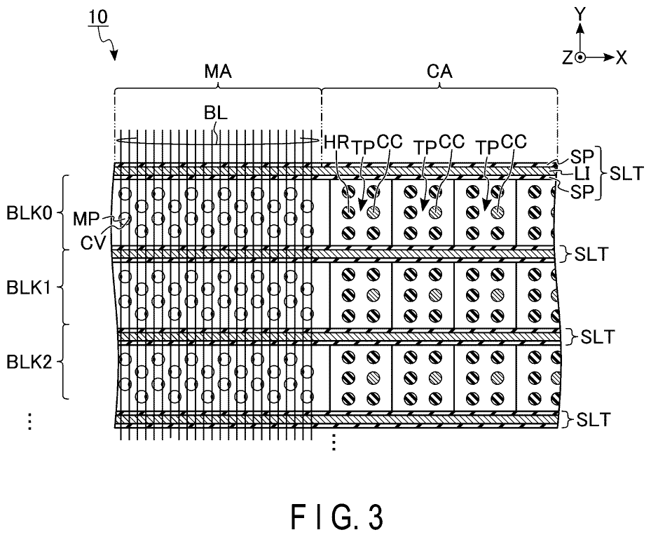

FIG. 3 is a plan view showing an example of a planar layout of the memory cell array 10 included in the memory device 1 according to the first embodiment. As shown in FIG. 3, the memory cell array 10 includes, for example, a plurality of members SLT. Further, the memory cell array 10 includes a memory area MA and a contact area CA arranged in the X direction.

Each of the members SLT has a portion provided to extend along the X direction. Each of the members SLT crosses the memory area MA and the contact area CA along the X direction. The members SLT are arranged in the Y direction. Each of the members SLT divides the stacked wiring lines for each block BLK. That is, in the memory cell array 10, each of the areas partitioned along the Y direction by the slits SLT corresponds to one block BLK. Each of the members SLT includes, for example, a conductive member LI and a spacer SP. The spacer SP is an insulator provided on a side surface of the conductive member LI, and separates the conductive member LI from the stacked wiring lines. The conductive member LI is insulated from the stacked wiring lines by the spacer SP and functions as a part of the source line SL. Each of the members SLT may contain an insulator wholly.

The memory area MA is used to store data and includes a plurality of memory pillars MP and a plurality of contact plugs CV. Each memory pillar MP is, for example, a substantially cylindrical member functioning as one NAND string NS. A plurality of memory pillars MP are arranged, for example, in a lattice configuration for each block BLK. At least one bit line BL is placed to overlap with each memory pillar MP. Then, one bit line BL is electrically connected to each memory pillar MP via the contact plug CV. Each contact plug CV includes a substantially cylindrical conductor provided to extend in the Z direction. The bit lines BL each have a portion provided to extend in the Y direction, and are arranged in the X direction. In the present example, two bit lines BL are arranged to overlap with one memory pillar MP.

The contact area CA is used for connection between the stacked wiring lines provided for each block BLK and the row decoder module 16. In the contact area CA, each wiring layer (conductive layer) included in the stacked wiring lines has a terrace portion TP. The terrace portion TP corresponds to a portion of the wiring layer that does not overlap with the upper wiring layer in a tier of a staircase structure of stacked wiring lines described later. In the contact area CA, for example, a plurality of terrace portions TP corresponding to the select gate line SGD, the word lines WL9 to WL0, and the select gate line SGS are arranged in order from the memory area MA toward the end in the X direction (right side in the drawing). In this manner, the terrace portions TP of the plurality of wiring layers included in the stacked wiring lines can be provided in a staircase shape of a single row. The terrace portions TP of the wiring layers included in the stacked wiring lines may be provided in a staircase shape of two or more rows. In addition, two terrace portions TP adjacent to each other in plan view do not necessarily need to be associated with two wiring layers adjacent to each other in the Z direction.

In addition, the contact area CA includes a plurality of contact plugs CC and a plurality of support pillars HR for each block BLK. Each contact plug CC includes a substantially cylindrical conductor provided to extend in the Z direction. Each contact plug CC is electrically connected to the terrace portion TP of any one wiring layer of the stacked wiring lines, and is not electrically connected to the other wiring layers. The plurality of contact plugs CC of each block BLK are arranged in a line in the X direction in the contact area CA, for example. Each support pillar HR includes a substantially cylindrical insulator provided to extend in the Z direction. Each support pillar HR is used as a pillar that supports a stacked structure having a void in the WL replacement. Each support pillar HR is appropriately arranged in a portion not overlapping the contact plug CC in the contact area CA.

In the memory cell array 10, the number and arrangement of the memory pillars MP can be freely designed. Associated memory pillars MP and bit lines BL may be connected via two or more contact plugs. The number and arrangement of the contact plugs CC of each block BLK can be freely designed. The number of contact plugs CC connected to the terrace portion TP of each wiring layer may be one or more. The plurality of contact plugs CC of each block BLK may be arranged in a lattice pattern in the contact area CA. The number and arrangement of the support pillars HR of each block BLK can be freely designed. The memory cell array 10 may include two contact areas CA arranged so as to sandwich the memory area MA in the X direction. The contact areas CA may be arranged so as to divide the memory area MA in the X direction.

### (2: Cross-Sectional Structure of Memory Area MA)

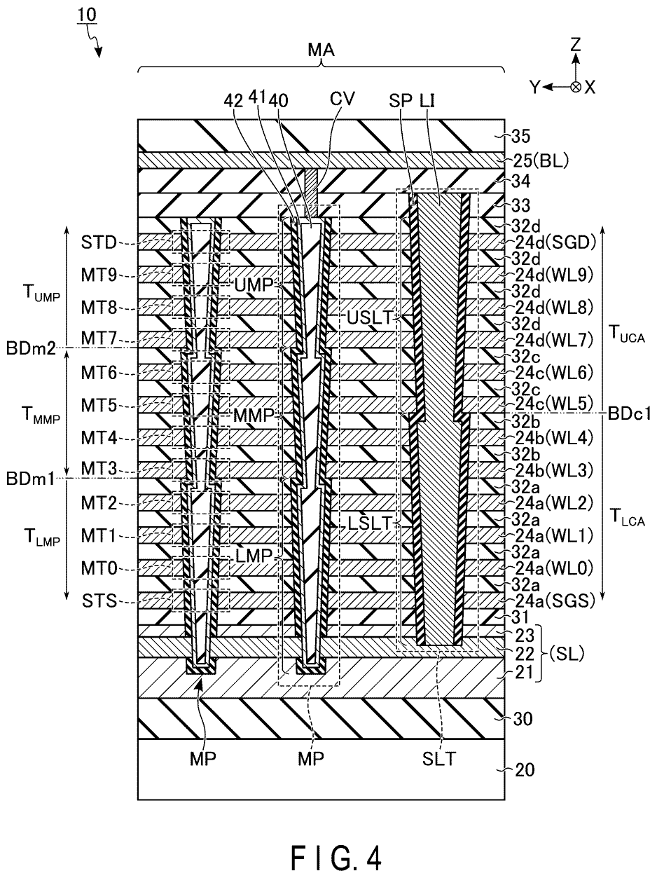

FIG. 4 is a cross-sectional view showing an example of a cross-sectional structure of the memory area MA of the memory cell array 10 included in the memory device 1 according to the first embodiment. FIG. 4 shows a YZ cross section including two memory pillars MP and one member SLT in the memory area MA of the memory cell array 10. As shown in FIG. 4, the memory cell array 10 includes, for example, a substrate 20, semiconductor layers 21 to 23, conductive layers 24 to 25, and insulating layers 30 to 35.

The substrate 20 is, for example, a silicon substrate. An insulating layer 30 is provided on the substrate 20. The insulating layer 30 contains, for example, silicon oxide (silicon and oxygen). Circuits such as the row decoder module 16 and the sense amplifier module 17 may be provided in the area where the insulating layer 30 is provided. In a case where the memory device 1 has a structure in which a chip provided with the memory cell array 10 and a chip provided with circuits and the like other than the memory cell array 10 are bonded to each other, the substrate 20 provided under the insulating layer 30 may be discarded.

The semiconductor layers 21, 22, and 23 are stacked in this order on the insulating layer 31. A set of semiconductor layers 21, 22, and 23 functions as the source line SL. Each of the semiconductor layers 21, 22, and 23 contains, for example, silicon. In addition, each of the semiconductor layers 21, 22, and 23 contains, for example, phosphorus (P) as an impurity of an n-type semiconductor. The semiconductor layer 22 is formed, for example, by replacing a sacrificial member provided between the semiconductor layers 21 and 23 with a semiconductor material. Hereinafter, a method of forming the semiconductor layer 22 by replacing the sacrificial member with the semiconductor material in this manner is referred to as “SL replacement”. Although not shown, the semiconductor layers 21 and 23 are provided from the memory area MA to the contact area CA. Then, in the present example, the semiconductor layer 22 is provided in the memory area MA and is not provided in the contact area CA. Depending on the structure of the memory cell array 10, the semiconductor layer 22 may be provided in the contact area CA.

The insulating layer 31 is provided on the semiconductor layer 23. The insulating layer 31 contains, for example, silicon oxide. On the insulating layer 31, for example, the conductive layer 24 of twelve layers (wiring layers) and the insulating layer 32 of twelve layers are alternately stacked one by one. The conductive layer 24 is, for example, formed in a plate shape spreading along the XY plane. The conductive layer 24 includes, for example, a stacked structure of titanium nitride (TiN)/tungsten (W) as a conductive material. In this case, titanium nitride (nitrogen and titanium) is formed so as to cover tungsten. Titanium nitride included in the conductive layer 24 has a function as a barrier layer for suppressing oxidation of tungsten or an adhesion layer for improving adhesion of tungsten when tungsten is formed by, for example, chemical vapor deposition (CVD). In addition, the conductive layer 24 may contain a high dielectric constant material such as aluminum oxide (oxygen and aluminum). In this case, the high dielectric constant material is formed so as to cover the conductive material of the conductive layer 24. For example, in the conductive layer 24, the high dielectric constant material is provided so as to be in contact with the insulating layer 31 or 32 provided above and below the conductive layer 24 and the side surface of the memory pillar MP. In the conductive layer 24, for example, titanium nitride is provided so as to be in contact with the high dielectric constant material, and tungsten is provided to be in contact with titanium nitride and to be embedded in the inside of the conductive layer 24.

An insulating layer 33 is provided on the uppermost insulating layer 32. The insulating layer 34 is provided on the insulating layer 33. Each of the insulating layers 33 and 34 contains, for example, silicon oxide. The conductive layer 25 is provided on the insulating layer 34. The conductive layer 25 functions as the bit line BL. The conductive layer 25 has, for example, a portion provided to extend in the Y direction. Although not shown, a plurality of conductive layers 25 are arranged in the X direction. The conductive layer 25 contains, for example, copper (Cu). The insulating layer 35 is provided on the conductive layer 25. The insulating layer 35 contains, for example, silicon oxide.

The member SLT has a portion spreading along the XZ plane. The member SLT divides the semiconductor layer 23, the insulating layer 31, the alternately stacked conductive layers 24 and insulating layers 32, and the insulating layer 33. In other words, the member SLT separates the semiconductor layer 23, the insulating layer 31, the alternately stacked conductive layers 24 and insulating layers 32, and the insulating layer 33 provided in the adjacent block BLK. The lower portion of the member SLT reaches the semiconductor layer 22. In the member SLT, each of the conductive member LI and the spacer SP has a portion extending along the XZ plane. The conductive member LI has a portion facing each of the plurality of conductive layers 24 in the Y direction with the spacer SP interposed therebetween. The lower end of the conductive member LI is electrically connected to the semiconductor layer 22 (source line SL). The conductive member LI contains, for example, tungsten and titanium nitride, or silicon. The spacer SP contains, for example, silicon oxide.

Each memory pillar MP is provided to extend along the Z direction, and penetrates (passes through) the semiconductor layers 22 and 23, the insulating layer 31, and the conductive layers 24 and the insulating layers 32 alternately stacked. For example, a lower portion of each memory pillar MP is covered with the semiconductor layers 21, 22, and 23. Each memory pillar MP includes, for example, a core member 40, a semiconductor film 41, and a stacked film 42. The core member 40 is a substantially cylindrical insulator extending along the Z direction. The upper end of the core member 40 is positioned above the uppermost conductive layer 24. The lower end of the core member 40 is located, for example, in the same layer as the semiconductor layer 21. The semiconductor film 41 is provided to extend along the Z direction and covers the periphery of the core member 40. The semiconductor film 41 has a portion connected to the semiconductor layer 22 (source line SL) via a part of the side surface of the memory pillar MP. The stacked film 42 covers the side surface and the bottom surface of the semiconductor film 41 except for a portion where the semiconductor film 41 and the semiconductor layer 22 are connected. The semiconductor film 41 faces each of the conductive layers 24 arranged in the Z direction in a planar direction (for example, the Y direction) with the stacked film 42 interposed therebetween.

A contact plug CV is provided on the semiconductor film 41 of each memory pillar MP. The contact plug CV penetrates (passes through) the insulating layers 33 and 34. The semiconductor film 41 (the memory pillar MP) and the conductive layer 25 (the bit line BL) are electrically connected via the contact plug CV.

The number of conductive layers 24 corresponds to the number of wiring layers included in the stacked wiring line (the conductive layers 24 arranged in the Z direction). In the present example, the conductive layer 24 of twelve layers is used as the select gate line SGS, the word lines WL0 to WL9, and the select gate line SGD in this order from the source line SL side. A portion where the conductive layer 24 used as the select gate line SGS and the memory pillar MP cross each other functions as a select transistor STS. A portion where the conductive layer 24 used as the word line WL and the memory pillar MP cross each other functions as a memory cell transistor MT. A portion where the conductive layer 24 used as the select gate line SGD and the memory pillar MP cross each other functions as a select transistor STD. The semiconductor film 41 in each memory pillar MP is used as channels (current paths) of the memory cell transistors MT0 to MT9 and the select transistors STD and STS included in a NAND string NS. In a case where the conductive layer 24 contains aluminum oxide as the high dielectric constant material, the memory cell transistor MT is also referred to as a metal-aluminum-nitride-oxide-silicon (MANOS) type memory cell.

### (3: Tier Structure of Memory Cell Array 10)

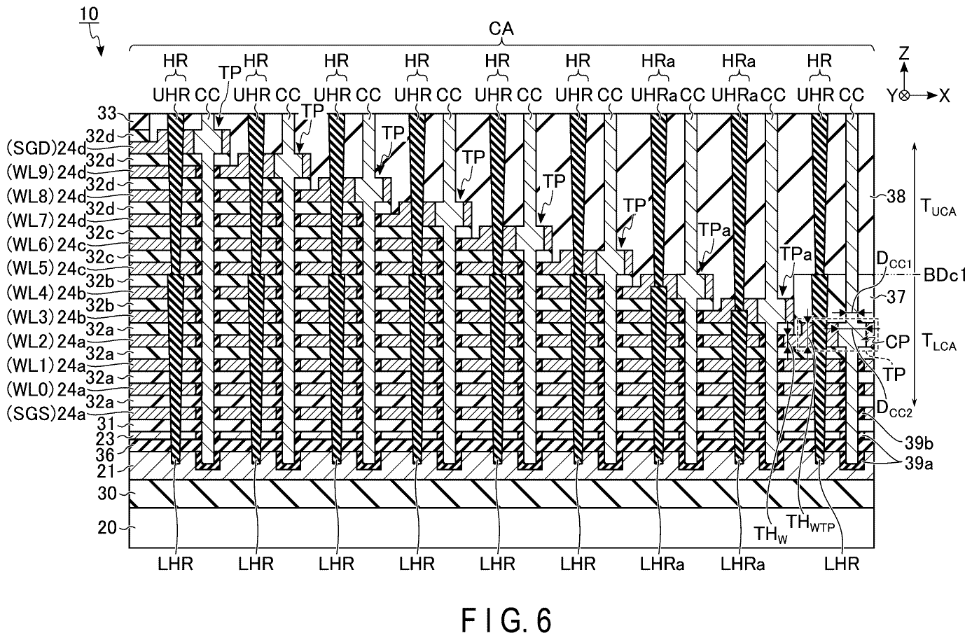

Next, the tier structure of the memory cell array 10 will be described with reference to FIG. 4. In the memory device 1 according to the first embodiment, the memory cell array 10 has a structure formed by being divided into a plurality of tiers. For example, the memory cell array 10 includes memory pillars MP formed in three tiers and a member SLT formed in two layers in the memory area MA, and includes support pillars HR (shown in FIG. 6 described later) formed in two tiers in the contact area CA.

Specifically, the member SLT are associated with two tiers, and includes a lower member LSLT and an upper member ULST connected in the Z direction. The memory pillars MP are associated with three tiers, and include a lower memory pillar LMP, a middle memory pillar MMP, and an upper memory pillar UMP connected in the Z direction. A boundary BDc1 shown in FIG. 4 indicates a boundary between the lower member LSLT and the upper member USLT. A boundary BDm1 indicates a boundary between the lower memory pillar LMP and the middle memory pillar MMP. A boundary BDm2 indicates a boundary between the middle memory pillar MMP and the upper memory pillar UMP. In this example, the position of the boundary BDc1 associated with the member SLT is different from the positions of the boundaries BDm1 and BDm2 associated with the memory pillar MP.

Hereinafter, the lower side of the contact area CA will be referred to as a “lower tier T_{LCA}”, and the upper side of the contact area CA will be referred to as an “upper tier T_{UCA}”. The lower member LSLT and the upper member USLT are associated with the lower tier T_{LCA} and the upper tier T_{UCA}, respectively. In addition, hereinafter, the layer corresponding to the lower memory pillar LMP is referred to as a “lower tier T_{LMP}”. The layer corresponding to the middle memory pillar MMP is referred to as a “middle tier T_{MMP}”. The layer corresponding to the upper memory pillar UMP is referred to as an “upper tier T_{UMP}”. The conductive layer 24 and the insulating layer 32 included in the lower tier T_{LCA} and the lower tier T_{LMP} are referred to as a conductive layer 24a and an insulating layer 32a, respectively. The conductive layer 24 and the insulating layer 32 included in the lower tier T_{LCA} and the middle tier T_{MMP} are referred to as a conductive layer 24b and an insulating layer 32b, respectively. The conductive layer 24 and the insulating layer 32 included in the upper tier T_{UCA} and the middle tier T_{MMP} are referred to as a conductive layer 24c and an insulating layer 32c, respectively. The conductive layer 24 and the insulating layer 32 included in the upper tier T_{UCA} and the upper tier T_{UMP} are referred to as a conductive layer 24d and an insulating layer 32d, respectively. The plurality of conductive layers 24 are arranged over a plurality of layers including the lower tier T_{LCA} and the upper tier T_{UCA}.

In the member SLT, the lower member LSLT divides the conductive layers 24a of four layers (select gate line SGS and word lines WL0 to WL2), the conductive layer 24b of two layers (word lines WL3 and WL4), the insulating layer 32a of four layers, and the insulating layer 32b of two layers. Then, the lower end of the lower member LSLT reaches the semiconductor layer 22. The upper member USLT divides the conductive layer 24c of two layers (word lines WL5 and WL6), the conductive layer 24d of four layers (word lines WL7 to WL9 and select gate line SGD), the insulating layer 32c of two layers, and the insulating layer 32d of four layers. The boundary BDc1 between the lower member LSLT and the upper member USLT is located between the conductive layer 24b functioning as the word line WL4 and the conductive layer 24c functioning as the word line WL5. In other words, the boundary BDc1 between the lower tier T_{LCA} and the upper tier T_{UCA} is located between the uppermost conductive layer 24b and the lowermost conductive layer 24c.

Each of the conductive member LI and the spacer SP is continuously provided in the lower member LSLT and the upper member USLT. Each of the lower member LSLT and the upper member USLT has, for example, a tapered shape in which the width of the upper end in the Y direction is larger than the width of the lower end in the Y direction. Therefore, the boundary BDc1 can be confirmed by observing the shape of the cross section. Each of the lower member LSLT and the upper member USLT may be referred to as a sub-portion of the member SLT.

In the memory pillar MP, the lower memory pillar LMP penetrates (passes through) the conductive layer 24a of four layers (select gate line SGS and word lines WL0 to WL2) and the insulating layer 32a of four layers. Then, the lower end of the lower memory pillar LMP reaches the semiconductor layer 21. The middle memory pillar MMP penetrates (passes through) the conductive layer 24b of two layers (word lines WL3 and WL4), the conductive layer 24c of two layers (word lines WL5 and WL6), the insulating layer 32b of two layers, and the insulating layer 32c of two layers. The upper memory pillar UMP penetrates (passes through) the conductive layer 24d of four layers (word lines WL7 to WL9 and select gate line SGD) and the insulating layers 32d of four layers. The boundary BDm1 between the lower memory pillar LMP and the middle memory pillar MMP is located between the conductive layer 24a functioning as the word line WL2 and the conductive layer 24b functioning as the word line WL3. The boundary BDm2 between the middle memory pillar MMP and the upper memory pillar UMP is located between the conductive layer 24c functioning as the word line WL6 and the conductive layer 24d functioning as the word line WL7. In other words, the boundary BDm1 between the lower tier T_{LMP} and the middle tier T_{MMP} is located between the uppermost conductive layer 24a and the lowermost conductive layer 24b. The boundary BDm2 between the middle tier T_{MMP} and the upper tier T_{UMP} is located between the uppermost conductive layer 24c and the lowermost conductive layer 24d.

Note that each of the core member 40, the semiconductor film 41, and the stacked film 42 is continuously provided in the lower memory pillar LMP, the middle memory pillar MMP, and the upper memory pillar UMP. Each of the lower memory pillar LMP, the middle memory pillar MMP, and the upper memory pillar UMP has, for example, a tapered shape (normal tapered shape) in which a diameter (XY cross-sectional area) of an upper end is larger than a diameter (XY cross-sectional area) of a lower end. In other words, each of the lower memory pillar LMP, the middle memory pillar MMP, and the upper memory pillar UMP has, for example, a truncated cone shape in which the lower portion is smaller than the upper portion. Therefore, each of the boundaries BDm1 and BDm2 can be confirmed by observing the cross-sectional shape of the memory pillar MP. Each of the lower memory pillar LMP, the middle memory pillar MMP, and the upper memory pillar UMP may be referred to as a sub-pillar of the memory pillar MP.

Hereinafter, the stacked structure corresponding to the conductive layer 24a of four layers and the insulating layer 32a of four layers through which the lower memory pillar LMP passes (penetrates) is also referred to as a “lower layer stack”. Hereinafter, the stacked structure corresponding to the conductive layer 24b of two layers, the conductive layer 24c of two layers, the insulating layer 32b of two layers, and the insulating layer 32c of two layers through which the middle memory pillar MMP passes (penetrates) is also referred to as a “middle layer stack”. Furthermore, in the middle layer stack, a layer including the conductive layer 24b of two layers and the insulating layer 32b of two layers is referred to as a lower layer of the middle layer stack. In the middle layer stack, a layer including the conductive layer 24c of two layers and the insulating layer 32c of two layers is referred to as an upper layer of the middle layer stack. Hereinafter, the stacked structure corresponding to the conductive layer 24d of four layers and the insulating layer 32d of four layers through which the upper memory pillar UMP passes (penetrates) is also referred to as a “upper layer stack”.

### (4: Cross-Sectional Structure of the Memory Pillar MP)

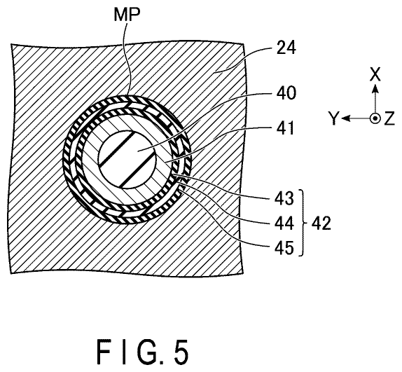

FIG. 5 is a cross-sectional view showing an example of a cross-sectional structure of the memory pillar MP included in the memory device 1 according to the first embodiment. FIG. 5 shows an XY cross section including the memory pillar MP and the conductive layer 24. As shown in FIG. 5, the stacked film 42 includes, for example, a tunnel insulating film 43, a charge storage film 44, and a block insulating film 45. The tunnel insulating film 43 surrounds the side surface of the semiconductor film 41. The charge storage film 44 surrounds the side surface of the tunnel insulating film 43. The block insulating film 45 surrounds the side surface of the charge storage film 44. The conductive layer 24 surrounds the side surface of the block insulating film 45. The core member 40 includes, for example, an insulator such as silicon oxide. The semiconductor film 41 contains, for example, silicon. Each of the tunnel insulating film 43 and the block insulating film 45 contains, for example, silicon oxide. The charge storage film 44 functions as a charge storage layer of the memory cell transistor MT, and includes, for example, silicon nitride (silicon and nitrogen).

### (5: Cross-Sectional Structure of Contact Area CA)

FIG. 6 is a cross-sectional view showing an example of a cross-sectional structure of the contact area CA of the memory cell array 10 included in the memory device 1 according to the first embodiment. FIG. 6 shows an XZ cross section including the terrace portion TP of the conductive layer 24 of three layers (word lines WL2 to WL4) included in the lower tier T_{LCA} and the terrace portion TP of the conductive layer 24 of six layers (word lines WL5 to WL9 and select gate line SGD) included in the upper tier T_{UCA} in the contact area CA of the memory cell array 10. As shown in FIG. 6, the memory cell array 10 further includes insulating layers 36, 37, 38, 39a, and 39b in the contact area CA.

The insulating layer 36 is provided between the semiconductor layer 21 and the semiconductor layer 23 in the contact area CA. The insulating layer 36 of the contact area CA remains without being removed at the time of the SL replacement. The insulating layer 36 contains, for example, silicon oxide.

The insulating layer 37 is provided so as to be embedded in the staircase portion formed by the plurality of terrace portions TP included in the lower tier T_{LCA} in the contact area CA. In other words, the insulating layer 37 is provided so as to be embedded in the staircase portion formed by the plurality of terrace portions TP of the lower layer stack and the plurality of terrace portions TP of the lower layer of the middle layer stack in the contact area CA. By the insulating layer 37, step differences due to the staircase portion corresponding to the lower layer stack and the lower layer of the middle layer stack can be flattened from the memory are MA to the contact area CA. The insulating layer 37 contains, for example, silicon oxide.

The insulating layer 38 is provided to be embedded in the staircase portion formed by the plurality of terrace portions TP included in the upper tier T_{UCA} in the contact area CA. In other words, in the contact area CA, the insulating layer 38 is provided to be embedded in the staircase portion formed by the plurality of terrace portions TP of the upper layer of middle layer stack, the plurality of terrace portions TP of the upper layer stack, and a terrace portion TPa to be further described later. By the insulating layer 38, step differences due to the staircase portion corresponding to the upper layer of the middle layer stack and the upper layer stack can be flattened from the memory are MA to the contact area CA. The insulating layer 38 contains, for example, silicon oxide.

In each conductive layer 24, the thickness TH_{WTP} of the terrace portion TP in the Z direction is thicker than the thickness TH_{W} of the other portions in the Z direction. In other words, the thickness in the Z direction of each terrace portion TP of the plurality of conductive layers 24 is thicker than the thickness in the Z direction of the portion included in the memory area MA in each of the conductive layers 24. In the present specification, a manufacturing process for forming the terrace portion TP to be thick is referred to as “thickening (processing)”. Details of the thickening processing will be described later. Furthermore, the terrace portion TP of the conductive layer 24 of at least one layer from the side included in the lower tier T_{LCA} and closer to the boundary BDc1 is referred to as a “terrace portion TPa”. The terrace portion TPa corresponds to, for example, the conductive layer 24b of at least one layer included in the lower tier T_{LCA} and arranged closer to the boundary BDc1 between the lower tier T_{LCA} and the upper tier T_{UCA} than the plurality of conductive layers 24a. The thickening processing for the terrace portion TPa is not executed together with the plurality of terrace portions TP included in the lower tier T_{LCA}, but is executed together with the plurality of terrace portions TP included in the upper tier T_{UCA}. Therefore, the thickness in the Z direction of the terrace portion TP of the conductive layer 24 included in the upper tier T_{UCA} is substantially the same as the thickness in the Z direction of the terrace portion TPa of the conductive layer 24 included in the lower tier T_{LCA}. Note that the thickness in the Z direction of the terrace portion TP of the conductive layer 24 included in the lower tier T_{LCA} may be different from the thickness in the Z direction of the terrace portion TP of the conductive layer 24 included in the upper tier T_{UCA}. Furthermore, above the terrace portion TPa of each conductive layer 24, the insulating layer 37 is removed, and the insulating layer 38 is embedded.

Each contact plug CC is provided to extend along the Z direction, and penetrates (passes through) the insulating layers 31, 32, and 36, the semiconductor layer 23, the terrace portion TP or TPa of the associated conductive layer 24, and the conductive layer 24 disposed below the associated conductive layer 24. In the present specification, the “associated conductive layer 24” indicates the conductive layer 24 to be electrically connected to the contact plug CC. The upper end of each contact plug CC is positioned in the upper layer of the uppermost conductive layer 24. The lower end of the contact plug CC is located, for example, in the same layer as the semiconductor layer 21. The contact plug CC associated with the conductive layer 24 whose terrace portion TP is included in the upper tier T_{UCA} penetrates (passes through) the insulating layer 38. The contact plug CC associated with the conductive layer 24 whose terrace portion TP is included in the lower tier T_{LCA} penetrates (passes through) the insulating layers 37 and 38. The contact plug CC associated with the conductive layer 24 having the terrace portion TPa penetrates (passes through) the insulating layer 38. The contact plug CC contains, for example, tungsten or copper.

Each contact plug CC is in contact with the associated conductive layer 24 in a portion (a portion of the side surface) intersecting the terrace portion TP or TPa of the associated conductive layer 24. Hereinafter, a portion where each contact plug CC intersects the terrace portion TP or TPa of the associated conductive layer 24 is referred to as an intersection portion CP. The upper end of the intersection portion CP of the contact plug CC is aligned with the upper end of the terrace portion TP or TPa of the associated conductive layer 24. The lower end of the intersection portion CP of the contact plug CC is aligned with the lower end of the terrace portion TP or TPa of the associated conductive layer 24. The diameter of the contact plug CC is “D_{CC1}” in a portion passing through the insulating layer 37 or 38 and close to the terrace portion TP or TPa. In addition, the diameter of the contact plug CC is “D_{CC2}” at the intersection portion CP. The diameter D_{CC2} of the contact plug CC is larger than the diameter D_{CC1} of the contact plug CC. That is, the XY cross-sectional area of the portion corresponding to the diameter D_{CC2} of the contact plug CC is larger than the XY cross-sectional area of the portion corresponding to the diameter D_{CC1} of the contact plug CC. Furthermore, in the XY cross section, the cross-sectional area at the intersection portion CP of the contact plug CC is larger than the cross-sectional area at a portion of the contact plug CC passing through the insulating layer 32 adjacent to the terrace portion TP or TPa on the substrate 20 side.

The plurality of insulating layers 39a is provided to separate the semiconductor layer 21 from the bottom of one contact plug CC. In addition, the plurality of insulating layers 39a is provided so as to separate a portion of the semiconductor layer 23 passed by one contact plug CC from the one contact plug CC. Each contact plug CC and each of the semiconductor layers 21 and 23 are insulated by the plurality of insulating layers 39a. The plurality of insulating layers 39b is provided so as to separate a portion of the plurality of conductive layers 24 other than the terrace portion TP or TPa, which is passed by one contact plug CC, from the one contact plug CC. Each contact plug CC and a portion of the conductive layer 24 excluding the terrace portion TP or TPa are insulated by the insulating layer 39b. The insulating layer 39 (39a and 39b) contains, for example, silicon oxide.

Each support pillar HR penetrates (passes through) the insulating layers 31, 32, and 36, the semiconductor layer 23, and the conductive layer 24 of at least one layer arranged to overlap in plan view. The upper end of each support pillar HR is positioned in the upper layer of the uppermost conductive layer 24. The lower end of the each support pillar HR is located, for example, in the same layer as the semiconductor layer 21. In addition, each support pillar HR has a structure formed in two layers (tier). Furthermore, in the first embodiment, the support pillars HR provided so as to penetrate (pass through) the terrace portion TPa of the conductive layer 24 have a structure different from the other support pillars HR. Hereinafter, among the plurality of support pillars HR, the support pillar HR provided so as to penetrate (pass through) the terrace portion TPa of the conductive layer 24 is referred to as a “support pillar HRa”. The support pillars HR and HRa contain, for example, silicon oxide.

Each support pillar HR includes a lower support pillar LHR and an upper support pillar UHR connected in the Z direction. Each support pillar HRa includes a lower support pillar LHRa and an upper support pillar UHRa connected in the Z direction. The lower support pillars LHR and LHRa are associated with the lower tier T_{LCA}. The upper support pillars UHR and UHRa are associated with the upper tier T_{UCA}. The structure corresponding to the lower support pillar LHRa is collectively formed with the lower support pillar LHR. Thereafter, the upper portion of the lower support pillar LHRa is processed to the height of the terrace portion TPa of the associated conductive layer 24. Further, the upper support pillar UHRa is collectively formed with the upper support pillar UHR. The lower end of the upper support pillar UHRa is positioned below the lower end of the upper support pillar UHR. In other words, the upper end of the lower support pillar LHRa is positioned below the upper end of the lower support pillar LHR. In the support pillar HR, the position of the boundary between the lower support pillar LHR and the upper support pillar UHR substantially coincides with the boundary BDc1. That is, in the present example, the boundary of the support pillars HR and the boundary of the member SLT substantially coincide with each other. On the other hand, in the lower support pillar LHRa, the position of the boundary between the lower support pillar LHRa and the upper support pillar UHRa is located lower than the boundary BDc1, unlike the boundary BDc1.

The insulating member included in the support pillar HR may be continuously provided in the lower support pillar LHR and the upper support pillar UHR, or may be separately provided between the lower support pillar LHR and the upper support pillar UHR. Each of the lower support pillars LHR and LHRa and the upper support pillars UHR and UHRa has, for example, a tapered shape (normal tapered shape) in which a diameter (XY cross-sectional area) of an upper end is larger than a diameter (XY cross-sectional area) of a lower end. In other words, each of the lower support pillars LHR and LHRa and the upper support pillars UHR and UHRa has, for example, a truncated cone shape in which the lower portion is smaller than the upper portion. Therefore, the boundary between the lower support pillar LHR and the upper support pillar UHR can be confirmed by observing the cross-sectional shape of the support pillar HR. Similarly, the boundary between the lower support pillar LHRa and the upper support pillar UHRa can be confirmed by observing the cross-sectional shape of the support pillar HRa. Each of the lower support pillars LHR and LHRa and the upper support pillars UHR and UHRa may be referred to as a sub-pillar of the support pillar HR or HRa.

The structure of the memory device 1 described above may be paraphrased as follows. For example, the plurality of support pillars HR include a first pillar in which the position of the boundary between a first sub-pillar and a second sub-pillar substantially coincides with a first boundary between the lower tier T_{LCA} and the upper tier T_{UCA}. In addition, the plurality of support pillars HR include a second pillar in which the position of the boundary between the first sub-pillar and the second sub-pillar is separated from the first boundary BDc1. The first pillar has a portion that passes through the terrace portion TP of the conductive layer 24c or 24d included in the upper tier T_{UCA} among the plurality of conductive layers 24. The second pillar has a portion that passes through the terrace portion TPa of the conductive layer 24b included in the lower tier T_{LCA} and arranged near the first boundary BDc1 among the plurality of conductive layers 24.

### (6: Cross-Sectional Structure of Contact Plug CC)

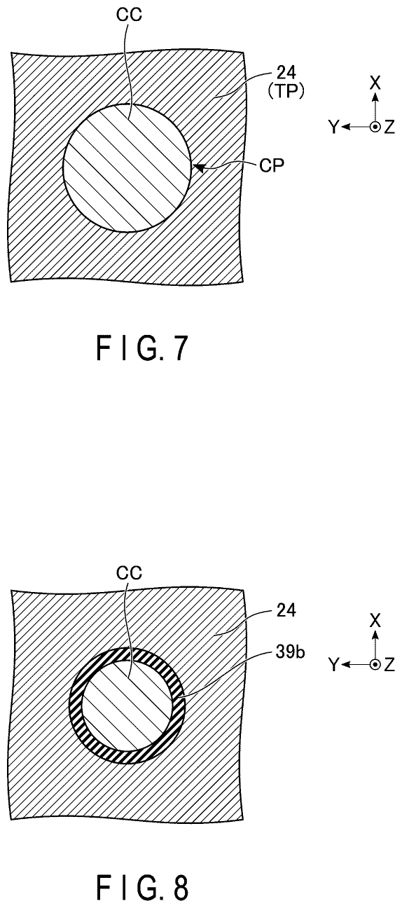

Each of FIGS. 7 and 8 is a cross-sectional view showing an example of a cross-sectional structure of the contact plug CC included in the memory device 1 according to the first embodiment. FIG. 7 shows an XY cross section including the intersection portion CP of the contact plug CC and the terrace portion TP of the associated conductive layer 24. FIG. 8 shows an XY cross section including the contact plug CC and the conductive layer 24 disposed below the associated conductive layer 24.

As shown in FIG. 7, the side surface of the intersection portion CP of the contact plug CC is surrounded by the associated conductive layer 24. Then, the contact plug CC is in contact with the associated conductive layer 24 via the side surface. On the other hand, as shown in FIG. 8, in the XY cross section including the contact plug CC and the conductive layer 24 disposed below the associated conductive layer 24, the side surface of the contact plug CC is surrounded by the insulating layer 39b. Then, the contact plug CC and the conductive layer 24 disposed below the associated conductive layer 24 are separated and insulated by the insulating layer 39b.

### (7: Cross-Sectional Structure of Support Pillar HR)

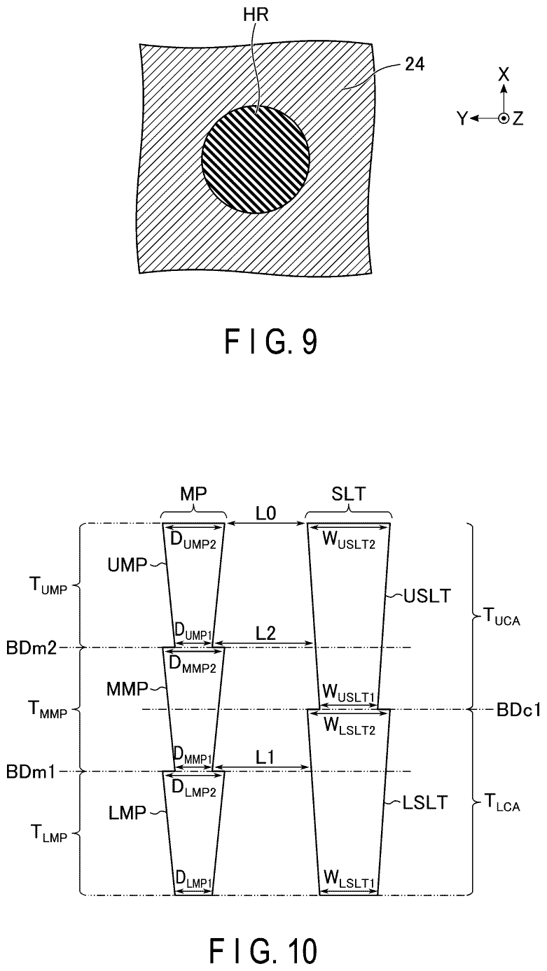

FIG. 9 is a cross-sectional view showing an example of a cross-sectional structure of the support pillar HR included in the memory device 1 according to the first embodiment. FIG. 9 shows an XY cross section including the support pillar HR and the conductive layer 24. As shown in FIG. 9, the conductive layer 24 surrounds the side surface of the support pillar HR. In the first embodiment, the support pillar HR contains an insulator and is in contact with the conductive layer 24.

### (8: Relationship Between Memory Pillar MP and Member SLT)

FIG. 10 is a diagram showing an example of a relationship between the memory pillar MP and the member SLT in the memory device 1 according to the first embodiment. As shown in FIG. 10, in the first embodiment, the memory pillar MP has two boundaries BDm1 and BDm2. The member SLT has one boundary BDc1. As described above, the memory pillar MP and the member SLT are different in the number of tiers (the number of boundaries). Each of the memory pillar MP and the member SLT has a tapered shape in each divided tier.

In the lower memory pillar LMP, the diameter D_{LMP1} (XY cross-sectional area) at the lower end is smaller than the diameter D_{LMP2} (XY cross-sectional area) at the upper end. In the middle memory pillar MMP, the diameter D_{MMP1} (XY cross-sectional area) at the lower end is smaller than the diameter D_{MMP2} (XY cross-sectional area) at the upper end. In the upper memory pillar UMP, the diameter D_{UMP1} (XY cross-sectional area) at the lower end is smaller than the diameter D_{UMP2} (XY cross-sectional area) at the upper end. The diameter D_{LMP2} (XY cross-sectional area) of the upper end of the lower memory pillar LMP is larger than the diameter D_{MMP1} (XY cross-sectional area) of the lower end of the middle memory pillar MMP. The diameter D_{MMP2} (XY cross-sectional area) of the upper end of the middle memory pillar MMP is larger than the diameter D_{UMP1} (XY cross-sectional area) of the lower end of the upper memory pillar UMP. In the lower member LSLT, the width W_{LSLT1} of the lower end in the Y direction is smaller than the width W_{LSLT2} of the upper end in the Y direction. In the upper member USLT, the width W_{USLT1} of the lower end in the Y direction is smaller than the width W_{USLT2} of the upper end in the Y direction. The width WL_{LSLT2} of the upper end of the lower member LSLT in the Y direction is larger than the width W_{USLT1} of the lower end of the upper member USLT in the Y direction.

As described above, the diameter (XY cross-sectional area) of the middle memory pillar MMP is the smallest in the vicinity of the boundary BDm1. The diameter (XY cross-sectional area) of the upper memory pillar UMP is the smallest in the vicinity of the boundary BDm2. The width of the upper member USLT becomes the smallest in the vicinity of the boundary BDc1. Then, the position of the boundary BDc1 is different from the respective positions of the boundaries BDm1 and BDm2. That is, the thinnest portion in the upper member USLT and each of the thinnest portion in the middle memory pillar MMP and the thinnest portion in the upper memory pillar UMP are not adjacent to each other in the planar direction (for example, the Y direction). As a result, the distance between the memory pillar MP and the member SLT can be made closer than the distance in a case where the memory pillar MP and the member SLT have the same number of tiers. That is, since the boundary position of the memory pillar MP and the boundary position of the member SLT are provided between the conductive layers 24 different from each other, it is possible to suppress an increase in spacing between the memory pillar MP and the member SLT.

Although not shown, the support pillar HR formed in two layers are similar to the memory pillar MP and the member SLT. That is, in the lower support pillar LHR, the diameter (XY cross-sectional area) of the lower end is smaller than the diameter (XY cross-sectional area) of the upper end. In the upper support pillar UHR, the diameter (XY cross-sectional area) of the lower end is smaller than the diameter (XY cross-sectional area) of the upper end. The diameter (XY cross-sectional area) of the upper end of the lower support pillar LHR is larger than the diameter (XY cross-sectional area) of the lower end of the upper support pillar UHR. In this manner, the diameter of the upper support pillar UHR becomes the smallest in the vicinity of the boundary BDc1. Then, the thinnest portion in the upper support pillar UHR and each of the thinnest portion in the middle memory pillar MMP and the thinnest portion in the upper memory pillar UMP are not adjacent to each other in the planar direction (for example, the X direction). As a result, the distance between the memory pillar MP and the support pillar HR can be made closer than the distance in a case where the memory pillar MP and the support pillar HR have the same number of tiers.

### <1-2> Manufacturing Method

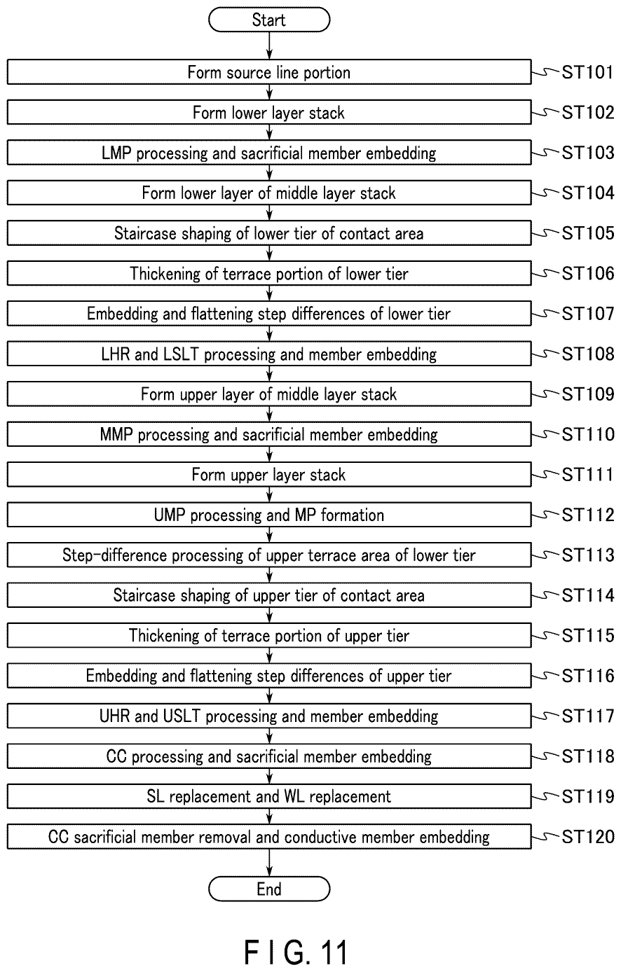

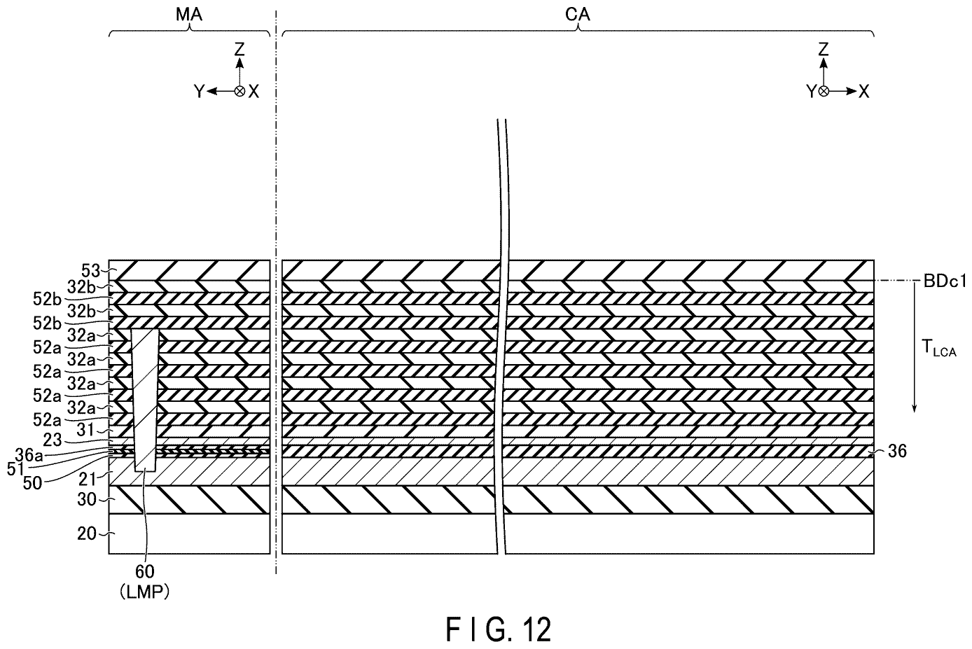

Next, as a method of manufacturing the memory device 1 according to the first embodiment, a method of forming the stacked wiring line and the contact plug CC corresponding to the memory cell array 10 will be described with reference to FIG. 11 as appropriate. FIG. 11 is a flowchart showing an example of a method of manufacturing the memory device according to the first embodiment. Each of FIGS. 12, 13, 14, 15, 16, 17, 18, 19, 20, 21, 22, 23, 24, 25, and 26 is a cross-sectional view showing an example of a cross-sectional structure in the manufacturing process of the memory device 1 according to the first embodiment. Each of FIGS. 12 to 26 shows an area where the memory pillar MP and the member SLT are formed and a part of the contact area CA.

First, the structure shown in FIG. 12 is formed by executing the processing of steps ST101, ST102, ST103, and ST104 in this order.

In the processing of step ST101, a source line portion is formed. The source line portion is a structure for forming the semiconductor layers 21 to 23 functioning as the source line SL in the memory area MA. Specifically, first, the insulating layer 50 and the sacrificial member 51 are stacked in this order on the semiconductor layer 21. The insulating layer 50 contains, for example, silicon oxide. The sacrificial member 51 contains, for example, silicon nitride. Then, the sacrificial member 51 in the contact area CA is removed. The insulating layer 36 is then formed and the top surface of insulating layer 36 is flattened. Hereinafter, a portion included in the memory area MA in the flattened insulating layer 36 is referred to as an insulating layer 36a. Thereafter, the semiconductor layer 23 is formed on the insulating layers 36 and 36a.

In the processing of step ST102, a lower layer stack is formed. Specifically, as the lower layer stack, the sacrificial member 52a associated with the conductive layer 24a and the insulating layer 32a are alternately stacked on the insulating layer 31. The sacrificial member 52 contains, for example, silicon nitride.

In the processing of step ST103, LMP processing and sacrificial member embedding are executed. Specifically, first, a plurality of holes corresponding to the lower memory pillar LMP is formed so as to penetrate the sacrificial members 51 and 52a and the insulating layers 31, 32a, 36a, and 50, and the bottom thereof reaches the semiconductor layer 21. Then, the sacrificial member 60 is embedded in the plurality of holes corresponding to the lower memory pillar LMP. The sacrificial member 60 contains, for example, any of carbon, silicon, and a metal material. Note that an anisotropic etching process such as reactive ion etching (RIE) is used in the steps of forming various holes described in the present specification.

In the processing of step ST104, a lower layer of the middle layer stack is formed. Specifically, as the lower layer of the middle layer stack, the sacrificial member 52b associated with the conductive layer 24b and the insulating layer 32b are alternately stacked on the lower layer stack. Thereafter, a member 53 is formed on the uppermost insulating layer 32b. The member 53 is used, for example, as a protective film in staircase shaping of the lower tier T_{LCA}.

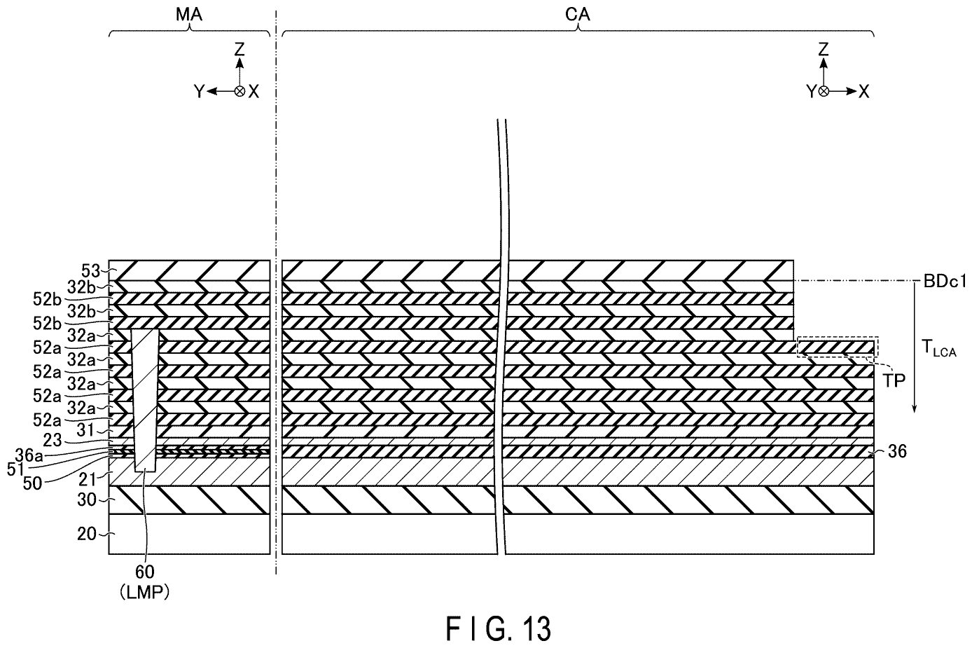

Next, as shown in FIG. 13, staircase shaping of the lower tier T_{LCA} of the contact area CA is executed (step ST105). Specifically, among the plurality of sacrificial members 52 (52a and 52b) of the lower tier T_{LCA}, a staircase structure configured by the terrace portions TP of the plurality of sacrificial members 52 (for example, the sacrificial member 52a) associated with the conductive layer 24 in which the terrace portion TP is to be formed is formed. In this step, the terrace portion TPa of the sacrificial member 52b associated with the conductive layer 24b where the terrace portion TPa is to be formed is not formed. In the present specification, the staircase shaping includes a set of photolithography processing and etching processing.

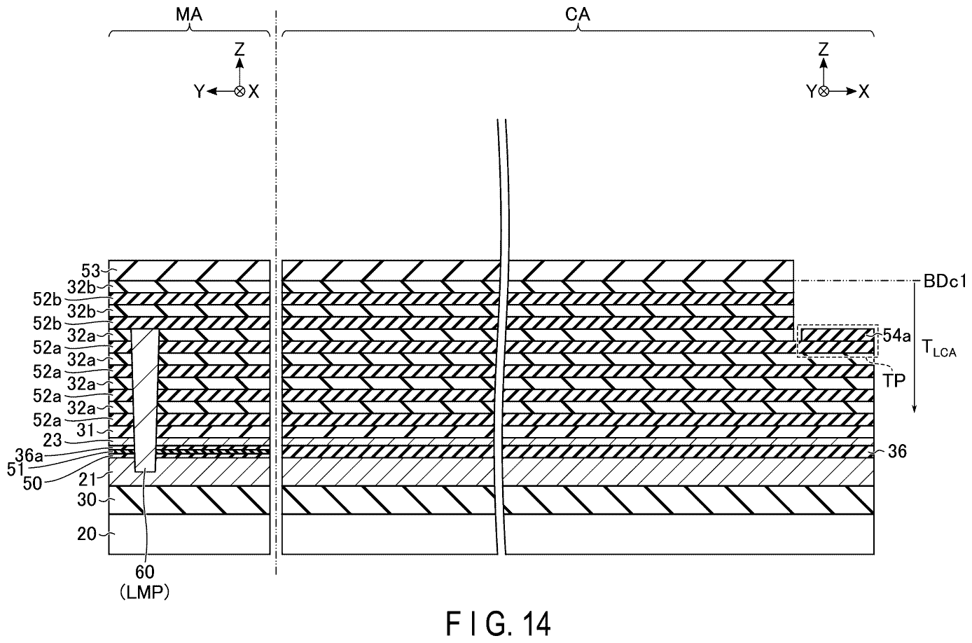

Next, as shown in FIG. 14, the terrace portion TP of the lower tier T_{LCA} is thickened (step ST106). Specifically, the sacrificial member 54a is formed on each sacrificial member 52a of the lower tier T_{LCA}. The shape of the set of the sacrificial member 52a and the sacrificial member 54a corresponds to the shape of the terrace portion TP of the conductive layer 24a of the lower tier T_{LCA}. The terrace portion TP of the sacrificial member 52a is separated from the terrace portion TP of the adjacent sacrificial member 52a in plan view. For example, the sacrificial member 54 is formed of the same material as the sacrificial member 52 and contains silicon nitride.

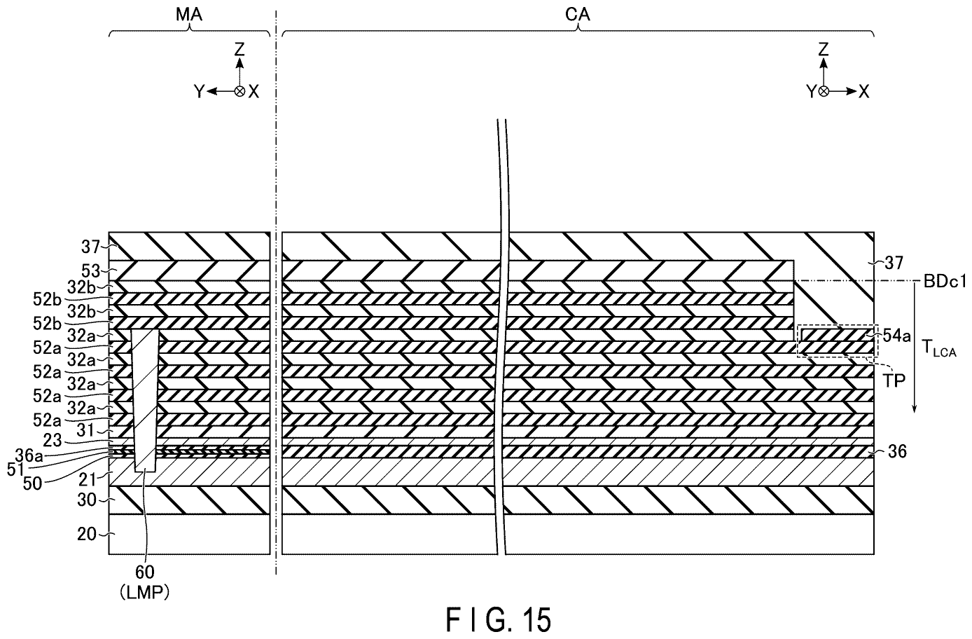

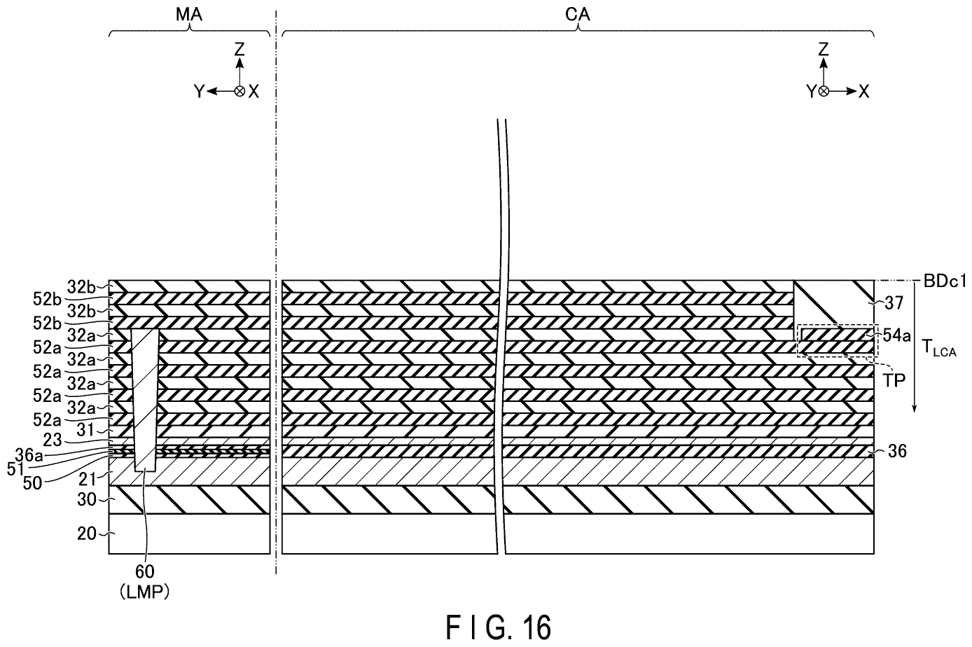

Next, embedding and flattening step differences of the lower tier T_{LCA} are executed (step ST107). Specifically, first, as shown in FIG. 15, the insulating layer 37 is formed so that the staircase structure formed in the lower tier T_{LCA} is embedded. Then, for example, as shown in FIG. 16, the member 53 and a part of the insulating layer 37 are removed by chemical mechanical polishing (CMP) processing. As a result, the upper surface of the uppermost insulating layer 32b in the memory area MA and the upper surface of the insulating layer 37 in the contact area CA are aligned (flattened).

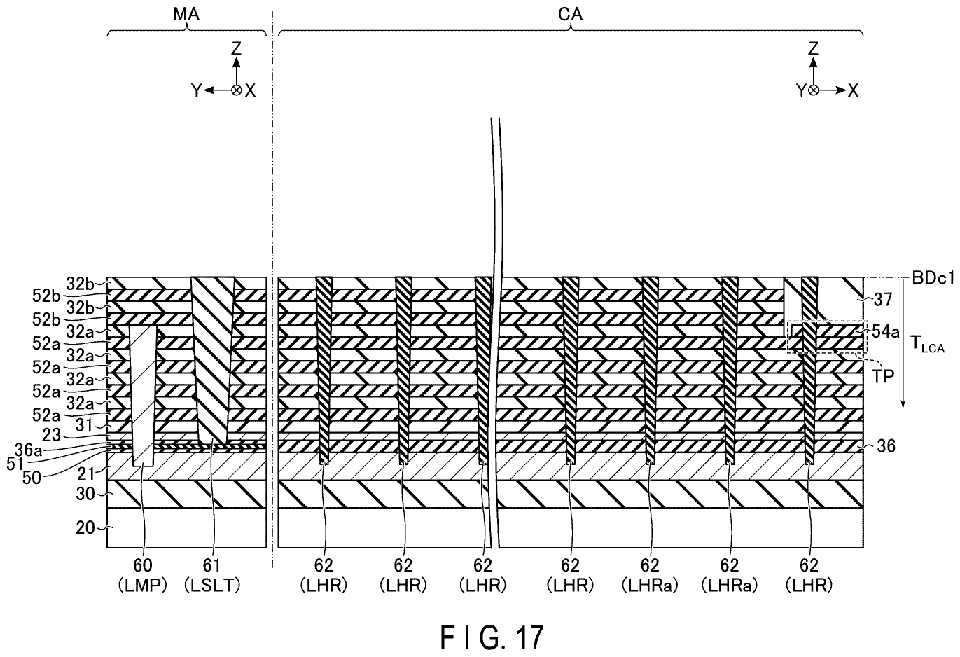

Next, as shown in FIG. 17, LHR and LSLT processing, and member embedding are executed (step ST108). Specifically, the slit corresponding to the lower member LSLT is formed so as to penetrate the sacrificial members 52a and 52b, the semiconductor layer 23, and the insulating layers 31, 32a, 32b, and 36a, and the bottom thereof reaches the sacrificial member 51. Then, the sacrificial member 61 is embedded in the slit corresponding to the lower member LSLT. The sacrificial member 61 contains, for example, any of carbon, silicon, and a metal material. Furthermore, in the processing of step ST108, a plurality of holes corresponding to the plurality of lower support pillars LHR or LHRa is formed to penetrate, for example, the sacrificial members 52a and 52b, the semiconductor layer 23, and the insulating layers 31, 32a, 32b, and 36, and such that the bottom thereof reaches the semiconductor layer 21. In a case where the plurality of holes corresponding to the plurality of lower support pillars LHR or LHRa overlap the terrace portion TP of the lower tier T_{LCA}, the plurality of holes are formed so as to penetrate the sacrificial members 52a and 54a, the semiconductor layer 23, and the insulating layers 31, 32a, and 36 below the associated terrace portion TP, and the insulating layer 37, and the bottom thereof reaches the semiconductor layer 21. Then, the insulating member 62 is embedded in the plurality of holes corresponding to the plurality of lower support pillars LHR or LHRa. At this time, the insulating member 62 corresponding to the lower support pillar LHRa is formed with the same structure as the insulating member 62 corresponding to the plurality of lower support pillars LHR. The insulating member 62 contains, for example, silicon oxide. Note that the order of processing and member embedding of the lower support pillar LHR and the lower member LSLT is any order.

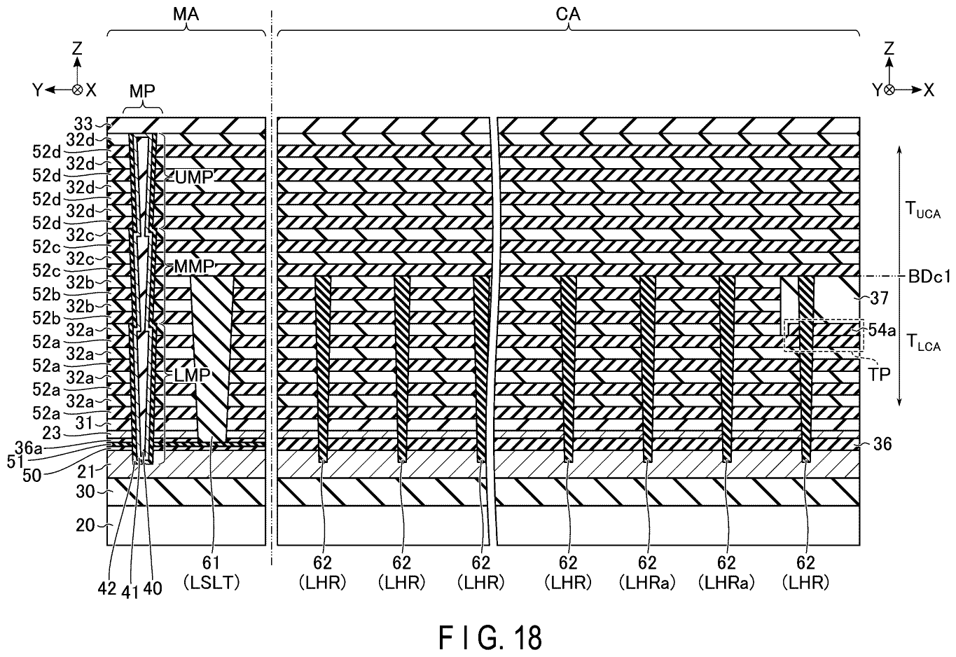

Next, the structure shown in FIG. 18 is formed by executing the processing of steps ST109, ST110, ST111, and ST112 in this order.

In the processing of step ST109, an upper layer of the middle layer stack is formed. Specifically, as the upper layer of the middle layer stack, the sacrificial member 52c associated with the conductive layer 24c and the insulating layer 32c are alternately stacked on the lower layer of the middle layer stack.

In the processing of step ST110, MMP processing and sacrificial member embedding are executed. Specifically, first, a plurality of holes corresponding to the middle memory pillar MMP is formed so as to penetrate the sacrificial members 52b and 52c and the insulating layers 32b and 32c, and reach the sacrificial member 60 in the lower memory pillar LMP with which the bottom thereof is associated. Then, the sacrificial member 60 is embedded in the plurality of holes corresponding to the middle memory pillar MMP.

In the processing of step ST111, an upper layer stack is formed. Specifically, as the upper layer stack, the sacrificial member 52d associated with the conductive layer 24d and the insulating layer 32d are alternately stacked on the upper layer of the middle layer stack.

In the processing of step ST112, UMP processing and MP formation are executed. Specifically, first, a plurality of holes corresponding to the upper memory pillar UMP is formed so as to penetrate the sacrificial member 52d and the insulating layer 32d, and reach the sacrificial member 60 in the middle memory pillar MMP with which the bottom thereof is associated. Then, the sacrificial member 60 formed in each hole corresponding to the middle memory pillar MMP and each hole corresponding to the lower memory pillar LMP is removed via the plurality of holes corresponding to the upper memory pillar UMP. Then, the stacked film 42, the semiconductor film 41, and the core member 40 are formed in each hole corresponding to a set of the upper memory pillar UMP, the middle memory pillar MMP, and the lower memory pillar LMP (that is, the memory pillar MP). Thereafter, the insulating layer 33 is formed on the uppermost insulating layer 32d.

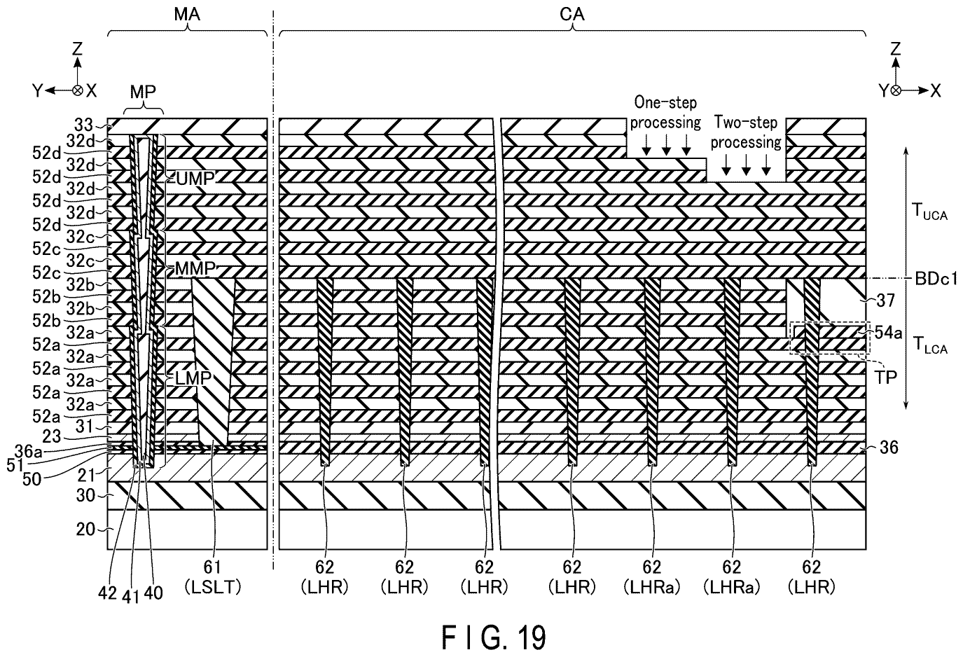

Next, as shown in FIG. 19, step-difference processing of the upper terrace area of the lower tier T_{LCA} is executed (step ST113). The upper terrace area of the lower tier T_{LCA} corresponds to an area overlapping the terrace portion TPa of the conductive layer 24b shown in FIG. 6 in plan view. Specifically, in the upper terrace area of the lower tier T_{LCA}, a step difference of a set of the sacrificial member 52d and the insulating layer 32d is formed according to the terrace portion TPa of the unprocessed sacrificial member 52b. The number of levels of the set of the sacrificial member 52d and the insulating layer 32d formed at this time corresponds to the number of levels of the set of the sacrificial member 52b and the insulating layer 32b to be processed from the boundary BDc1 to the lower layer. In this example, since the terrace portion TPa of two steps is formed, one-step processing and two-step processing are executed. In the portion of the one-step processing, one set of the sacrificial member 52d and the insulating layer 32d is processed (removed) from above in the area where the upper tier T_{UCA} and the upper terrace area of the lower layer overlap. In the portion of the two-step processing, two sets of the sacrificial member 52d and the insulating layer 32d is processed (removed) from above in the area where the upper tier T_{UCA} and the upper terrace area of the lower layer overlap. In the step-difference processing in step ST113, the peripheral area of the memory cell array 10 is not processed.

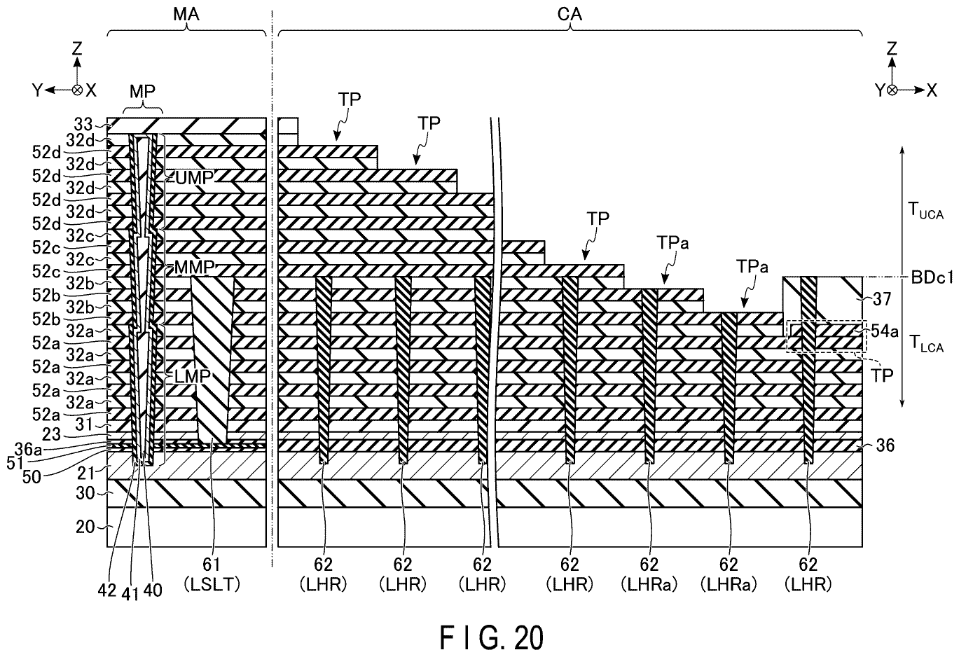

Next, staircase shaping of the upper tier T_{UCA} of the contact area CA is executed (step ST114). In the staircase shaping of the upper tier T_{UCA} in this process, the upper terrace area of the lower tier T_{LCA} is also to be processed. That is, in the etching processing for forming the staircase structure of the upper tier T_{UCA}, every time the set of the sacrificial member 52 and the insulating layer 32 is processed, the set of the sacrificial member 52 and the insulating layer 32 in the upper terrace area of the lower tier T_{LCA} is also processed. As a result, as shown in FIG. 20, the staircase structure of the terrace portion TP of the plurality of sacrificial members 52 (52c and 52d) is formed in the upper tier T_{UCA}, and the terrace portion TPa of at least one sacrificial member 52b is formed in the upper terrace area of the lower tier T_{LCA}. At this time, in this step, the upper portion of the insulating member 62 in the lower support pillar LHRa provided so as to penetrate the terrace portion TPa is also processed. As a result, the position of the upper end of the lower support pillar LHRa is lower than the position of the upper end of the lower support pillar LHR.

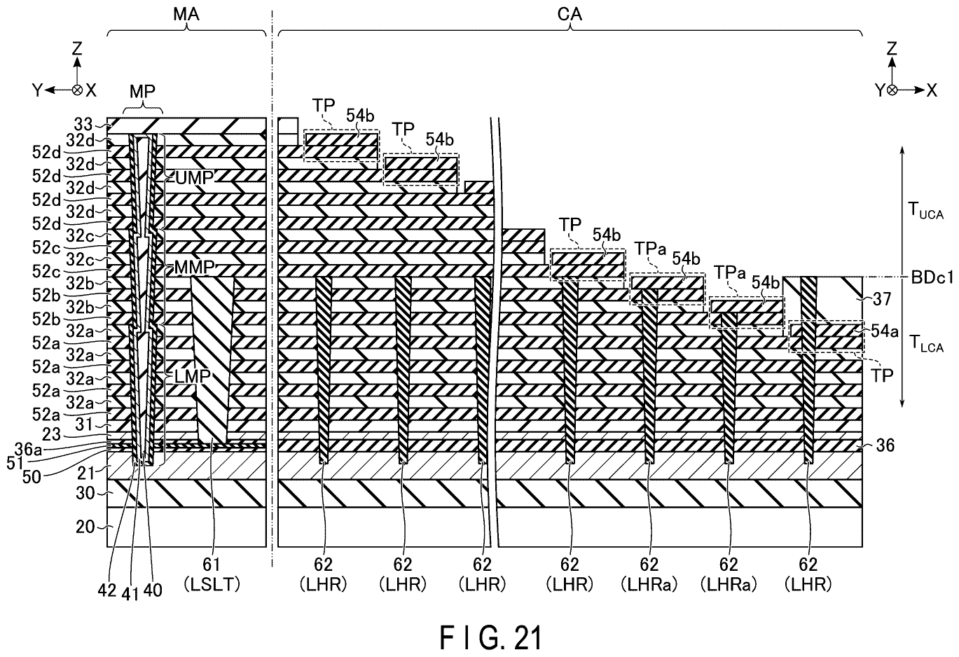

Next, as shown in FIG. 21, the terrace portion of the upper tier T_{UCA} is thickened (step ST115). Specifically, the sacrificial member 54b is formed on each of the sacrificial members 52 of the upper tier T_{UCA} and each of the sacrificial members 52b of the upper terrace area of the lower tier T_{LCA}. The shape of the set of the sacrificial member 52c and 52d and the sacrificial member 54b corresponds to the shape of the terrace portion TP of the conductive layer 24c or 24d of the upper tier T_{UCA}. The shape of the set of the sacrificial member 52b and the sacrificial member 54b corresponds to the shape of the terrace portion TPa of the conductive layer 24b. Each of the terrace portion TP of the sacrificial member 52c or 52d and the terrace portion TPa of the sacrificial member 52b is separated from the terrace portion TP or TPa of the adjacent sacrificial member 52 in plan view.

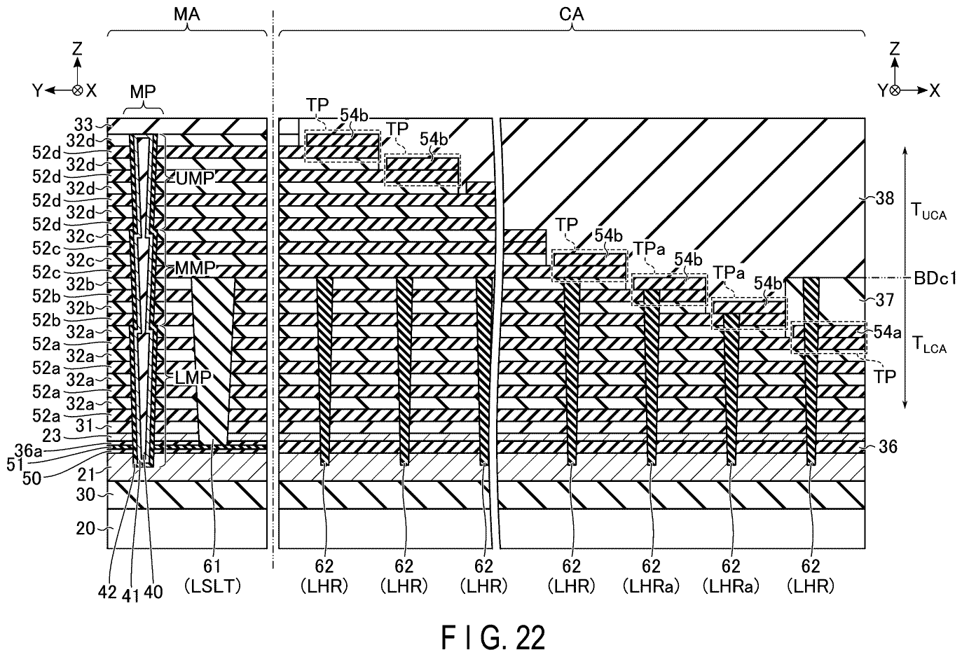

Next, as shown in FIG. 22, embedding and flattening step differences of the upper tier T_{UCA} are executed (step ST116). Specifically, first, the insulating layer 38 is formed so that the staircase structure formed in the upper tier T_{UCA} is embedded. Then, for example, a part of the insulating layer 38 is removed by CMP processing. As a result, the upper surface of the insulating layer 33 in the memory area MA and the upper surface of the insulating layer 38 in the contact area CA are aligned (flattened).

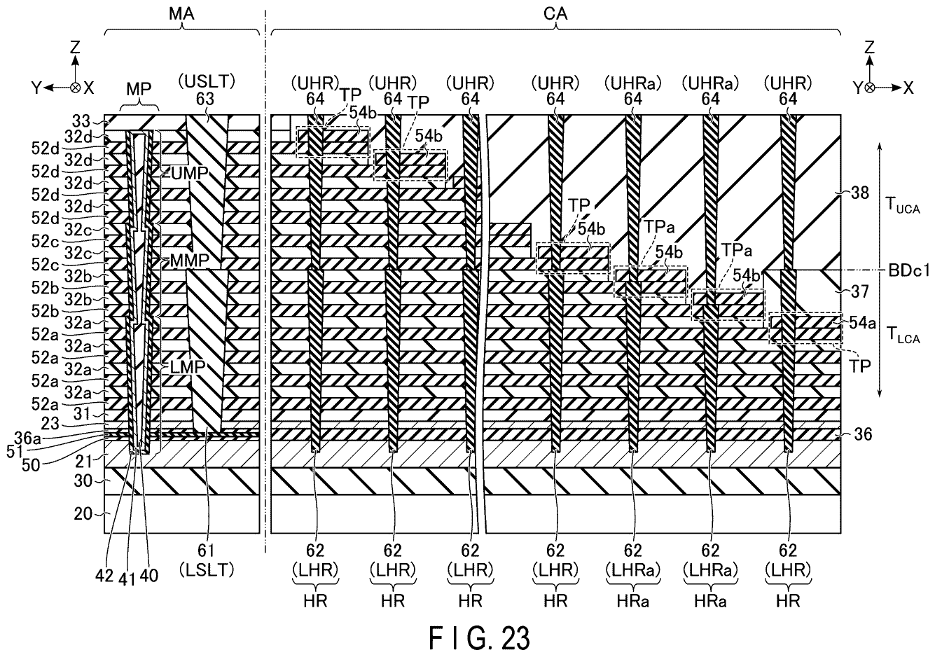

Next, as shown in FIG. 23, UHR and USLT processing, and member embedding are executed (step ST117). Specifically, the slit corresponding to the upper member USLT is formed so as to penetrate the sacrificial members 52c, 52d, and 54b, and the insulating layers 32c, 32d, and 33, and reach the sacrificial member 61 of the lower member LSLT with which the bottom thereof is associated. Then, the sacrificial member 63 is embedded in the slit corresponding to the upper member USLT. The sacrificial member 63 contains, for example, any of carbon, silicon, and a metal material. Furthermore, in the processing of step ST117, a plurality of holes corresponding to the plurality of upper support pillar UHR is formed to penetrate, for example, the sacrificial members 52c, 52d, and 54b, and the insulating layers 32c, 32d, 33, and 38, and reach the insulating member 62 of the lower support pillar LHR with which the bottom thereof is associated. In a case where the plurality of holes corresponding to the plurality of upper support pillars UHR overlap the terrace portion TP of the lower tier T_{LCA}, the plurality of holes are formed so as to penetrate the insulating layer 38, and reach the insulating member 62 of the lower support pillar LHR with which the bottom thereof is associated. Furthermore, a hole corresponding to the upper support pillar UHRa is formed, for example, to penetrate the insulating layer 38, and the associated sacrificial member 54b of the terrace portion TPa, and reach the insulating member 62 of the lower support pillar LHRa with which the bottom thereof is associated. Then, the insulating member 64 is embedded in the plurality of holes corresponding to the plurality of upper support pillars UHR or UHRa. The insulating member 64 contains, for example, silicon oxide. Note that the order of processing and embedding of the upper support pillar UHR and the upper member USLT is any order.

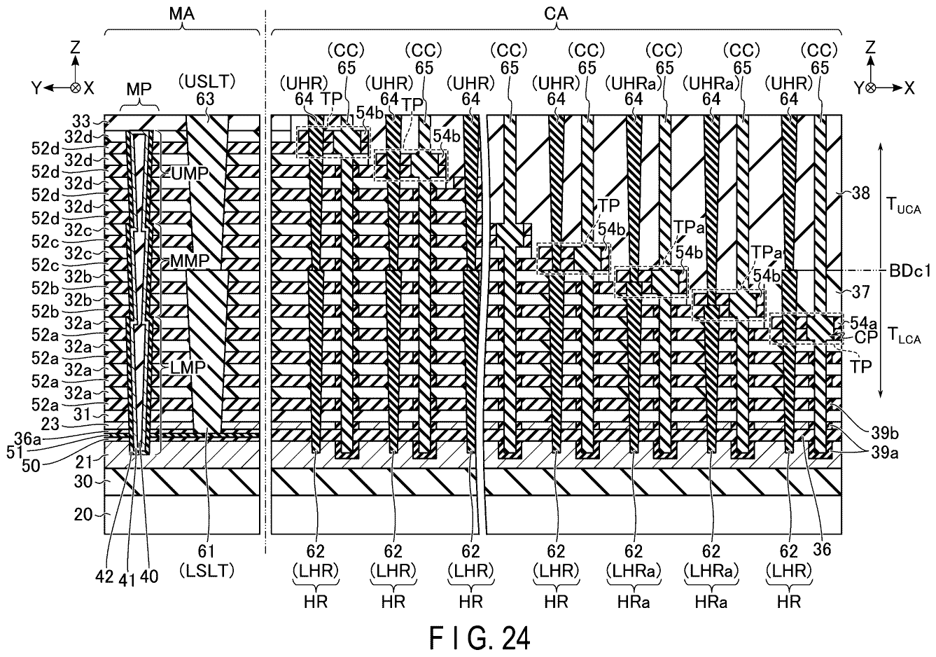

Next, as shown in FIG. 24, CC processing and sacrificial member embedding are executed (step ST118). Specifically, first, a plurality of holes corresponding to a plurality of contact plugs CC is formed, for example, so as to penetrate the sacrificial members 52 and 54, the insulating layers 32, 36, 37, and 38, and the semiconductor layer 23, and such that the bottom thereof reaches the semiconductor layer 21. Then, a part of the semiconductor layers 21 and 23 are oxidized via the plurality of holes corresponding to the plurality of contact plugs CC. As a result, the insulating layer 39a is formed at a portion of the semiconductor layers 21 and 23 that is in contact with the hole. Next, recess processing of the sacrificial members 52 and 54 is performed via the plurality of holes corresponding to the plurality of contact plugs CC, and the insulating layer 39b is formed in the plurality of holes. At this time, in a portion where the sacrificial member 52 is recessed in a layer different from the terrace portion TP or TPa, the insulating layer 39b is substantially completely embedded. On the other hand, in a portion where the sacrificial members 52 and 54 corresponding to the terrace portion TP or TPa are recessed, the insulating layer 39b is formed along the recessed portion. Then, the insulating layer 39b provided on each of the side surfaces of the plurality of holes and the terrace portion TP or TPa is removed. As a result, a structure in which the insulating layer 39b remains in a portion where the sacrificial member 52 is recessed in a layer different from the terrace portion TP or TPa is formed. Thereafter, the sacrificial member 65 is embedded in the plurality of holes corresponding to the plurality of contact plugs CC.

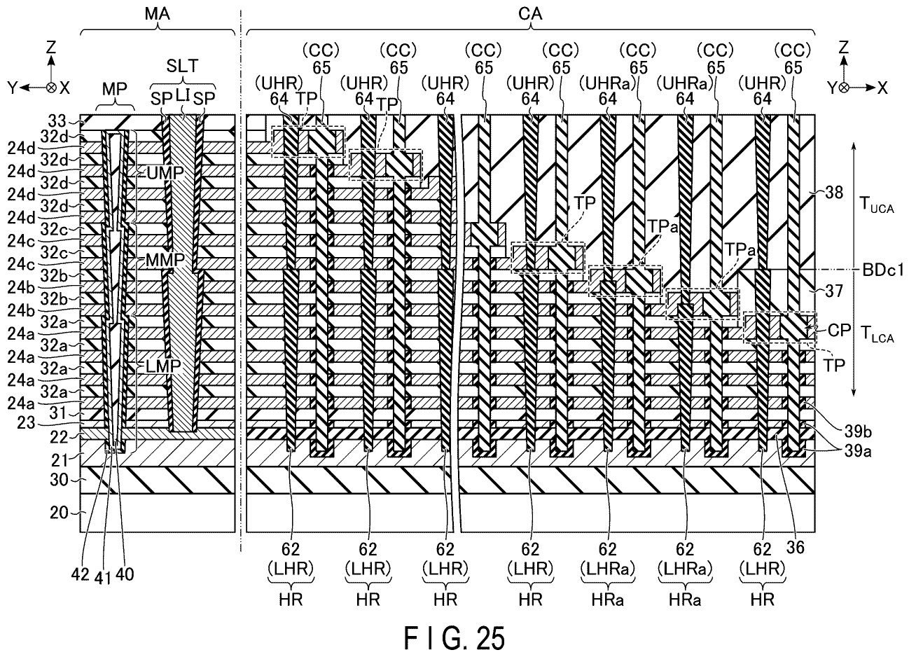

Next, as shown in FIG. 25, the SL replacement and the WL replacement are executed (step ST119). Specifically, first, the sacrificial member 61 of the lower member LSLT and the sacrificial member 63 of the upper member ULST are removed, and the slit corresponding to the member SLT is opened. Then, by the SL replacement, the insulating layers 50 and 36a and the sacrificial member 51 of the memory area MA are replaced with the semiconductor layer 22. Then, the sacrificial members 52 and 54 of the memory area MA and the contact area CA are replaced with the conductive layer 24 by the WL replacement.

In the SL replacement, first, an insulating film is formed on a side surface of the opened slit, and an insulating film at the bottom of the slit is removed. Then, the sacrificial member 51 is removed through the slit corresponding to the member SLT by wet etching. Subsequently, the insulating layers 50 and 36a are removed through the slits corresponding to the members SLT by wet etching. At this time, in each memory pillar MP, the stacked film 42 located in the same layer as the sacrificial member 51 is also removed at the same time. Then, the semiconductor layer 22 is embedded in the area from which the insulating layers 50 and 36a and the sacrificial member 51 are removed. Thereafter, the excess semiconductor layer 22 is removed on each of the side surface of the slit corresponding to the member SLT and above the insulating layer 33.

In the WL replacement, first, the insulating film on the side surface of the slit is removed. Then, the sacrificial members 52 (52a to 52d) and 54 (54a and 54b) are removed through the slit corresponding to the member SLT by wet etching. Then, the conductive layer 24 is embedded in the area where each of the sacrificial members 52 and 54 is removed. Thereafter, the excess conductive layer 24 is removed on each of the side surface and the bottom of the slit corresponding to the member SLT and above the insulating layer 33. When the WL replacement is completed, the spacer SP is formed in the slit corresponding to the member SLT, and the spacer SP at the bottom of the slit is removed. Then, the conductive member LI is formed in the slit.

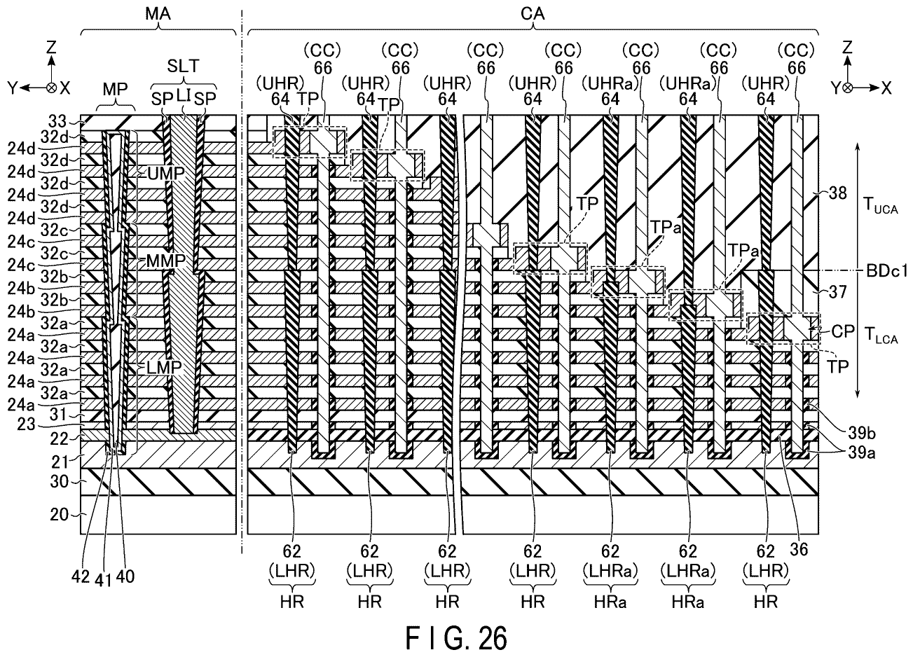

Next, as shown in FIG. 26, CC sacrificial member removal and conductive member embedding are executed (step ST121). Specifically, first, the sacrificial member 65 in the plurality of holes corresponding to the plurality of contact plugs CC is removed. Then, the conductive member 66 is embedded in the plurality of holes corresponding to the plurality of contact plugs CC. As a result, each contact plug CC is electrically connected to the terrace portion TP or TPa of the associated conductive layer 24, and the structure of the memory cell array 10 described with reference to FIGS. 4 to 8 is completed.

### <1-3> Advantageous Effects of the First Embodiment

By using the memory device 1 according to the first embodiment described hereinabove, the chip size can be reduced, and the manufacturing cost of the memory device 1 can be reduced. Advantageous effects of the memory device 1 according to the first embodiment will now be described using a first comparative example.

In the three-dimensional stacked NAND flash memory, the difficulty of processing the memory pillar MP, the member SLT, the support pillar HR, and the contact plug CC increases as the number of stacked word lines WL increases. Therefore, each of the memory pillar MP, the member SLT, the support pillar HR, and the contact plug CC may be processed in a plurality of tiers. For example, the respective tiers of the memory pillar MP, the member SLT, and the support pillar HR are set to the same number. On the other hand, the difficulty level of processing differs for each of the memory pillar MP, the member SLT, the support pillar HR, and the contact plug CC. Therefore, the suitable number of tiers of each configuration varies depending on the difficulty level of processing. When the number of tiers is set in accordance with the memory pillar MP, the number of tiers (the number of times of processing) of the member SLT and the support pillar HR may be different from a suitable number of tiers. In this case, the number of manufacturing processes and the manufacturing cost of the memory cell array 10 may increase.

On the other hand, in the memory device 1 according to the first embodiment, the number of tiers of the memory pillar MP is different from the number of tiers of the member SLT, the support pillar HR, and the contact plug CC. Then, the boundary BDm corresponding to the tier of the memory pillar MP and the boundary BDc corresponding to the tier of the member SLT and the support pillar HR are set between different conductive layers 24 (wiring layers). As a result, as described with reference to FIG. 10, the distance between the memory pillar MP and the member SLT or the support pillar HR is suppressed from increasing, and the deflection of the layer stack can be suppressed. As described above, the memory device 1 according to the first embodiment can reduce the number of manufacturing processes and the manufacturing cost of the memory cell array 10 by using a more suitable number of tiers for each of the memory pillars MP, the member SLT, and the support pillars HR.

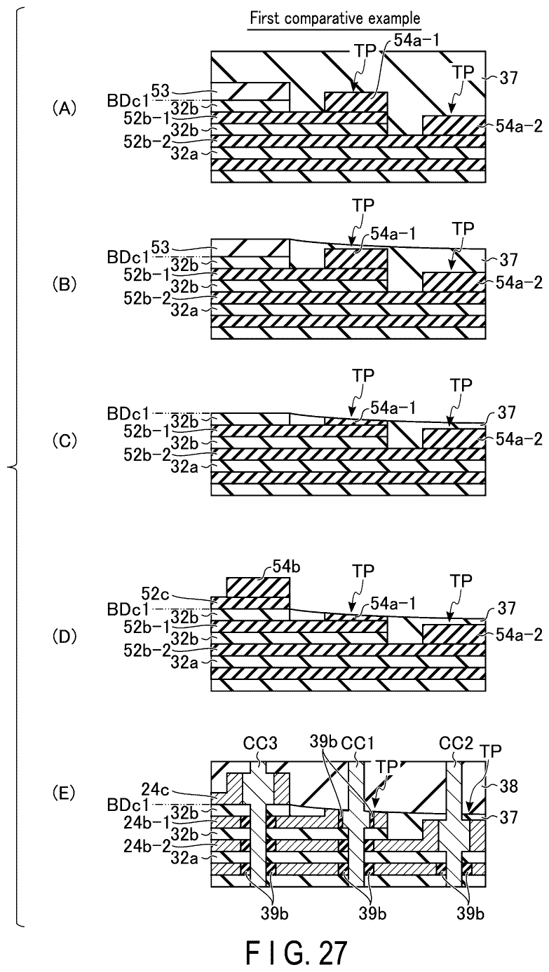

Furthermore, in the staircase structure of a plurality of tiers, the shape of the terrace portion TP of the conductive layer 24 provided in the upper portion of the lower tier T_{LCA} cannot be maintained due to a factor of the manufacturing process. FIG. 27 is a cross-sectional view showing an example of a cross-sectional structure in the vicinity of the boundary BDc1 of a layer stack in a process of manufacturing a memory device 1 according to a first comparative example. The first comparative example corresponds to a case where the processing of step ST113 is omitted in the flowchart shown in FIG. 11, the sacrificial member 52 of the lower tier T_{LCA} is subjected to the staircase shaping (terrace portion formation) of the lower tier T_{LCA}, and the sacrificial member 52 of the upper tier T_{UCA} is subjected to the staircase processing (terrace portion formation) of the upper tier T_{UCA}.

As shown in (A) of FIG. 27, in the first comparative example, the terrace portion TP of each of sacrificial members 52b-1 and 52b-2 in the upper portion of the lower tier T_{LCA} is formed at the point of time when embedding the step differences of the lower tier T_{LCA} is executed. On the sacrificial members 52b-1 and 52b-2, sacrificial members 54a-1 and 54a-2 are formed by thickening the terrace portion TP, respectively. When the flattening (CMP processing) of the lower tier T_{LCA} is executed in this state, dishing may occur in the portion of the insulating layer 37 as shown in (B) of FIG. 27. Then, when the CMP processing reaches the surface of the target insulating layer 32b, as shown in (C) of FIG. 27, for example, the uppermost sacrificial member 54b-1 (alternatively, a set of sacrificial members 54b-1 and 52-1) of the lower tier T_{LCA} may be scraped by dishing. That is, the thickness of the terrace portion TP constituted by the sacrificial members 52b-1 and 54b-1 may be thinner than the other terrace portions TP. Then, as shown in (D) of FIG. 27, the sacrificial members 52c and 54b and the like of the upper tier T_{UCA} are formed, and as shown in (E) of FIG. 27, the contact plug CC is formed after the WL replacement.

In the first comparative example, the conductive layer 24b-2 formed by replacing the sacrificial members 52b-2 and 54b-2 is connected to the contact plug CC2. In addition, the conductive layer 24c formed by replacing the sacrificial members 52c and 54b is connected to the contact plug CC3. On the other hand, in the terrace portion TP corresponding to the uppermost sacrificial member 52b-1 of the lower tier T_{LCA}, the insulating layer 39b may remain in the terrace portion TP at the time of forming the insulating layer 39b due to the insufficient film thickness by dishing. As a result, the conductive layer 24b-1 formed by replacing the sacrificial members 52b-1 and 54b-1 may be in non-contact with the contact plug CC1. In order to thicken the terrace portion TP of the conductive layer 24b in the upper portion of the lower tier T_{LCA} similarly to the terrace portions TP of the other conductive layers 24, it is conceivable to thicken the insulating layer 32b in contact with the boundary BDc1. However, increasing the thickness of the insulating layer 32b in contact with the boundary BDc1 causes an increase in the channel resistance of the memory pillar MP. Such an increase in the channel resistance of the memory pillar MP is particularly concerned in a case where the boundary BDm corresponding to between the tiers of the memory pillars MP and the boundary BDc corresponding to between the tiers of the staircase structure of the stacked wiring line are different (separated), and the thickness of the insulating layer 32b in contact with the boundary BDc1 is preferably formed to be thin as much as possible.

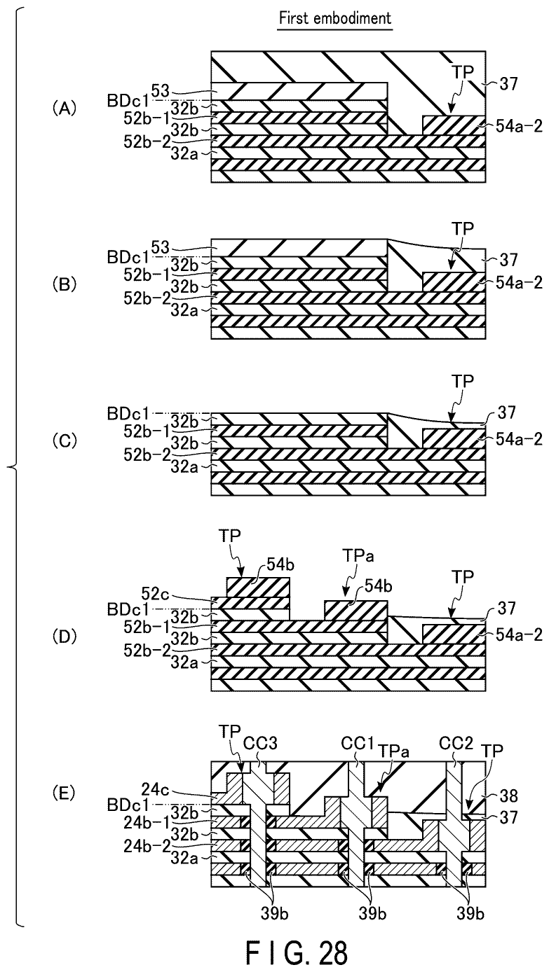

On the other hand, in the memory device 1 according to the first embodiment, the terrace portion TPa corresponding to the uppermost sacrificial member 52b-1 of the lower tier T_{LCA} is formed at the time of staircase shaping of the upper tier T_{UCA}. FIG. 28 is a cross-sectional view showing an example of a cross-sectional structure in the vicinity of a boundary of a layer stack in a process of manufacturing the memory device 1 according to the first embodiment.

As shown in (A) of FIG. 28, in the first embodiment, the terrace portion TPa of the sacrificial member 52b-1 in the upper portion of the lower tier T_{LCA} is not thickened at the point of time when the step difference embedding of the lower tier T_{LCA} is executed. Then, when the flattening (CMP processing) of the lower tier T_{LCA} is executed in this state, dishing may occur in the portion of the insulating layer 37 as shown in (B) of FIG. 28, similar to the first comparative example. On the other hand, even if the CMP processing reaches the target surface of the insulating layer 32b, the influence of dishing does not reach the terrace portion TP as shown in (C) of FIG. 28. Thereafter, as shown in (D) of FIG. 28, the sacrificial members 52c and 54b and the like of the upper tier T_{UCA} are formed, and the sacrificial member 54b is formed on the terrace portion TPa of the sacrificial member 52b of the lower tier T_{LCA} formed at the time of staircase shaping of the upper tier T_{UCA}. As a result, as shown in (E) of FIG. 28, after the WL replacement, the conductive layer 24b-1 formed by replacing the sacrificial members 52b-1 and 54b may be connected to the contact plug CC1.

As described above, in the memory device 1 according to the first embodiment, the terrace portion TPa of the conductive layer 24b of the lower tier T_{LCA} provided in the vicinity of the boundary BDc1 can be thickened similarly to the other terrace portions TP. As a result, the memory device 1 according to the first embodiment can suppress the occurrence of a defect caused by the non-connection of the contact plug CC, and can reduce the manufacturing cost of the memory device 1.

Furthermore, in the memory device 1 according to the first embodiment, the insulating layer 32b in contact with the boundary BDc1 can be formed to have substantially the same thickness as the other insulating layers 32b. In other words, in the memory device 1, the plurality of conductive layers 24a to 24d through which the memory pillars MP penetrate can be arranged at substantially equal spacing. As a result, an increase in the channel resistance of the memory pillar MP between the conductive layers 24b and 24c adjacent to each other with the boundary BDc1 interposed therebetween can be suppressed. As a result, the memory device 1 according to the first embodiment can improve the operation characteristics of the NAND string NS.

### <1-4> Modification Example of the First Embodiment

The memory device 1 according to the first embodiment can be variously modified.

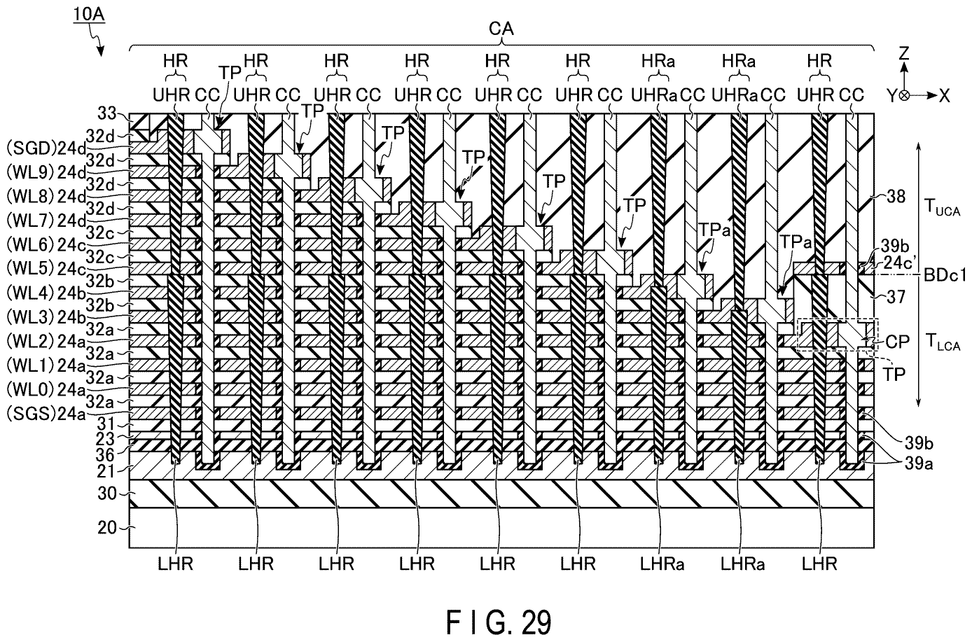

FIG. 29 is a cross-sectional view showing an example of a cross-sectional structure of the contact area CA of the memory cell array 10A included in the memory device 1 according to a modification of the first embodiment. As shown in FIG. 29, in the memory cell array 10A, a conductive layer 24c′ located in the same layer as the conductive layer 24c in the upper tier T_{UCA} is provided above the insulating layer 37 in the lower tier T_{LCA}. Then, the contact plug CC connected to the conductive layer 24a included in the lower tier T_{LCA} is provided so as to penetrate (pass through) the conductive layer 24c′. The contact plug CC connected to the conductive layer 24a and the conductive layer 24c′ are separated and insulated by the insulating layer 39b. As described above, one or more conductive layers 24 may be provided above the insulating layer 37. Then, the contact plug CC may have a portion that penetrates (passes through) one or more conductive layers 24 included in a different tier from the conductive layer 24a to be electrically connected.

In the method for manufacturing the memory device 1 according to the first embodiment, the case where the formation of the holes and the embedding of the insulating member are executed for each layer when the support pillars HR are formed has been exemplified, but the configuration is not limited thereto. For example, in the process of step ST108, a sacrificial member such as silicon or a metal material may be embedded in a hole corresponding to the lower support pillar LHR. In this case, in the process of step ST117, after a hole corresponding to the upper support pillar UHR is formed, the sacrificial member in the lower support pillar LHR is removed. Then, insulating members are collectively embedded in the holes of the lower support pillars LHR and the holes corresponding to the upper support pillars UHR connected in the Z direction. In this manner, the insulating member in the support pillar HR may be continuously provided between the lower support pillar LHR and the upper support pillar UHR.

### <2> Second Embodiment

The second embodiment relates to a case where a material different from that of the first embodiment is used in the step of forming the structure corresponding to the lower support pillar LHR. Hereinafter, the memory device 1 according to the second embodiment will be described focusing on differences from the first embodiment.

### <2-1> Configuration

First, a configuration of the memory device 1 according to the second embodiment is described.

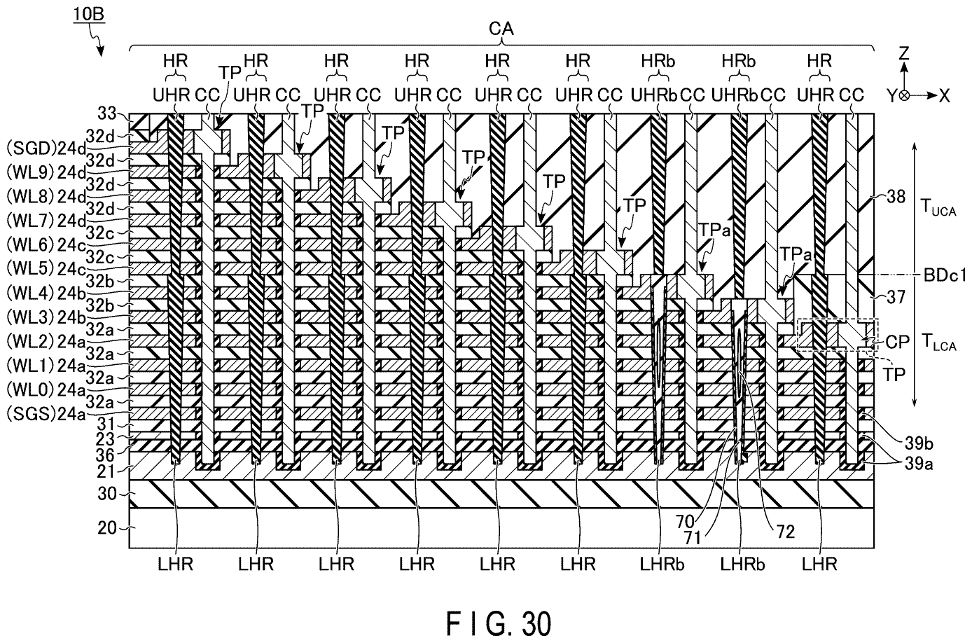

FIG. 30 is a cross-sectional view showing an example of a cross-sectional structure of the contact area CA of the memory cell array 10B included in the memory device 1 according to the second embodiment. As shown in FIG. 30, the contact area CA of the memory cell array 10B includes a configuration in which the support pillar HRa is replaced with the support pillar HRb in the memory cell array 10 of the first embodiment.

Each support pillar HRb includes a lower support pillar LHRb and an upper support pillar UHRb connected in the Z direction. The shape of the lower support pillar LHRb is substantially the same as that of the lower support pillar LHRa. The shape of the upper support pillar UHRb is substantially the same as that of the upper support pillar UHRa. The lower support pillar LHR includes an insulating film 70, an insulating member 71, and a void 72. The insulating film 70 is provided on a side surface portion of the lower support pillar LHRb and is in contact with the conductive layer 24 through which the lower support pillar LHRb penetrates (passes through). The upper end of the insulating film 70 is located, for example, between the upper surface and the lower surface of the terrace portion TPa. In the lower support pillar LHRb, the insulating member 71 is provided so as to fill the inside of the insulating film 70. The void 72 may be generated when the insulating member 71 is formed. Each of the insulating film 70 and the insulating member 71 contains, for example, silicon oxide.

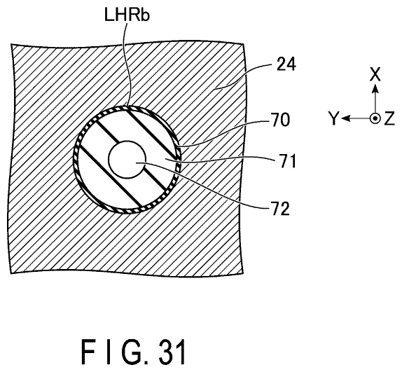

FIG. 31 is a cross-sectional view showing an example of a cross-sectional structure of the support pillar HRb included in the memory device 1 according to the second embodiment. FIG. 31 shows an XY cross section including the lower support pillar LHRb and the conductive layer 24. As shown in FIG. 31, the insulating member 71 is provided in an annular shape in plan view. The void 72 surrounded by the insulating member 71 is provided in a central portion of the lower support pillar LHRb. The insulating member 71 is surrounded by the insulating film 70. The insulating film 70 is surrounded by the conductive layer 24.

The configuration of the other parts of the memory device 1 according to the second embodiment is similar to that of the first embodiment.

### <2-2> Manufacturing Method

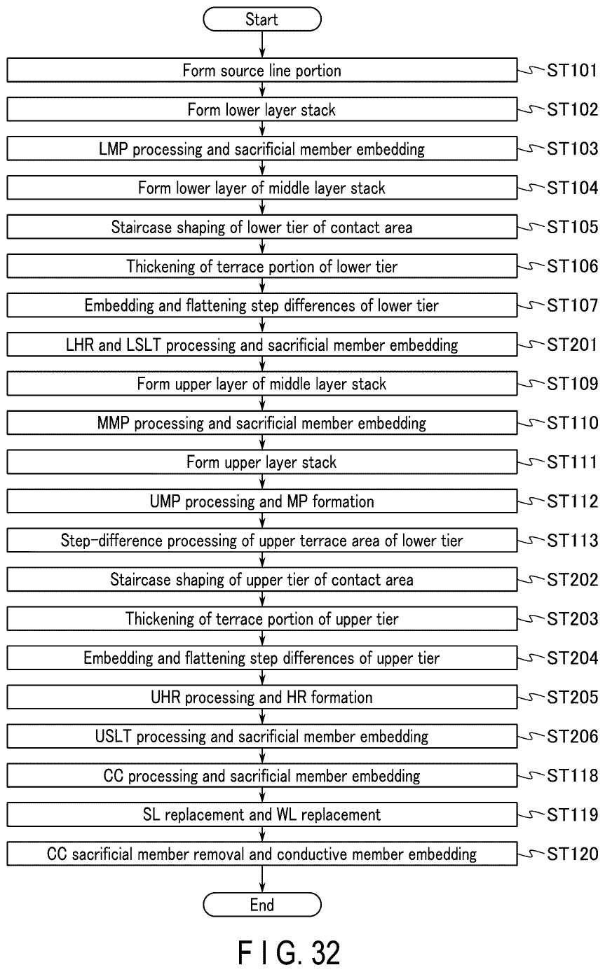

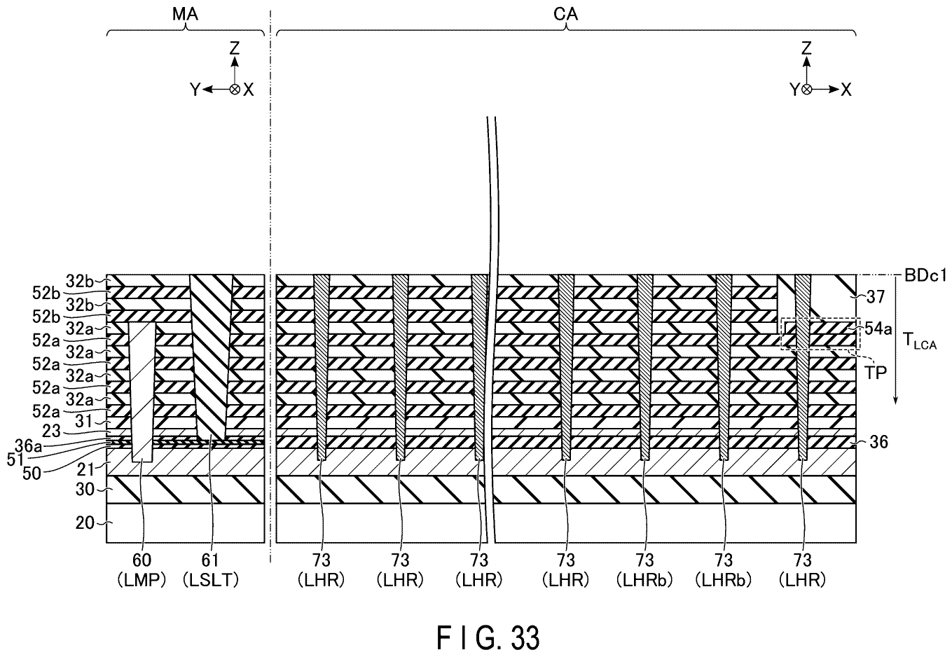

Next, as a method of manufacturing the memory device 1 according to the second embodiment, a method of forming the stacked wiring line and the contact plug CC corresponding to the memory cell array 10B will be described with reference to FIG. 32 as appropriate. FIG. 32 is a flowchart showing an example of a method of manufacturing the memory device according to the second embodiment. FIGS. 33, 34, 35, 36, 37, 38, and 39 are cross-sectional views showing examples of cross-sectional structures in the manufacturing process of the memory device 1 according to the second embodiment. Each of FIGS. 33 to 39 shows an area where the memory pillar MP and the member SLT are formed and a part of the contact area CA.

First, similarly to the first embodiment, the processing of steps ST101, ST102, ST103, ST104, ST105, ST106, and ST107 is executed in this order. That is, the source line portion is formed (step ST101), the lower layer stack is formed (step ST102), the LMP processing and the sacrificial member embedding are executed (step ST103), the lower layer of the middle layer stack is formed (step ST104), the staircase shaping of the lower tier T_{LCA} of the contact area CA is executed (step ST105), the terrace portion TP of the lower tier T_{LCA} is thickened (step ST106), and embedding and flattening step differences of the lower tier T_{LCA} are executed (step ST107). As a result, the structure described using FIG. 16 in the first embodiment is formed.

Next, as shown in FIG. 33, LHR and LSLT processing, and sacrificial member embedding are executed (step ST201). In the process of step ST201, a plurality of holes corresponding to the plurality of lower support pillars LHR or LHRb are formed similarly to step ST108 of the first embodiment. Then, the sacrificial member 73 is embedded in the plurality of holes corresponding to the plurality of lower support pillars LHR or LHRb. The sacrificial member 73 contains, for example, carbon. Details of the LSLT processing are the same as those of the first embodiment. Furthermore, the order of processing and embedding of the lower support pillar LHR and the lower member LSLT is any order.

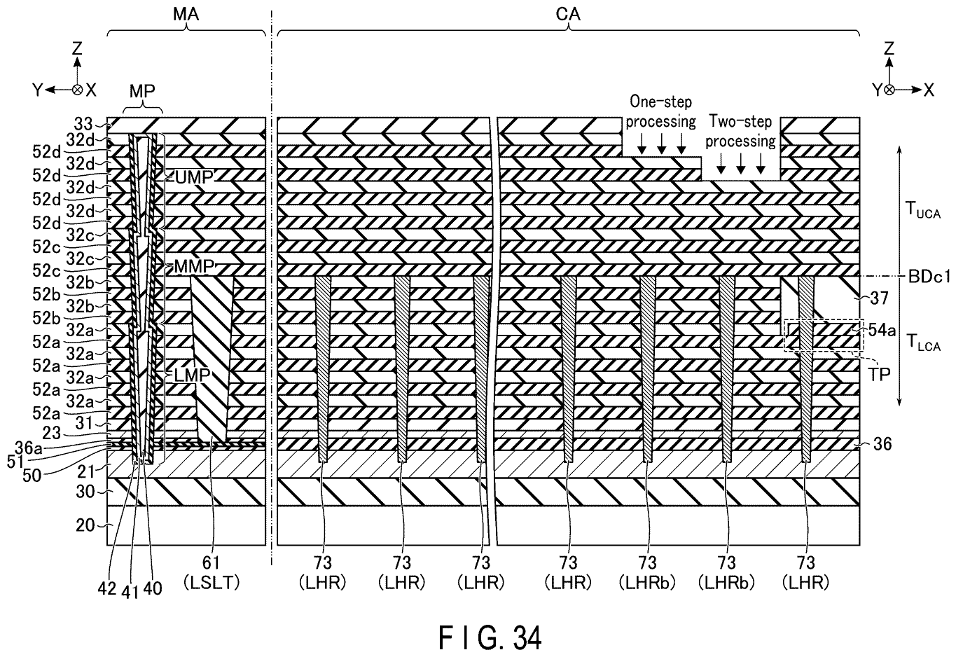

Next, similarly to the first embodiment, the processing of steps ST109, ST110, ST111, ST112, and ST113 is executed in this order. That is, the upper layer of the middle layer stack is formed (step ST109), MMP processing and sacrificial member embedding are executed (step ST110), the upper layer stack is formed (step ST111), UMP processing and MP formation are executed (step ST112), and step-difference processing of the upper terrace area of the lower tier T_{LCA} is executed (step ST113). Thereby, the structure shown in FIG. 34 is formed.

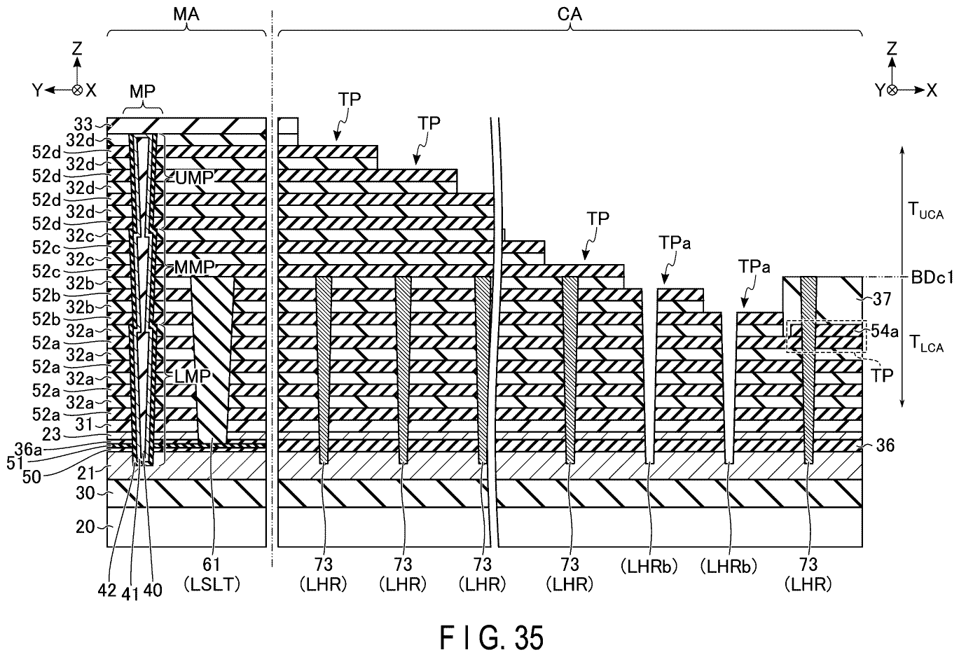

Next, staircase shaping of the upper tier T_{UCA} of the contact area CA is executed (step ST202). In the staircase shaping of the upper tier T_{UCA} in this process, similarly to the first embodiment, the upper terrace area of the lower tier T_{LCA} is also to be processed. As a result, the staircase structure of the terrace portion TP of the plurality of sacrificial members 52 (52c and 52d) is formed in the upper tier T_{UCA}, and the terrace portion TPa of at least one sacrificial member 52b is formed in the upper terrace area of the lower tier T_{LCA}. As a result, the position of the upper end of the hole corresponding to the lower support pillar LHRb is lower than the position of the upper end of the sacrificial member 73 in the lower support pillar LHR. Furthermore, in the second embodiment, as shown in FIG. 35, the sacrificial member 73 in the hole corresponding to the lower support pillar LHRb can be removed.

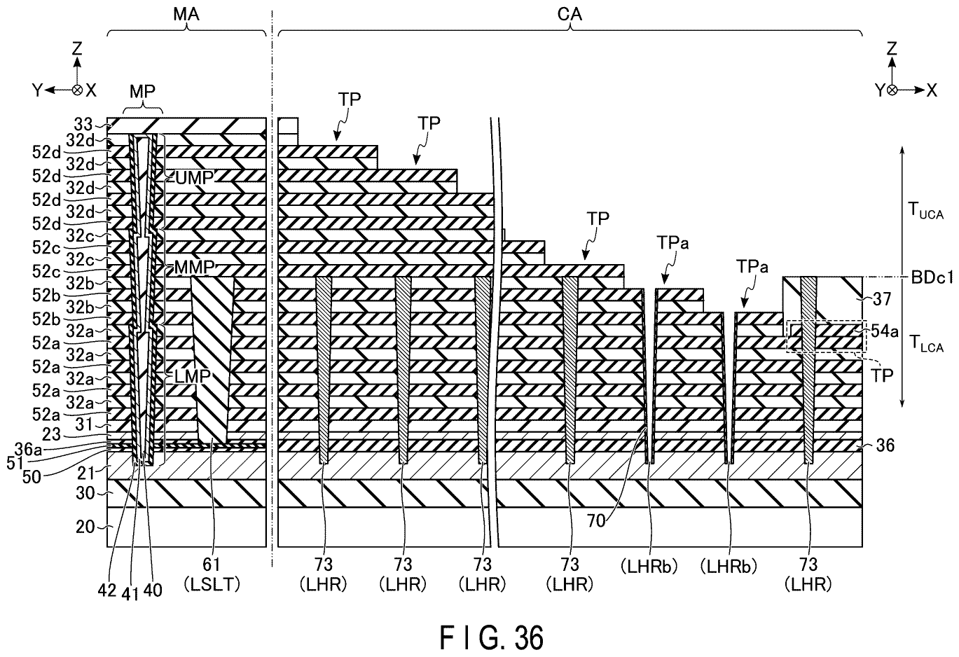

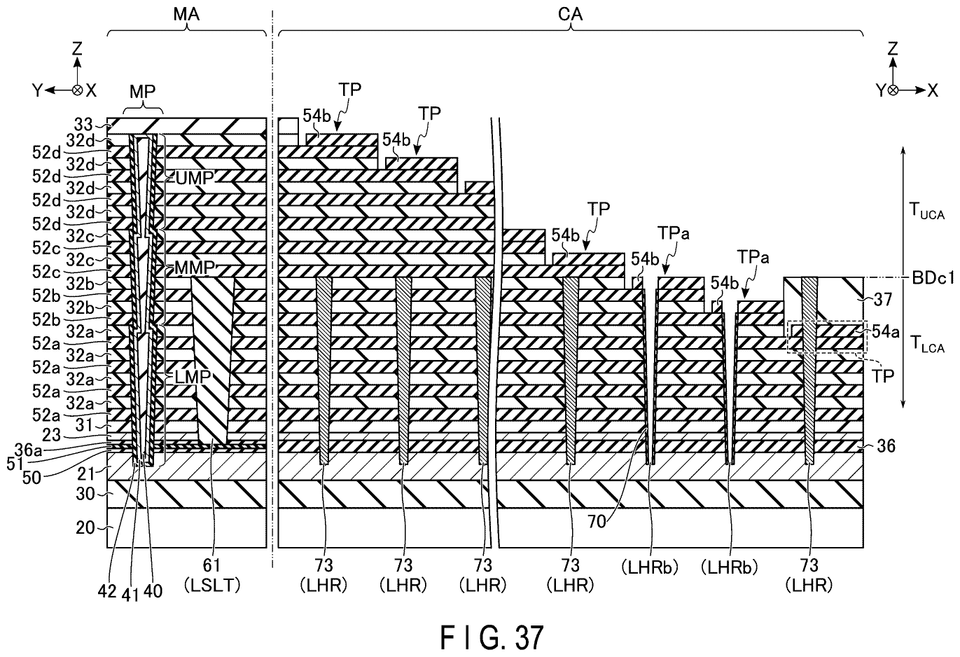

Next, the terrace portion TP of the upper tier T_{UCA} is thickened (step ST203). Specifically, first, as shown in FIG. 36, the insulating film 70 is formed on the side surface of each hole corresponding to the lower support pillar LHRb. Thereafter, as shown in FIG. 37, the sacrificial member 54b is formed on the terrace portion TP of each sacrificial member 52 (52c or 52d) of the upper tier T_{UCA}. At this time, the sacrificial member 54b is also formed on each sacrificial member 52b in the upper terrace area of the lower tier T_{LCA}. In the process of forming the sacrificial member 54b, the sacrificial member 54b is also formed in each hole corresponding to the lower support pillar LHRb. However, the sacrificial member 54b formed in each hole corresponding to the lower support pillar LHRb can be removed by the wet etching process for separating the two adjacent terrace portions TP or TPa.

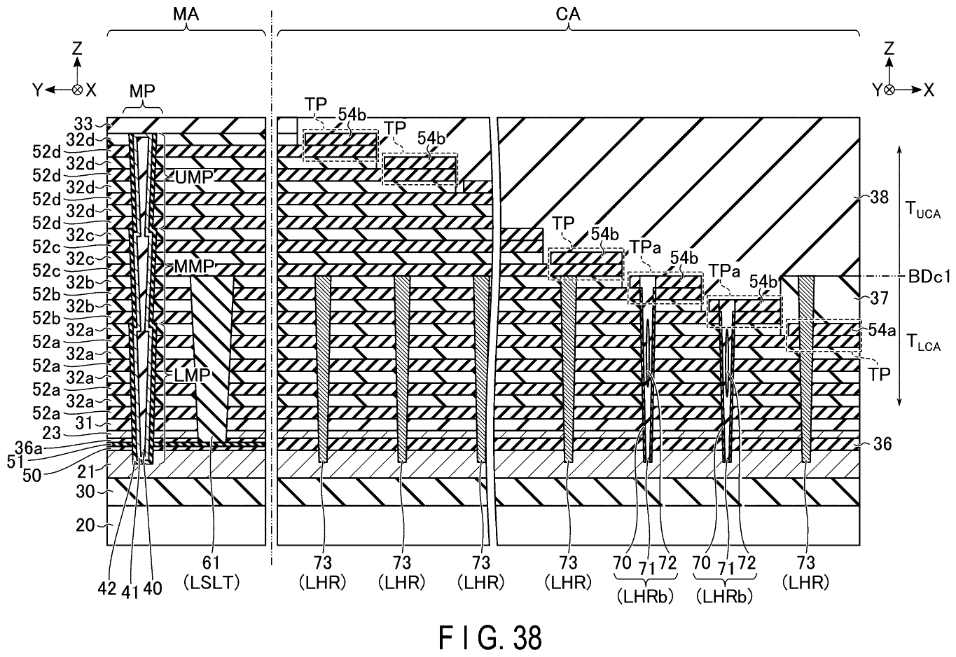

Next, as shown in FIG. 38, embedding and flattening step differences of the upper tier T_{UCA} are executed (step ST204). Specifically, first, the insulating layer 38 is formed so that the staircase structure formed in the upper tier T_{UCA} is embedded. At this time, the insulating layer 38 is also embedded in each hole corresponding to the lower support pillar LHRb. In FIG. 38, the insulating layer 38 embedded in each hole corresponding to the lower support pillar LHRb is shown as insulating member 71. By forming the insulating member 71 by this step, the void 72 can remain in each hole corresponding to the lower support pillar LHRb. Thereafter, for example, a part of the insulating layer 38 is removed by CMP processing. As a result, the upper surface of the insulating layer 33 in the memory area MA and the upper surface of the insulating layer 38 in the contact area CA are aligned (flattened).

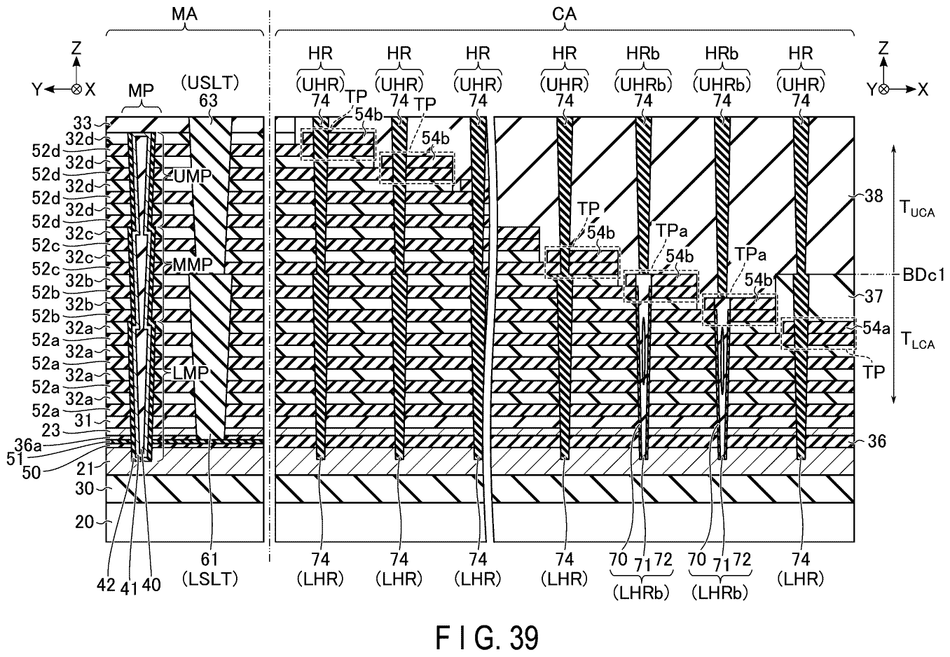

Next, the structure shown in FIG. 39 is formed by executing the processing of steps ST205 and ST206.

In the processing of step ST205, UHR processing and HR formation are executed. Specifically, first, a plurality of holes corresponding to the plurality of upper support pillars UHR or UHRb are formed similarly to step ST117 of the first embodiment. At this time, the insulating member 71 in the associated lower support pillar LHRb is exposed at the bottom of the hole corresponding to the upper support pillar UHRb. In addition, the sacrificial member 73 in the associated lower support pillar LHR is removed via the hole associated with the upper support pillar UHR. Then, insulating members 74 are collectively embedded in the holes of the lower support pillars LHR and the holes corresponding to the upper support pillars UHR connected in the Z direction. At this time, the insulating member 74 is also embedded in each hole corresponding to the upper support pillar UHRb. As a result, the plurality of support pillars HR and HRb are formed.

In the processing of step ST206, USLT processing and sacrificial member embedding are executed. Specifically, the slit corresponding to the upper member USLT is formed similarly to step ST117 of the first embodiment. Then, the sacrificial member 63 is embedded in the slit corresponding to the upper member USLT. Note that the order of the processing of step ST205 and the processing of step ST206 may be interchanged.

Thereafter, similarly to the first embodiment, the processing of steps ST118, ST119, and ST120 is executed in this order. That is, CC processing and sacrificial member embedding are executed (step ST118), the SL replacement and WL replacement are executed (step ST119), and CC sacrificial member removal and conductive member embedding are executed (step ST120), thereby completing the structure of the memory cell array 10B described using FIGS. 30 to 31.

Other processing of method of manufacturing the memory device 1 according to the second embodiment is similar to that of the first embodiment.

### <2-3> Advantageous Effects of Second Embodiment

As described above, after the hole corresponding to the lower support pillar LHR is formed, the sacrificial member 73 that can be removed during the staircase shaping of the upper tier T_{UCA} may be embedded in the hole. In such a case, similarly to the first embodiment, the terrace portion TPa of the conductive layer 24b of the lower tier T_{LCA} provided in the vicinity of the boundary BDc1 can be thickened similarly to the other terrace portions TP. Furthermore, similarly to the first embodiment, the insulating layer 32b in contact with the boundary BDc1 can be formed to have substantially the same thickness as the other insulating layers 32b. As a result, the memory device 1 according to the second embodiment can reduce the manufacturing cost of the memory device 1 and improve the operation characteristics of the NAND string NS, similarly to the first embodiment.

### <3> Third Embodiment

The third embodiment relates to a case where the insulating layer 32 in contact with the boundary BDc1 is provided to be thick, and the terrace portion TPa similar to that of the first embodiment is formed. Hereinafter, the memory device 1 according to the third embodiment will be described focusing on differences from the first and second embodiments.

### <3-1> Configuration

First, a configuration of the memory device 1 according to the third embodiment is described.

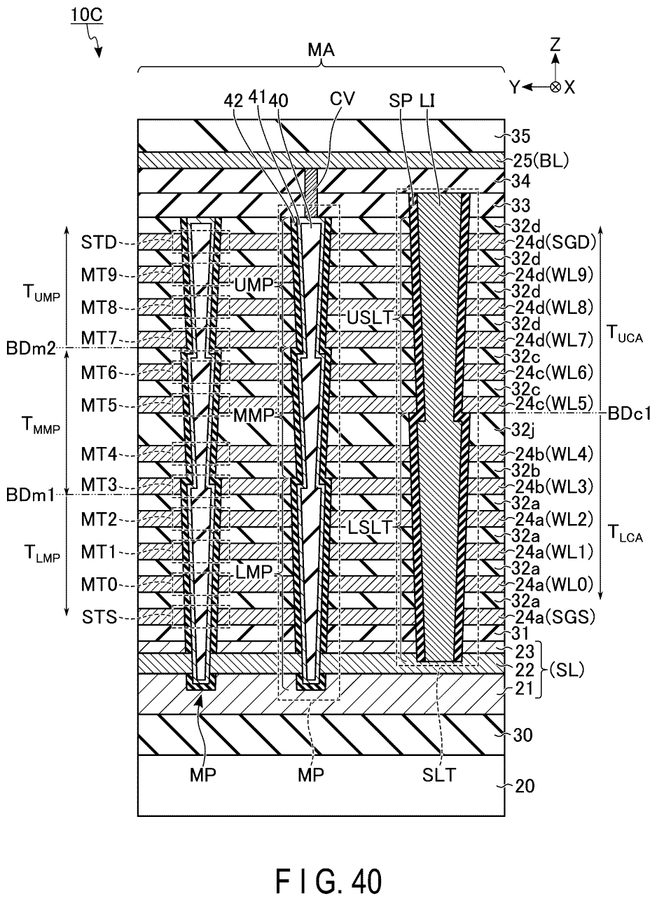

FIG. 40 is a cross-sectional view showing an example of a cross-sectional structure of the memory area MA of the memory cell array 10C included in the memory device 1 according to the third embodiment. As shown in FIG. 40, the memory area MA of the memory cell array 10C includes a configuration in which the uppermost insulating layer 32b included in the lower tier T_{LCA} is replaced with an insulating layer 32j in the memory cell array 10 of the first embodiment. The thickness of the insulating layer 32j in the Z direction is thicker than the other insulating layers 32. Therefore, spacing in the Z direction between the conductive layers 24b and 24c adjacent to each other with the boundary BDc1 interposed therebetween is larger than spacing in the Z direction between two conductive layers 24 adjacent to each other without the boundary BDc1 interposed therebetween. In other words, spacing in the Z direction between the conductive layer 24b of one layer adjacent to the boundary BDc1 and the conductive layer 24c adjacent to the conductive layer 24b of one layer in the Z direction among the plurality of conductive layers 24c is wider than spacing between two conductive layers 24 included in the lower tier T_{LCA} and adjacent in the Z direction among the plurality of conductive layers 24. The insulating layer 32j may contain a plurality of insulating layers. The lower member LSLT may have a shape in which the width is widened at a portion intersecting the insulating layer 32j.

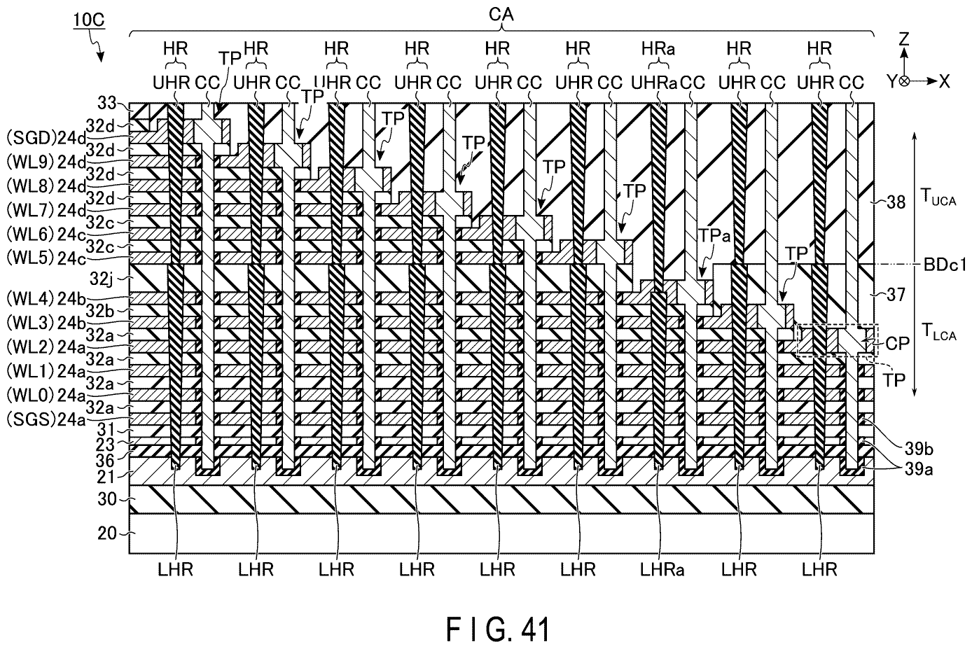

FIG. 41 is a cross-sectional view showing an example of a cross-sectional structure of the contact area CA of the memory cell array 10C included in the memory device 1 according to the third embodiment. As shown in FIG. 41, the contact area CA of the memory cell array 10C includes a configuration in which the uppermost insulating layer 32b included in the lower tier T_{LCA} is replaced with the insulating layer 32j in the memory cell array 10 of the first embodiment. In the memory cell array 10C, one terrace portion TPa is provided for each block BLK, and a plurality of terrace portions TPa are not provided for each block BLK. Above the terrace portion TPa of the conductive layer 24, the insulating layer 32j is removed, and the insulating layer 38 is embedded.

The configuration of the other parts of the memory device 1 according to the third embodiment is similar to that of the first embodiment.

### <3-2> Manufacturing Method

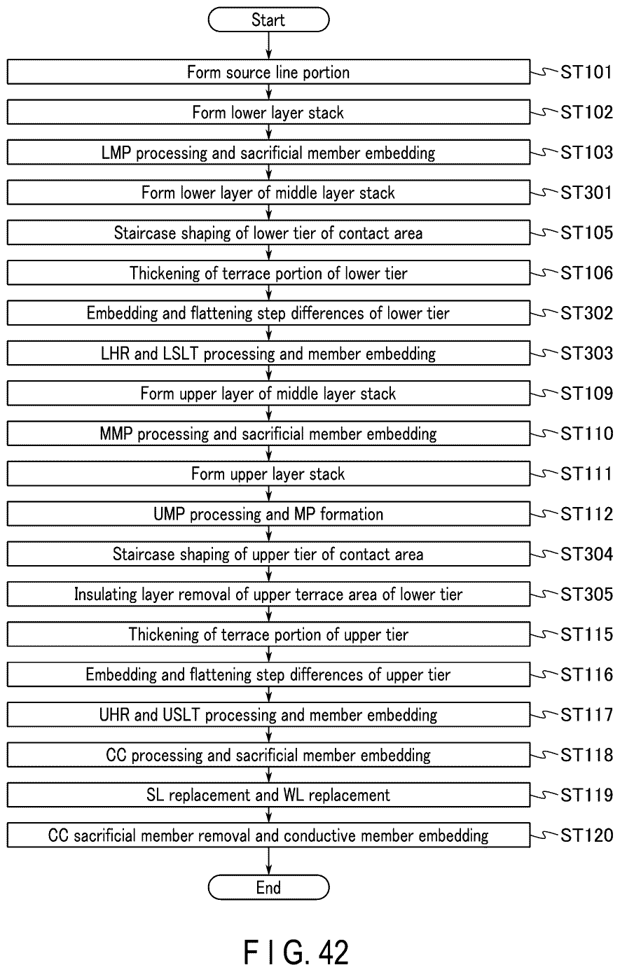

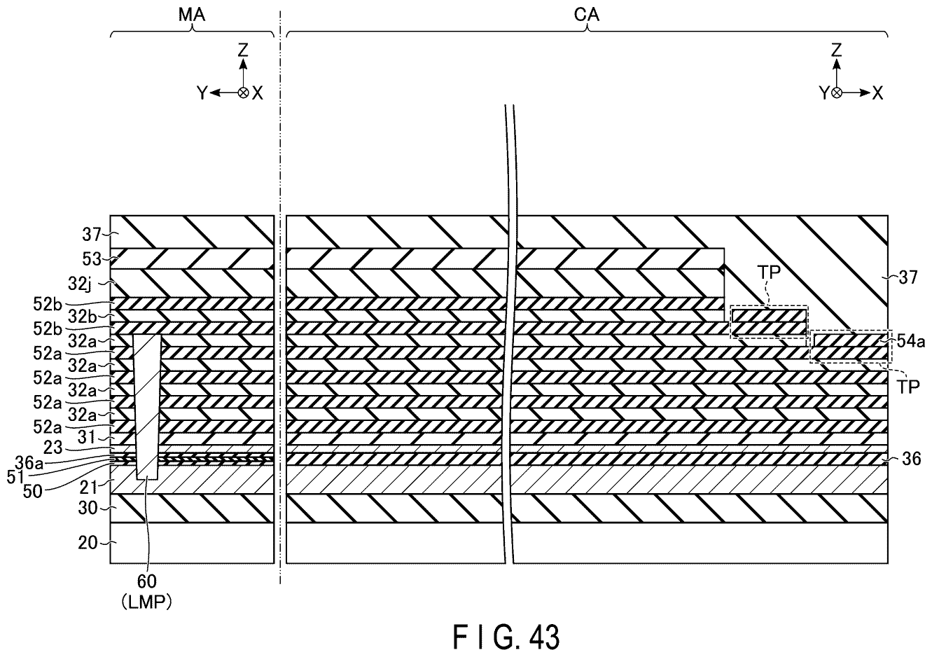

Next, as a method of manufacturing the memory device 1 according to the third embodiment, a method of forming the stacked wiring line and the contact plug CC corresponding to the memory cell array 10C will be described with reference to FIG. 42 as appropriate. FIG. 42 is a flowchart showing an example of a method of manufacturing the memory device 1 according to the third embodiment. FIGS. 43, 44, 45, 46, 47, 48, and 49 are cross-sectional views showing examples of cross-sectional structures in the manufacturing process of the memory device 1 according to the third embodiment. Each of FIGS. 43 to 49 shows an area where the memory pillar MP and the member SLT are formed and a part of the contact area CA.

First, similarly to the first embodiment, the processing of steps ST101, ST102, and ST103 is executed in this order. That is, a source line portion is formed (step ST101), a lower layer stack is formed (step ST102), and LMP processing and sacrificial member embedding are executed (step ST103).

Next, a lower layer of the middle layer stack is formed (step ST301). Specifically, as the lower layer of the middle layer stack, first, the sacrificial member 52b associated with the conductive layer 24b and the insulating layer 32b are alternately stacked on the lower layer stack. Then, the insulating layer 32j is formed on the uppermost sacrificial member 52b. Then, the member 53 is formed on the insulating layer 32j. Thereafter, similarly to the first embodiment, the staircase shaping of the lower tier T_{LCA} of the contact area CA is executed (step ST105), and the terrace portion TP of the lower tier T_{LCA} is thickened (step ST106).

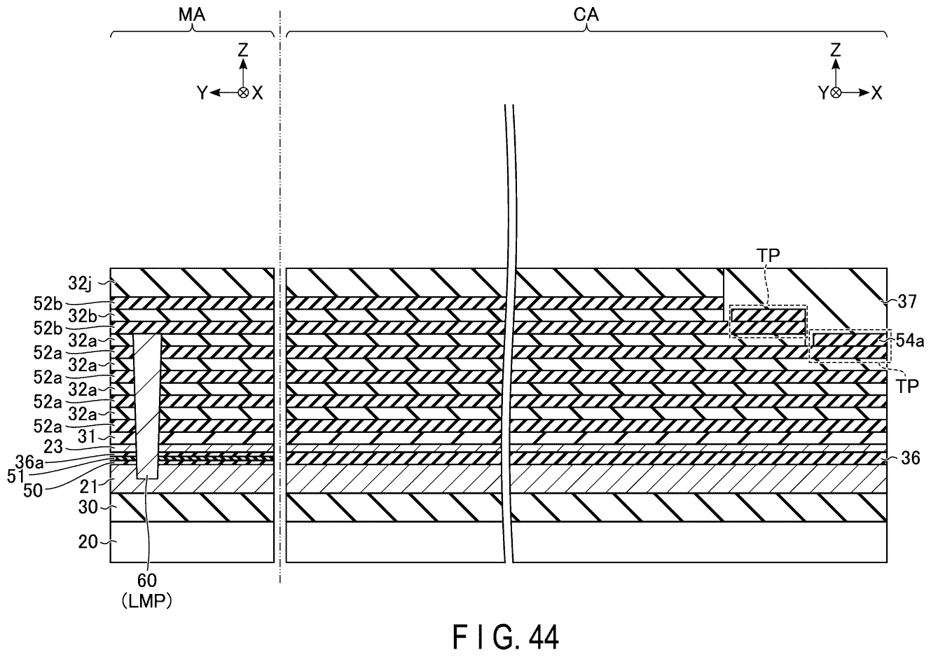

Next, embedding and flattening step differences of the lower tier T_{LCA} are executed (step ST302). Specifically, first, as shown in FIG. 43, the insulating layer 37 is formed so that the staircase structure formed in the lower tier T_{LCA} is embedded. Then, for example, as shown in FIG. 44, the member 53 and a part of the insulating layer 37 are removed by CMP processing. As a result, the upper surface of the uppermost insulating layer 32j in the memory area MA and the upper surface of the insulating layer 37 in the contact area CA are aligned (flattened).

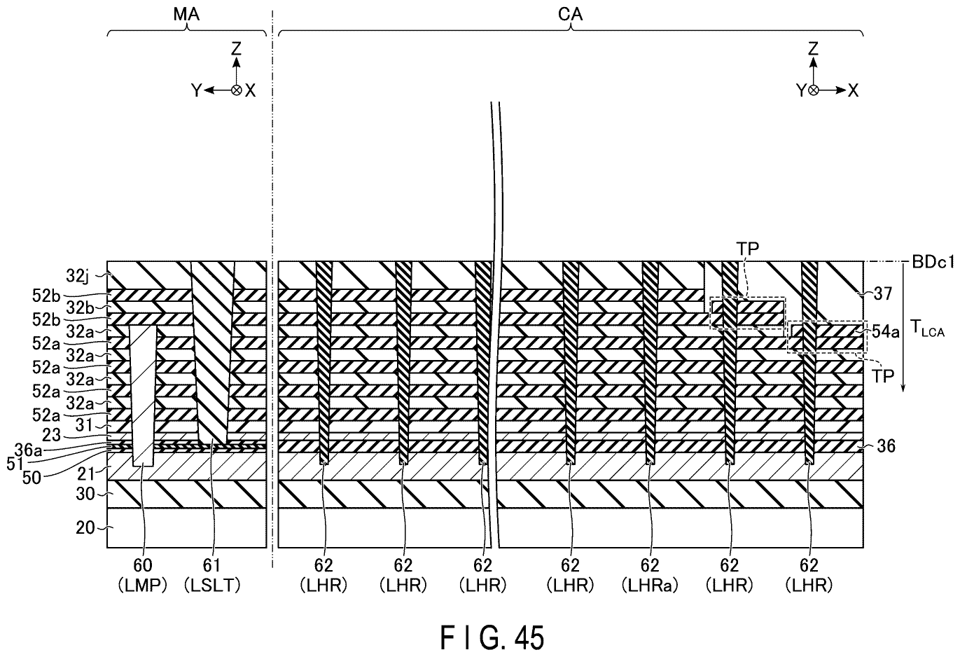

Next, as shown in FIG. 45, LHR and LSLT processing, and member embedding are executed (step ST303). Specifically, the slit corresponding to the lower member LSLT is formed so as to penetrate the sacrificial members 52a and 52b, the semiconductor layer 23, and the insulating layers 31, 32a, 32b, 32j, and 36a, and the bottom thereof reaches the sacrificial member 51. Then, the sacrificial member 61 is embedded in the slit corresponding to the lower member LSLT. Furthermore, in the processing of step ST303, a plurality of holes corresponding to the plurality of lower support pillars LHR or LHRa is formed to penetrate, for example, the sacrificial members 52a and 52b, the semiconductor layer 23, and the insulating layers 31, 32a, 32b, 32j, and 36, and such that the bottom thereof reaches the semiconductor layer 21. In a case where the plurality of holes corresponding to the plurality of lower support pillars LHR or LHRa overlap the terrace portion TP of the lower tier T_{LCA}, the plurality of holes are formed so as to penetrate the sacrificial members 52a, 52b, and 54a, the semiconductor layer 23, and the insulating layers 31, 32a, and 36 below the associated terrace portion TP, and the insulating layer 37, and such that the bottom thereof reaches the semiconductor layer 21. Then, the insulating member 62 is embedded in the plurality of holes corresponding to the plurality of lower support pillars LHR or LHRa. At this time, the insulating member 62 corresponding to the lower support pillar LHRa is formed with the same structure as the insulating member 62 corresponding to the plurality of lower support pillars LHR. Note that the order of processing and member embedding of the lower support pillar LHR and the lower member LSLT is any order.

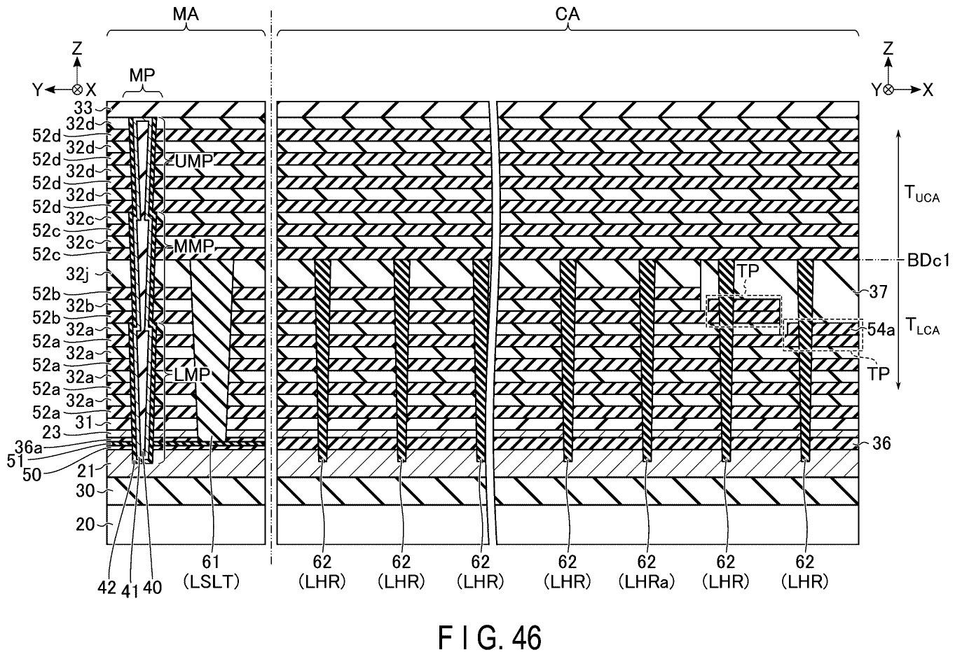

Next, similarly to the first embodiment, the processing of steps ST109, ST110, ST111, and ST112 is executed in this order. That is, the upper layer of the middle layer stack is formed (step ST109), MMP processing and sacrificial member embedding are executed (step ST110), the upper layer stack is formed (step ST111), and UMP processing and MP formation are executed (step ST112). Thereby, the structures shown in FIG. 46 is formed.

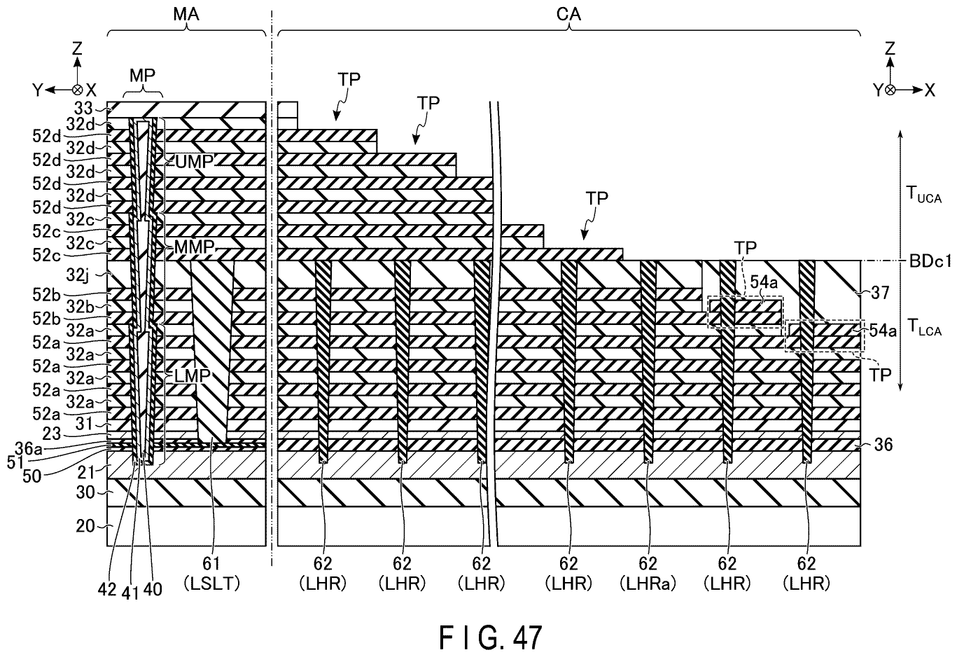

Next, as shown in FIG. 47, staircase shaping of the upper tier T_{UCA} of the contact area CA is executed (step ST304). As a result, the staircase structure of the plurality of terrace portions TP of the plurality of sacrificial members 52 (52c and 52d) is formed in the upper tier T_{UCA}. In the third embodiment, since the step-difference processing of the upper terrace area of the lower tier T_{LCA} described in the first embodiment is not executed, the terrace portion TPa of the sacrificial member 52b is not formed by the processing of step ST304.

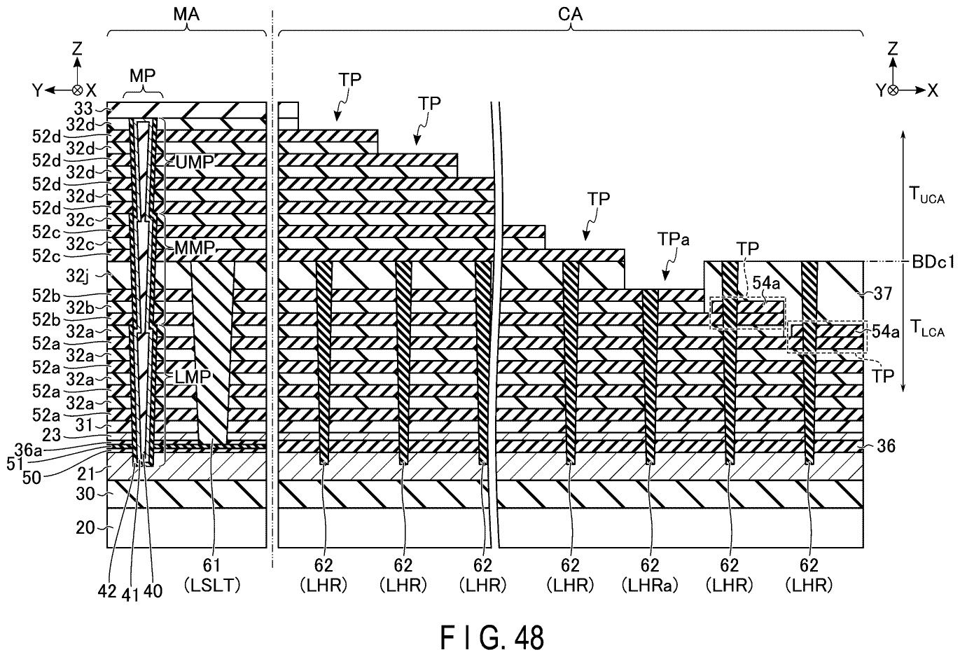

Next, as shown in FIG. 48, insulating layer removal of the upper terrace area of the lower tier T_{LCA} is executed (step ST305). Specifically, after forming a mask in which the upper terrace area of the lower tier T_{LCA} is opened, anisotropic etching processing for the insulating layer 32j is executed. As a result, the surface of the terrace portion TPa of the sacrificial member 52b is exposed in the upper terrace area of the lower tier T_{LCA}. In addition, the upper portion of the insulating member 62 in the lower support pillar LHRa provided so as to penetrate the terrace portion TPa is also processed. As a result, the position of the upper end of the insulating member 62 in the lower support pillar LHRa is lower than the position of the upper end of the insulating member 62 in the lower support pillar LHR.

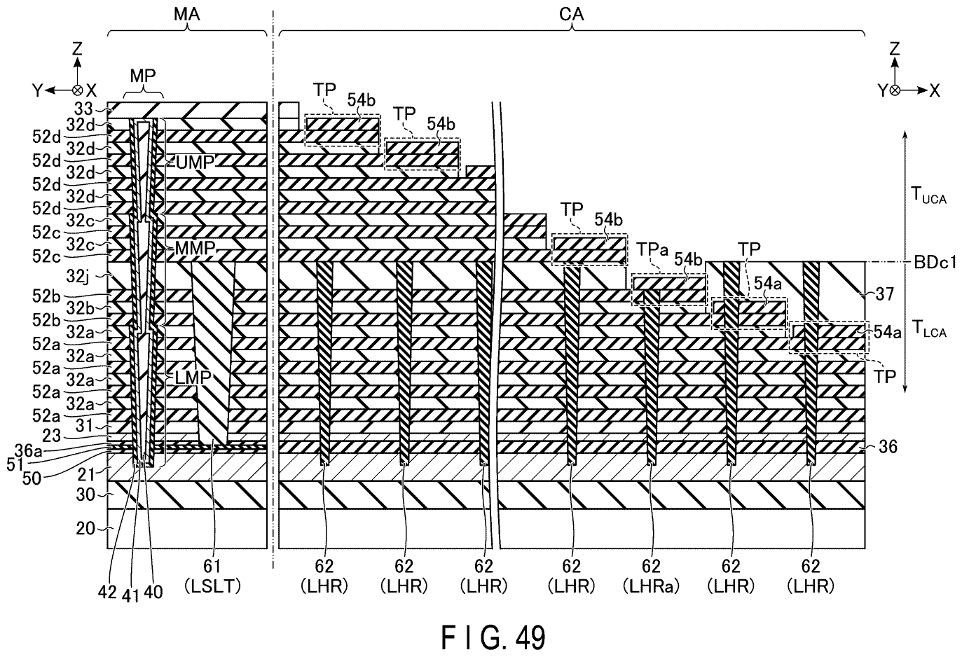

Next, similarly to the first embodiment, the terrace portion TP of the upper tier T_{UCA} is thickened (step ST115). As a result, as shown in FIG. 49, the sacrificial member 54b is formed on each of the sacrificial members 52 (52c or 52d) of the upper tier T_{UCA} and on the sacrificial member 52b of the upper terrace area of the lower tier T_{LCA}. Thereafter, similarly to the first embodiment, the processing of steps ST116, ST117, ST118, ST119, and ST120 is executed in this order. That is, embedding and flattening step differences of the upper tier T_{UCA} are executed (step ST116), UHR and USLT processing, and member embedding are executed (step ST117), CC processing and sacrificial member embedding are executed (step ST118), the SL replacement and WL replacement are executed (step ST119), and CC sacrificial member removal and conductive member embedding are executed (step ST120), thereby completing the structure of the memory cell array 10C described using FIG. 41.

Other processing of method of manufacturing the memory device 1 according to the third embodiment is similar to that of the first embodiment.

### <3-3> Advantageous Effects of Third Embodiment

As described above, the insulating layer 32j thicker than the other insulating layers 32 may be provided in the vicinity of the boundary BDc1 between the lower tier T_{LCA} and the upper tier T_{UCA}. Even in such a case, by removing the insulating layer 32j in the upper terrace area of the lower tier T_{LCA} after the formation of the staircase structure of the upper tier T_{UCA}, the terrace portion TPa can be thickened similarly to the first embodiment. As a result, similarly to the first embodiment, the memory device 1 according to the third embodiment can suppress the occurrence of a defect caused by the non-connection of the contact plug CC, and can reduce the manufacturing cost of the memory device 1.

### <4> Fourth Embodiment

The fourth embodiment relates to a case where the contact plug CC is formed in two layers in the memory device 1 according to the third embodiment. Hereinafter, the memory device 1 according to the fourth embodiment will be described focusing on differences from the first to third embodiments.

### <4-1> Configuration

First, a configuration of the memory device 1 according to the fourth embodiment is described.

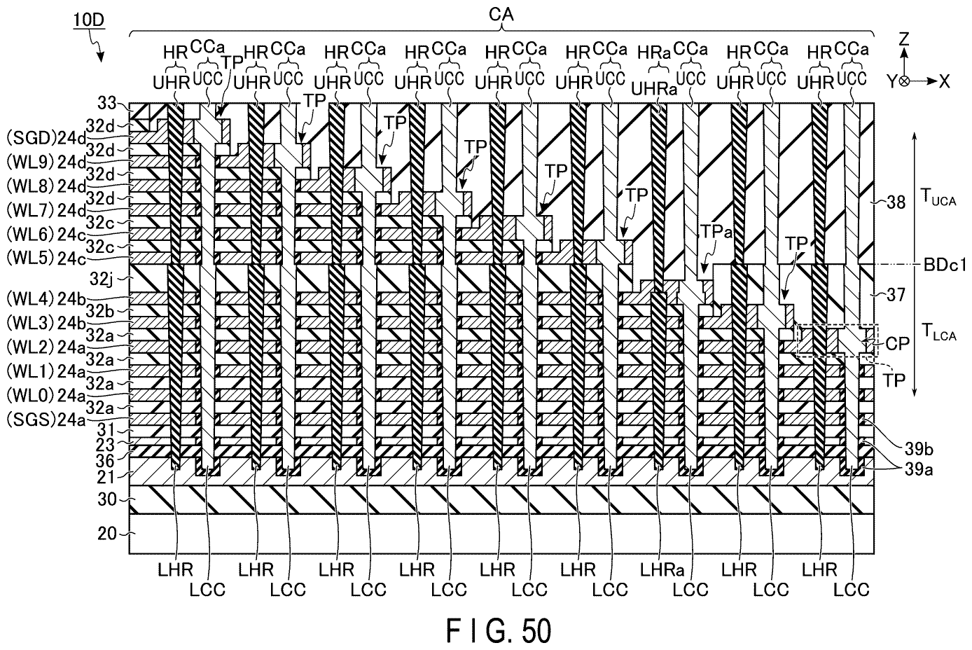

FIG. 50 is a cross-sectional view showing an example of a cross-sectional structure of the contact area CA of the memory cell array 10D included in the memory device 1 according to the fourth embodiment. As shown in FIG. 50, the contact area CA of the memory cell array 10D includes a configuration in which the contact plug CC is replaced with the contact plug CCa in the memory cell array 10 of the first embodiment.

The contact plug CCa corresponds to the contact plug CC formed in two layers. Specifically, the contact plug CCa includes a lower contact plug LCC and an upper contact plug UCC connected in the Z direction. The lower contact plug LCC is associated with the lower tier T_{LCA}. The upper contact plug UCC is associated with the upper tier T_{UCA}. In the contact plug CCa connected to the terrace portion TP of the associated conductive layer 24, the position of the boundary between the lower contact plug LCC and the upper contact plug UCC substantially coincides with the boundary BDc1. On the other hand, in the contact plug CCa connected to the terrace portion TPa of the associated conductive layer 24, the boundary between the lower contact plug LCC and the upper contact plug UCC is located lower than the boundary BDc1. Specifically, in the contact plug CCa connected to the terrace portion TPa, the boundary between the lower contact plug LCC and the upper contact plug UCC is located between the upper surface and the lower surface of the connected terrace portion TPa.

The shape of the intersection portion CP of the contact plug CCa connected to the terrace portion TPa may be different from the shape of the intersection portion CP of the contact plug CCa connected to the terrace portion TP. For example, the cross-sectional shape (diameter) of the intersection portion CP of the contact plug CCa connected to the terrace portion TPa can change more steeply in the vicinity of the boundary between the lower contact plug LCC and the upper contact plug UCC than in other portions. That is, the XY cross-sectional area of the intersection portion CP of the contact plug CCa connected to the terrace portion TPa can change more steeply in the vicinity of the boundary between the lower contact plug LCC and the upper contact plug UCC than in other portions.

The conductive member included in the contact plug CCa is continuously provided in the lower contact plug LCC and the upper contact plug UCC. Each of the lower contact plug LCC and the upper contact plug UCC has, for example, a tapered shape (normal tapered shape) in which a diameter (XY cross-sectional area) of an upper end is larger than a diameter (XY cross-sectional area) of a lower end. In other words, each of the lower contact plug LCC and the upper contact plug UCC has, for example, a truncated cone shape in which the lower portion is smaller than the upper portion. Therefore, in the contact plug CCa connected to the terrace portion TP, the boundary between the lower contact plug LCC and the upper contact plug UCC can be confirmed by observing the cross-sectional shape of the contact plug CCa. Each of the lower contact plug LCC and the upper contact plug UCC may be referred to as a sub-contact plug of the contact plug CCa.

The configuration of the other parts of the memory device 1 according to the fourth embodiment is similar to that of the third embodiment.

### <4-2> Manufacturing Method

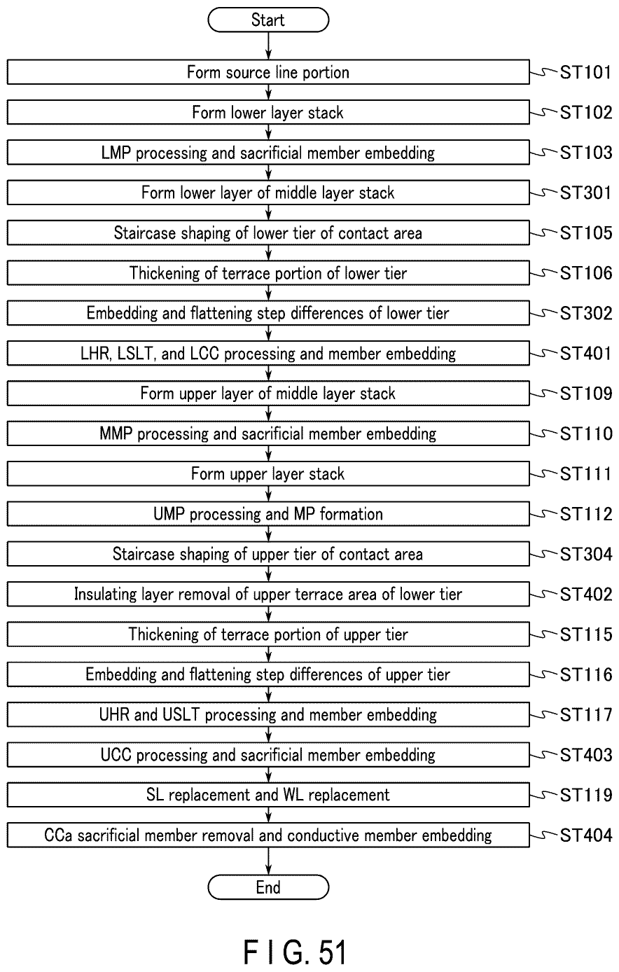

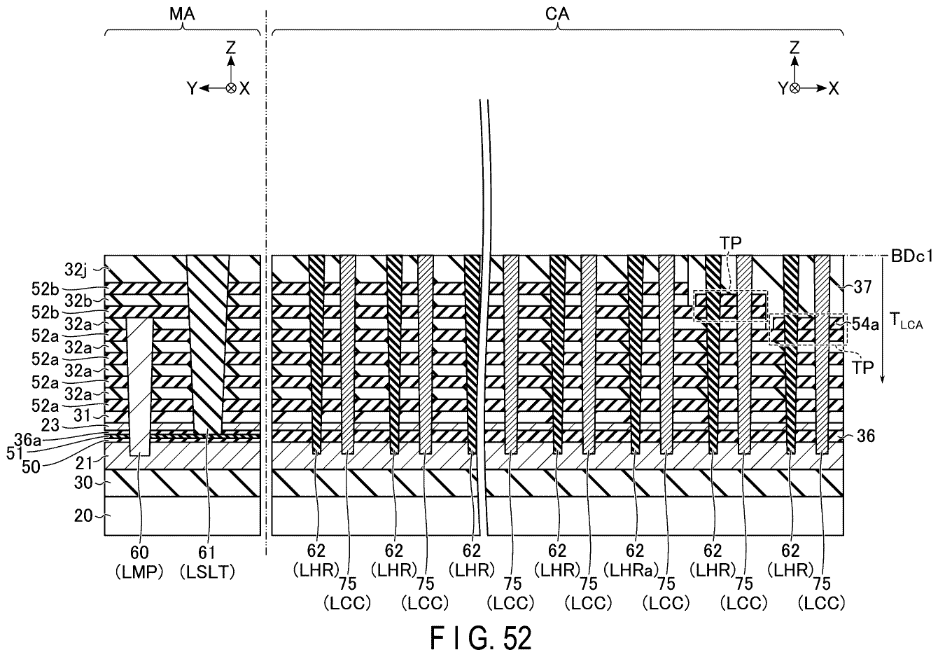

Next, as a method of manufacturing the memory device 1 according to the fourth embodiment, a method of forming the stacked wiring line and the contact plug CCa corresponding to the memory cell array 10D will be described with reference to FIG. 51 as appropriate. FIG. 51 is a flowchart showing an example of a method of manufacturing the memory device 1 according to the fourth embodiment. FIGS. 52, 53, 54, 55, 56, 57, 58, and 59 are cross-sectional views showing examples of cross-sectional structures in the manufacturing process of the memory device 1 according to the fourth embodiment. Each of FIGS. 52 to 59 shows an area where the memory pillar MP and the member SLT are formed and a part of the contact area CA.

First, similarly to the third embodiment, the processing of steps ST101, ST102, ST103, ST301, ST105, ST106, and ST302 is executed in this order. That is, the source line portion is formed (step ST101), the lower layer stack is formed (step ST102), the LMP processing and the sacrificial member embedding are executed (step ST103), the lower layer of the middle layer stack is formed (step ST301), the staircase shaping of the lower tier T_{LCA} of the contact area CA is executed (step ST105), the terrace portion TP of the lower tier T_{LCA} is thickened (step ST106), and embedding and flattening step differences of the lower tier T_{LCA} are executed (step ST302).

Next, as shown in FIG. 52, LHR, LSLT, and LCC processing, and member embedding are executed (step ST401). Specifically, the slit corresponding to the lower member LSLT is formed similarly to the third embodiment. Then, the sacrificial member 61 is embedded in the slit corresponding to the lower member LSLT. In addition, a plurality of holes corresponding to the plurality of lower support pillars LHR or LHRa are formed similarly to the third embodiment. Then, the insulating member 62 is embedded in the plurality of holes corresponding to the plurality of lower support pillars LHR or LHRa. At this time, the insulating member 62 corresponding to the lower support pillar LHRa is formed with the same structure as the insulating member 62 corresponding to the plurality of lower support pillars LHR. Furthermore, a plurality of holes corresponding to the plurality of lower contact plugs LCC associated with the conductive layer 24 (24c or 24d) of the upper tier T_{UCA} is formed to penetrate, for example, the sacrificial members 52a and 52b, the semiconductor layer 23, and the insulating layers 31, 32a, 32b, 32j, and 36, and such that the bottom thereof reaches the semiconductor layer 21. In addition, a plurality of holes corresponding to the plurality of lower contact plugs LCC associated with the conductive layer 24 (24a or 24b) of the lower tier T_{LCA} is formed to penetrate, for example, the sacrificial members 52a, 52b, and 54a, the semiconductor layer 23, and the insulating layers 31, 32a, 32j, 36, and 37, and such that the bottom thereof reaches the semiconductor layer 21. Then, the sacrificial member 75 is embedded in the plurality of holes corresponding to the plurality of lower contact plugs LCC. The sacrificial member 75 contains, for example, silicon, a metal material, or the like. Note that the order of processing and member embedding of the lower support pillar LHR, the lower member LSLT, and the lower contact plug LCC is any order.

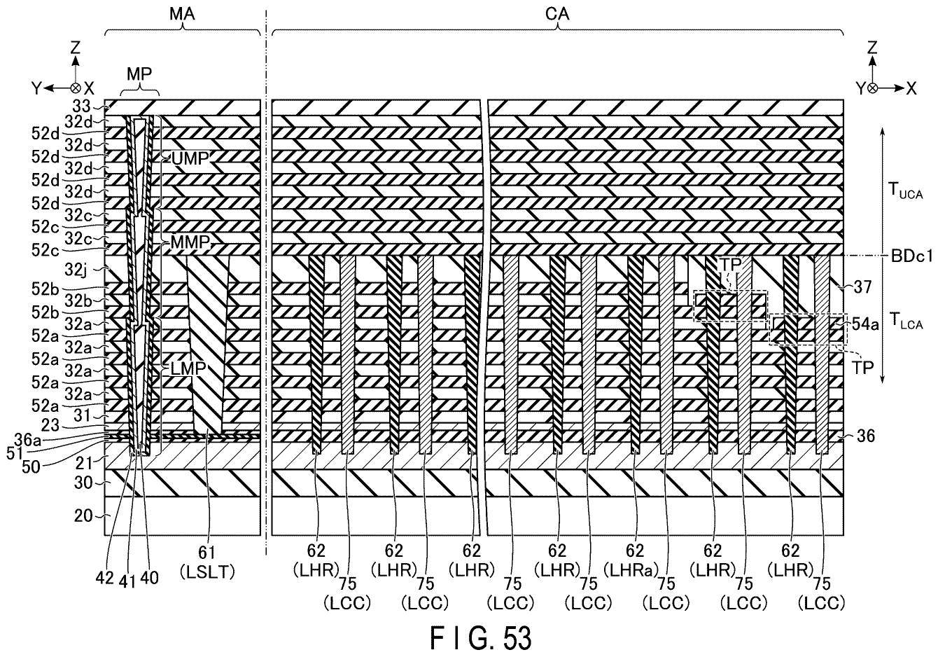

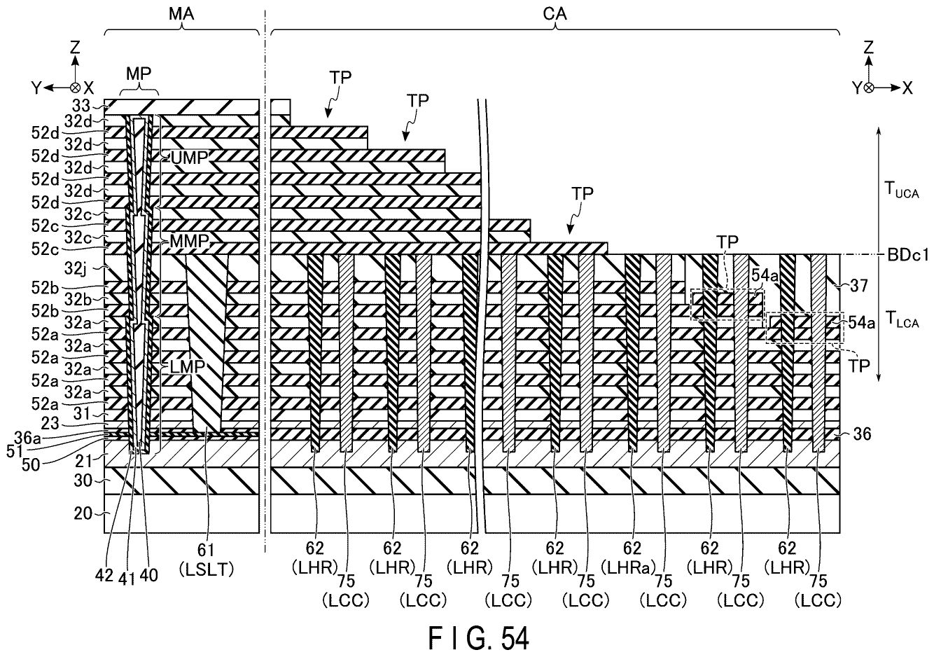

Next, similarly to the third embodiment, the processing of steps ST109, ST110, ST111, ST112, and ST304 is executed in this order. That is, the upper layer of the middle layer stack is formed (step ST109), MMP processing and sacrificial member embedding are executed (step ST110), the upper layer stack is formed (step ST111), and UMP processing and MP formation are executed (step ST112). Thereby, the structures shown in FIG. 53 is formed. Then, similarly to the third embodiment, staircase shaping of the upper tier T_{UCA} of the contact area CA is executed (step ST304), and the structure shown in FIG. 54 is formed.

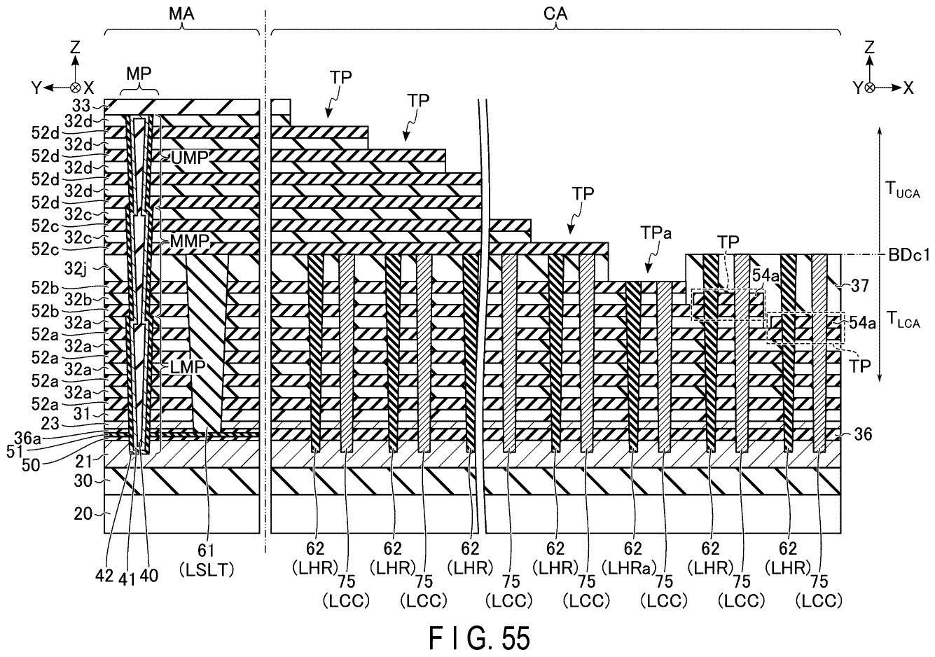

Next, as shown in FIG. 55, insulating layer removal of the upper terrace area of the lower tier T_{LCA} is executed (step ST402). Specifically, similarly to step ST305 of the third embodiment, anisotropic etching processing is executed on the insulating layer 32j provided in the upper terrace area of the lower tier T_{LCA}. As a result, the surface of the terrace portion TPa of the sacrificial member 52b is exposed in the upper terrace area of the lower tier T_{LCA}. In addition, the upper portion of the lower contact plug LCC is processed together with the upper portion of the insulating member 62 in the lower support pillar LHRa provided so as to penetrate the terrace portion TPa. As a result, the position of the upper end of the insulating member 62 in the lower support pillar LHRa associated with the terrace portion TPa is lower than the position of the upper end of the lower support pillar LHR. In addition, the position of the upper end of the sacrificial member 75 in the lower contact plug LCC associated with the terrace portion TPa is lower than the position of the upper end of the sacrificial member 75 in the lower contact plug LCC associated with the terrace portion TP.

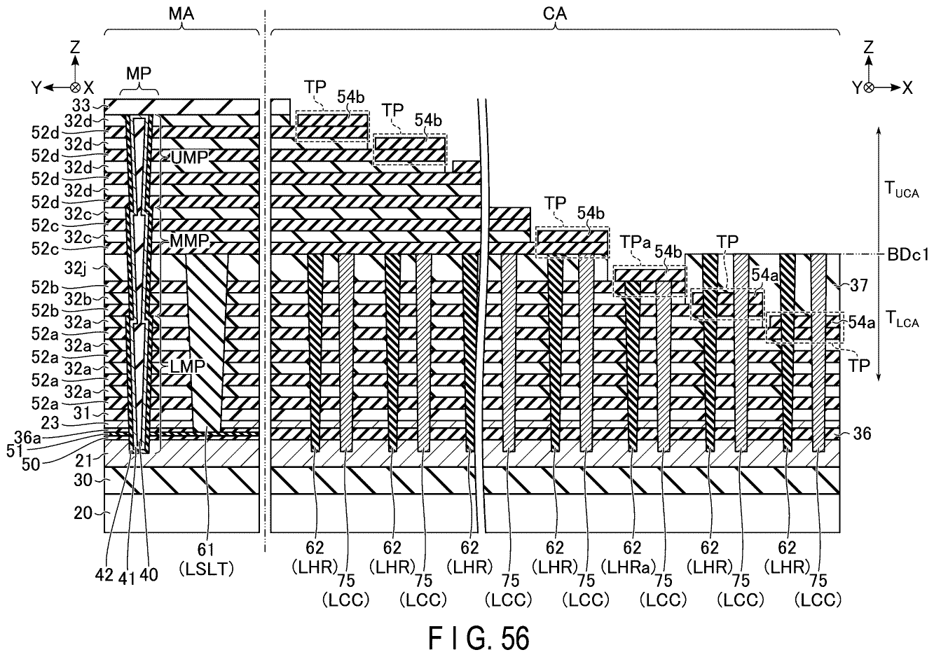

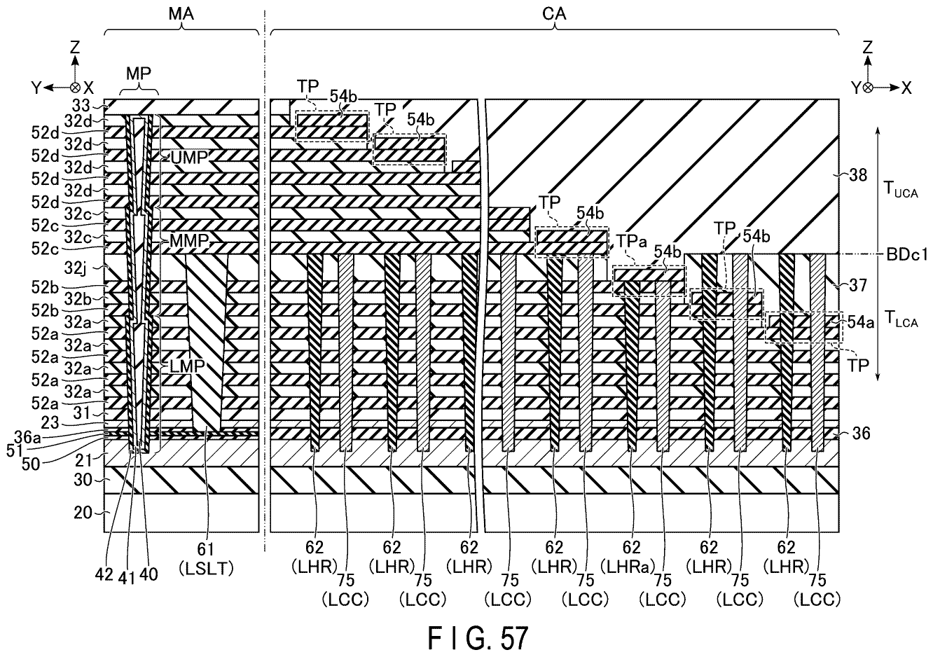

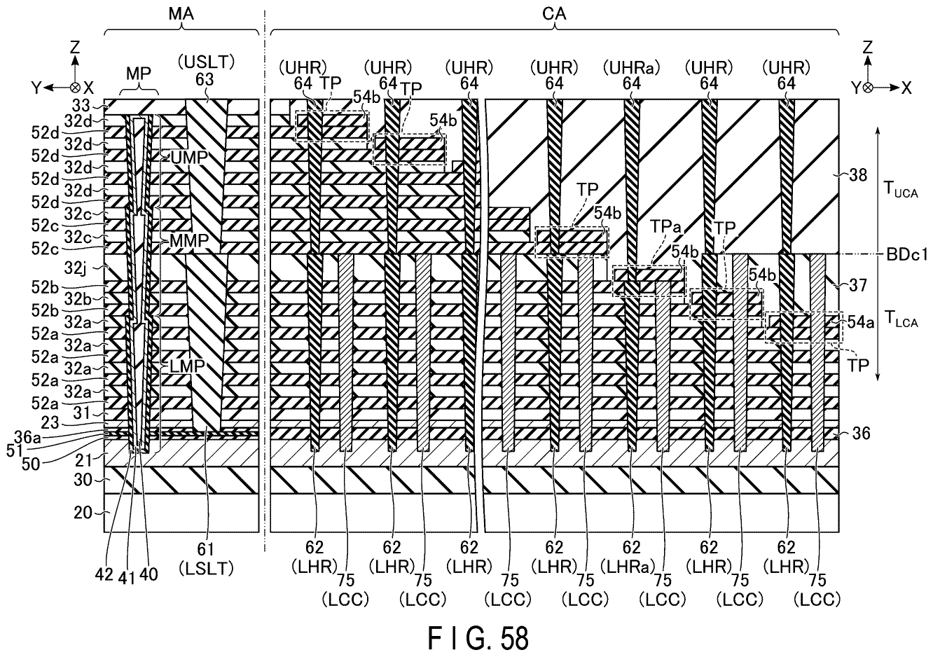

Next, as shown in FIG. 56, the terrace portion TP of the upper tier T_{UCA} is thickened similarly to the first embodiment (step ST115). Then, as shown in FIG. 57, embedding and flattening step differences of the upper tier T_{UCA} are executed similarly to the first embodiment (step ST116). Next, as shown in FIG. 58, UHR and USLT processing, and member embedding are executed similarly to the third embodiment (step ST117).

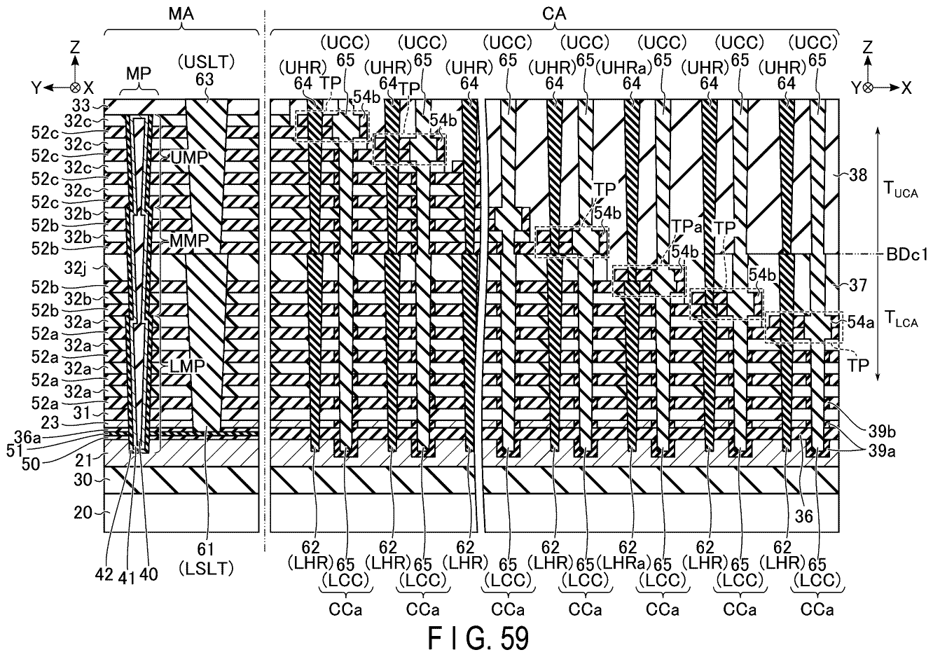

Next, as shown in FIG. 59, UCC processing and sacrificial member embedding are executed (step ST403). Specifically, first, a plurality of holes corresponding to the plurality of upper contact plugs UCC is formed, for example, so as to penetrate the insulating layer 38, and reach the sacrificial member 75 in the lower contact plug LCC with which the bottom thereof is associated. Then, the sacrificial member 75 in each lower contact plug LCC is removed via the plurality of holes corresponding to the plurality of upper contact plugs UCC. Then, similarly to the first embodiment, the insulating layers 39a and 39b are formed using holes corresponding to the upper contact plug UCC and the lower contact plug LCC connected in the Z direction, that is, the contact plug CCa. Thereafter, the sacrificial member 65 is embedded in the hole corresponding to the contact plug CCa.

Next, similarly to the first embodiment, the SL replacement and WL replacement are executed (step ST119). That is, by the SL replacement, the insulating layers 50 and 36a and the sacrificial member 51 of the memory area MA are replaced with the semiconductor layer 22, and the semiconductor layer 22 and the semiconductor film 41 in the memory pillar MP are connected. The sacrificial members 52a, 52b, 52c, 52d, 54a, and 54b of the memory area MA and the contact area CA are replaced with the conductive layer 24 by the WL replacement. Thereafter, the spacer SP and the conductive member LI are formed in the slit corresponding to the member SLT.

Next, CCa sacrificial member removal and conductive member embedding are executed (step ST404).

Specifically, first, the sacrificial member 65 in the plurality of holes corresponding to the contact plugs CCa is removed. Then, the conductive member 66 is embedded in the plurality of holes corresponding to the contact plugs CCa. As a result, each contact plug CCa is electrically connected to the terrace portion TP or TPa of the associated conductive layer 24, and the structure of the memory cell array 10D described with reference to FIG. 50 is completed.

Other processing of method of manufacturing the memory device 1 according to the fourth embodiment is similar to that of the third embodiment.

### <4-3> Advantageous Effects of the Fourth Embodiment

As described above, the contact plug CC may be formed in two layers in the memory device 1 according to the third embodiment. In the memory device 1 according to the fourth embodiment, by removing the insulating layer 32j in the upper terrace area of the lower tier T_{LCA} after the formation of the staircase structure of the upper tier T_{UCA}, the terrace portion TPa can be thickened similarly to the third embodiment. As a result, similarly to the third embodiment, the memory device 1 according to the fourth embodiment can suppress the occurrence of a defect caused by the non-connection of the contact plug CC, and can reduce the manufacturing cost of the memory device 1. Note that a structure such as the contact plug CCa provided in a plurality of layers can also be applied to the first or second embodiment.

### <5> Fifth Embodiment

The fifth embodiment relates to a case where the contact plug CC is connected to the terrace portion TP of the conductive layer 24 without penetrating the stacked wiring line in the memory device 1 according to the first embodiment. In the fifth embodiment, at least two conductive layers 24b having the terrace portion TPa are provided from the side closer to the boundary DBc1. Hereinafter, the memory device 1 according to the fifth embodiment will be described focusing on differences from the first to fourth embodiments.

### <5-1> Configuration

First, a configuration of the memory device 1 according to the fifth embodiment is described.

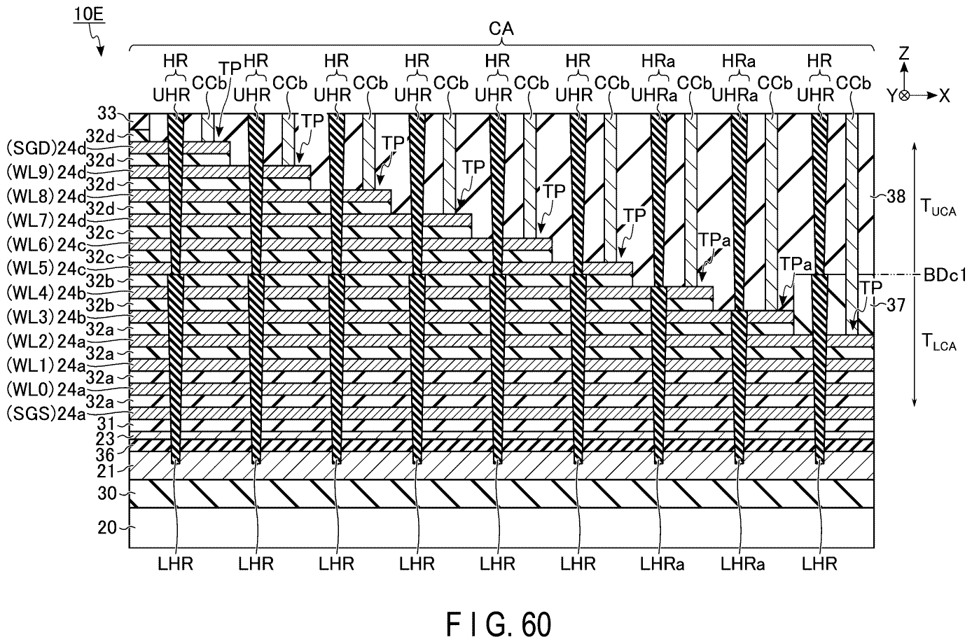

FIG. 60 is a cross-sectional view showing an example of a cross-sectional structure of the contact area CA of the memory cell array 10E included in the memory device 1 according to the fifth embodiment. As shown in FIG. 60, the contact area CA of the memory cell array 10E includes a configuration in which the contact plug CC is replaced with the contact plug CCb and a plurality of insulating layers 39 is omitted in the memory cell array 10 of the first embodiment. The contact area CA of the memory cell array 10E includes a plurality of support pillars HR and a plurality of support pillars HRa. Then, in the lower tier T_{LCA}, at least two conductive layers 24 (24b) having the terrace portion TPa are provided from the side closer to the boundary DBc1. In addition, the conductive layer 24 (24b) of at least two layers having the terrace portion TPa is provided for each block BLK.

Each contact plug CCb is provided to extend along the Z direction. The upper end of each contact plug CCb is positioned in the upper layer of the uppermost conductive layer 24. The lower end of each contact plug CCb is connected to the terrace portion TP or TPa of the associated conductive layer 24. Then, the contact plug CCb does not penetrate (pass through) the conductive layer 24 located below the associated terrace portion TP or TPa. The contact plug CCb connected to the terrace portion TP of the conductive layer 24 (24c or 24d) included in the upper tier T_{UCA} penetrates (passes through) the insulating layer 38. The contact plug CCb connected to the terrace portion TPa of the conductive layer 24b penetrates (passes through) the insulating layer 38. The contact plug CCb connected to the terrace portion TP of the conductive layer 24 (24a) included in the lower tier T_{LCA} penetrates (passes through) the insulating layers 37 and 38. The contact plug CCb contains, for example, tungsten or copper.

Note that the contact plug CCb connected to the terrace portion TP of the conductive layer 24 included in the lower tier T_{LCA} among the contact plugs CCb may be formed in a plurality of layers as in the contact plug CCa of the fourth embodiment. The configuration of the other parts of the memory device 1 according to the fifth embodiment is similar to that of the first embodiment.

### <5-2> Manufacturing Method

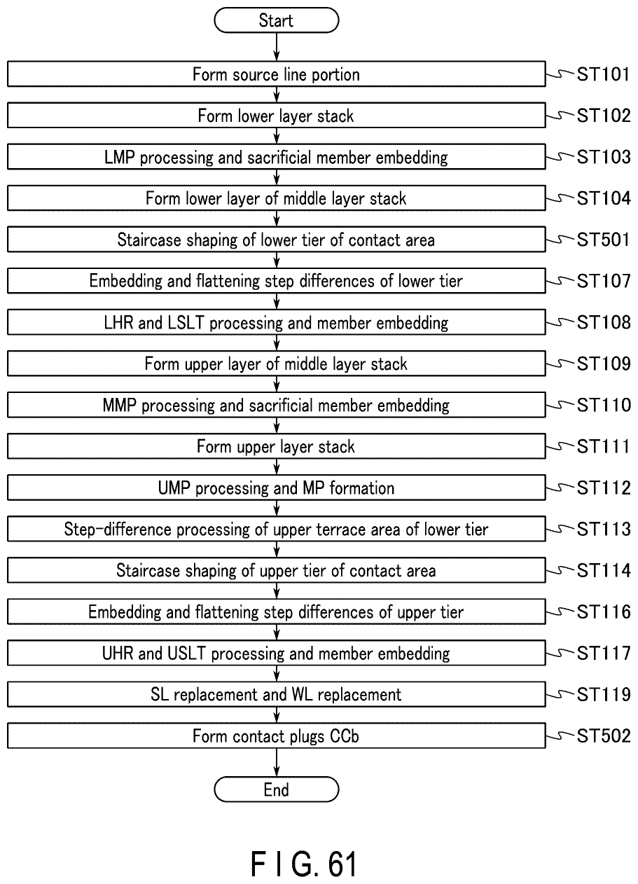

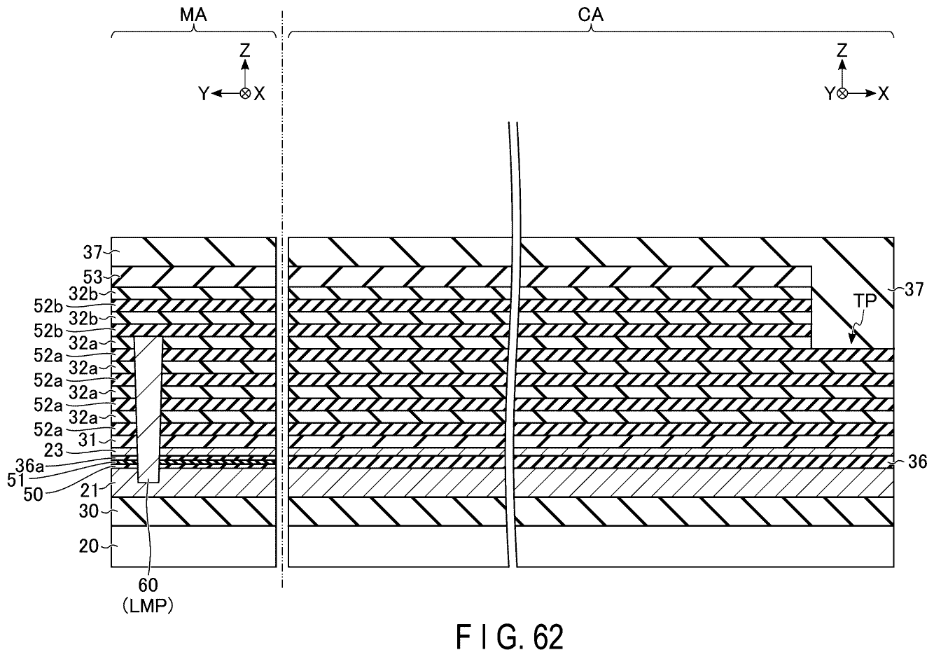

Next, as a method of manufacturing the memory device 1 according to the fifth embodiment, a method of forming the stacked wiring line and the contact plug CCb corresponding to the memory cell array 10E will be described with reference to FIG. 61 as appropriate. FIG. 61 is a flowchart showing an example of a method of manufacturing the memory device 1 according to the fifth embodiment. FIGS. 62, 63, 64, 65, 66, 67, 68, and 69 are cross-sectional views showing examples of cross-sectional structures in the manufacturing process of the memory device 1 according to the fifth embodiment. Each of FIGS. 62 to 69 shows an area where the memory pillar MP and the member SLT are formed and a part of the contact area CA.

First, similarly to the first embodiment, the processing of steps ST101, ST102, ST103, and ST104 is executed in this order. That is, a source line portion is formed (step ST101), a lower layer stack is formed (step ST102), LMP processing and sacrificial member embedding are executed (step ST103), and the lower layer of the middle layer stack is formed (step ST104).

Next, staircase shaping of the lower tier T_{LCA} of the contact area CA is executed (step ST501). The processing of step S501 is executed such that staircase shaping similar to step ST105 of the first embodiment does not form the terrace portion TP of at least two layers of the sacrificial members 52b from the uppermost layer. Then, embedding and flattening step differences of the lower tier T_{LCA} are executed without thickening the terrace portion TP of the lower tier T_{LCA} (step ST107). That is, as shown in FIG. 62, the insulating layer 37 is formed so that the staircase structure formed in the lower tier T_{LCA} is embedded. Then, for example, the member 53 and a part of the insulating layer 37 are removed by CMP processing. As a result, the upper surface of the uppermost insulating layer 32b in the memory area MA and the upper surface of the insulating layer 37 in the contact area CA are aligned (flattened).

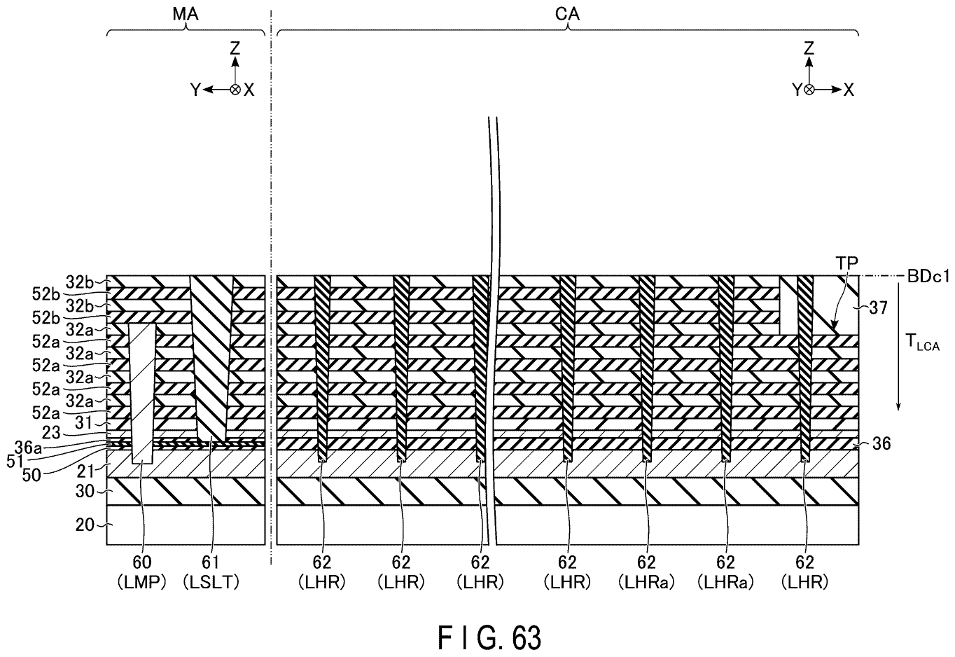

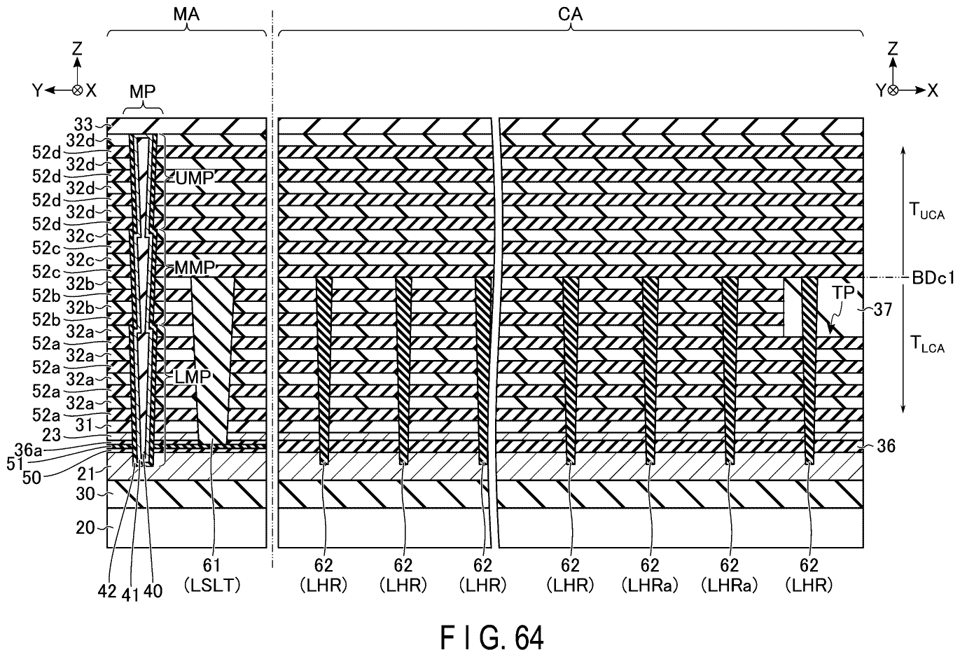

Next, as shown in FIG. 63, LHR and LSLT processing, and member embedding are executed similarly to the first embodiment (step ST108). Thereafter, similarly to the first embodiment, the processing of steps ST109, ST110, ST111, and ST112 is executed in this order. That is, the upper layer of the middle layer stack is formed (step ST109), MMP processing and sacrificial member embedding are executed (step ST110), the upper layer stack is formed (step ST111), and UMP processing and MP formation are executed (step ST112). Thereby, the structure shown in FIG. 64 is formed.

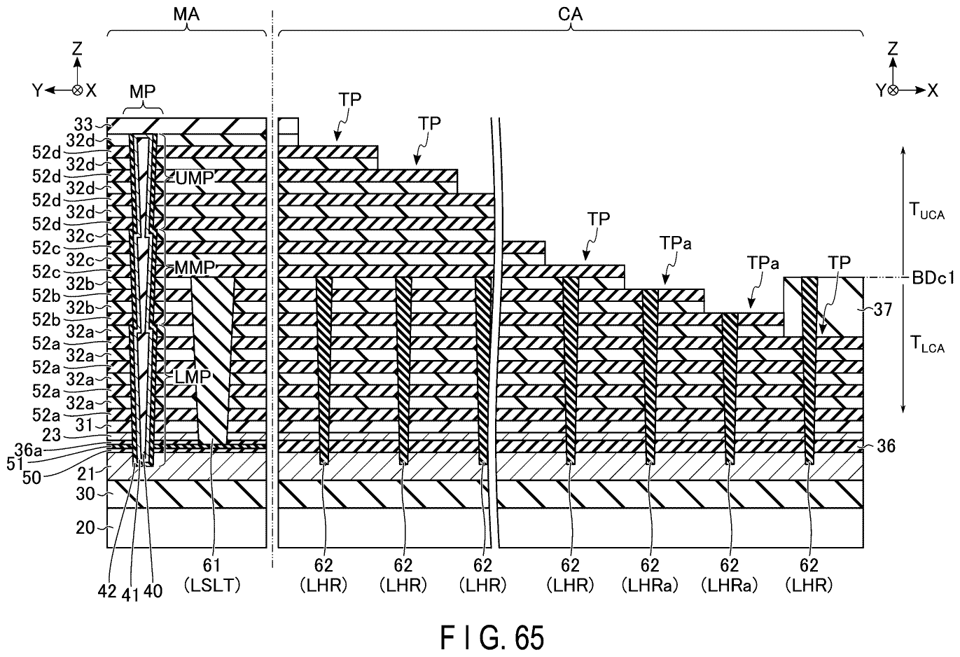

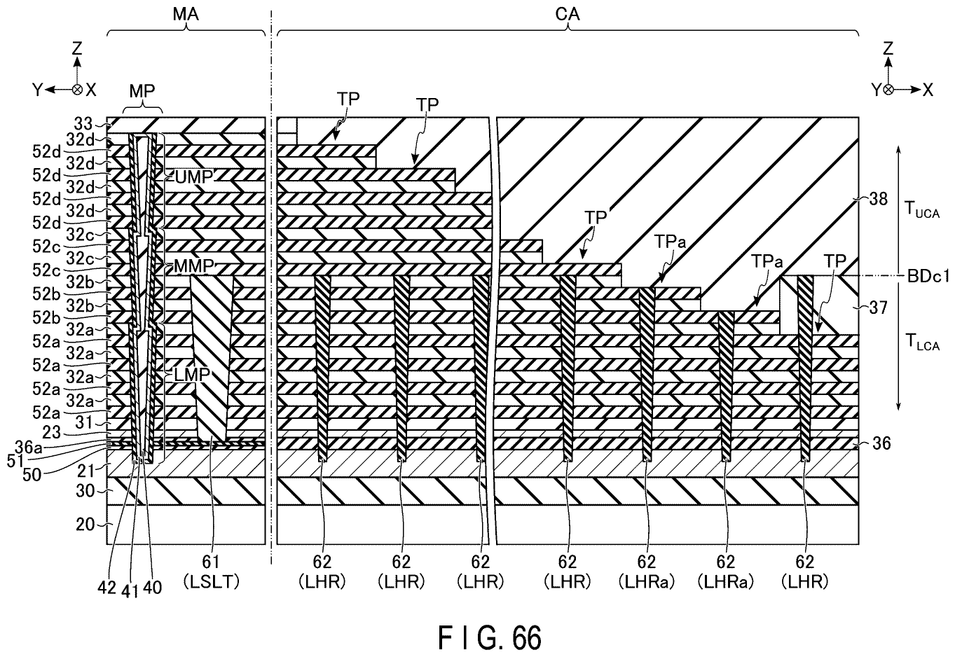

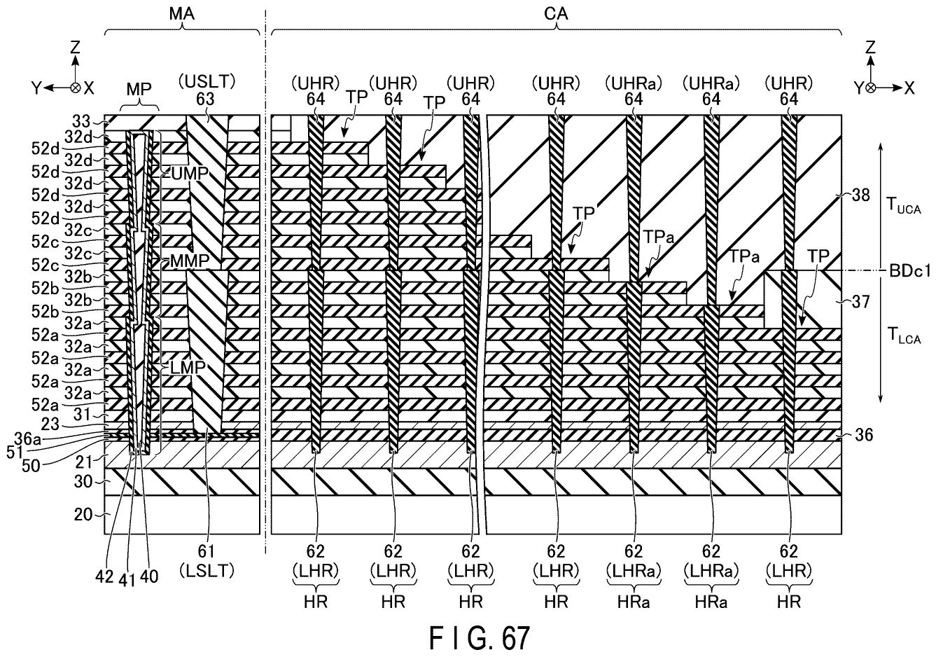

Next, similarly to the first embodiment, the step-difference processing of the upper terrace area of the lower tier T_{LCA} is executed (step ST113), and the staircase shaping of the upper tier T_{UCA} of the contact area CA is executed (step ST114). As a result, the terrace portion TP is formed in each of the plurality of sacrificial members 52 (52c and 52d) of the upper tier T_{UCA}, and the terrace portion TPa is formed in each of the sacrificial members 52 (52b) of at least two layers in which the terrace portion TP is not formed in step ST501 in the lower tier T_{LCA}. As a result, the structure shown in FIG. 65 is formed. Then, embedding and flattening step differences of the upper tier T_{UCA} are executed without thickening the terrace portion TP of the upper tier T_{UCA} (step ST116). That is, as shown in FIG. 66, the insulating layer 38 is formed so that the staircase structure formed in the upper tier T_{UCA} is embedded. Then, for example, a part of the insulating layer 38 is removed by CMP processing. As a result, the upper surface of the insulating layer 33 in the memory area MA and the upper surface of the insulating layer 38 in the contact area CA are aligned (flattened). Then, as shown in FIG. 67, UHR and USLT processing, and member embedding are executed similarly to the first embodiment (step ST117).

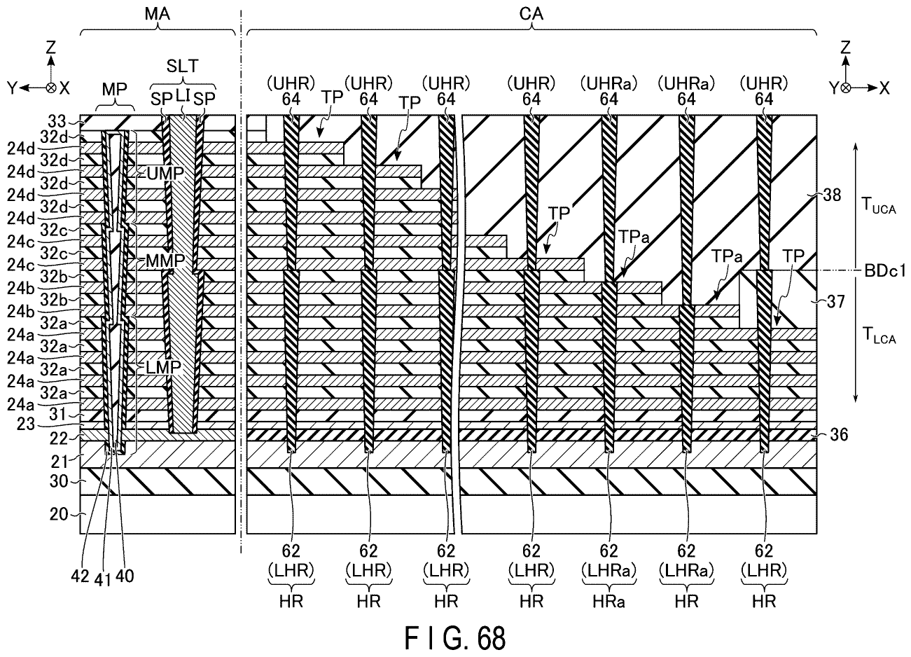

Next, as shown in FIG. 68, similarly to the first embodiment, the SL replacement and WL replacement are executed (step ST119). By the SL replacement, the insulating layers 50 and 36a and the sacrificial member 51 of the memory area MA are replaced with the semiconductor layer 22, and the semiconductor layer 22 and the semiconductor film 41 in the memory pillar MP are connected. The sacrificial members 52a, 52b, 52c, and 52d of the memory area MA and the contact area CA are replaced with the conductive layer 24 by the WL replacement. Thereafter, the spacer SP and the conductive member LI are formed in the slit corresponding to the member SLT.

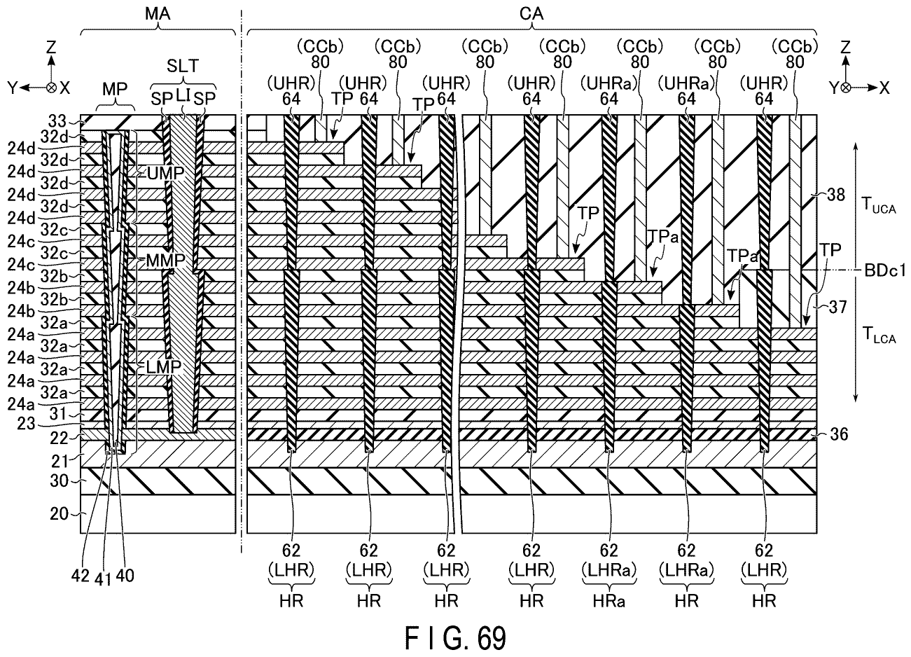

Next, as shown in FIG. 69, a plurality of contact plugs CCb is formed (step ST502). Specifically, first, a plurality of holes corresponding to the plurality of contact plugs CCb is formed, for example, so as to penetrate the insulating layer 38 or the insulating layers 37 and 38, and reach the terrace portion TP or TPa of the conductive layer 24 with which the bottom thereof is associated. Then, the conductive member 80 is embedded in the plurality of holes corresponding to the plurality of contact plugs CCb. The conductive member 80 contains, for example, tungsten or copper. As a result, each contact plug CCb is electrically connected to the terrace portion TP or TPa of the associated conductive layer 24, and the structure of the memory cell array 10E described with reference to FIG. 60 is completed.

Other processing of method of manufacturing the memory device 1 according to the fifth embodiment is similar to that of the first embodiment.

### <5-3> Advantageous Effects of the Fifth Embodiment

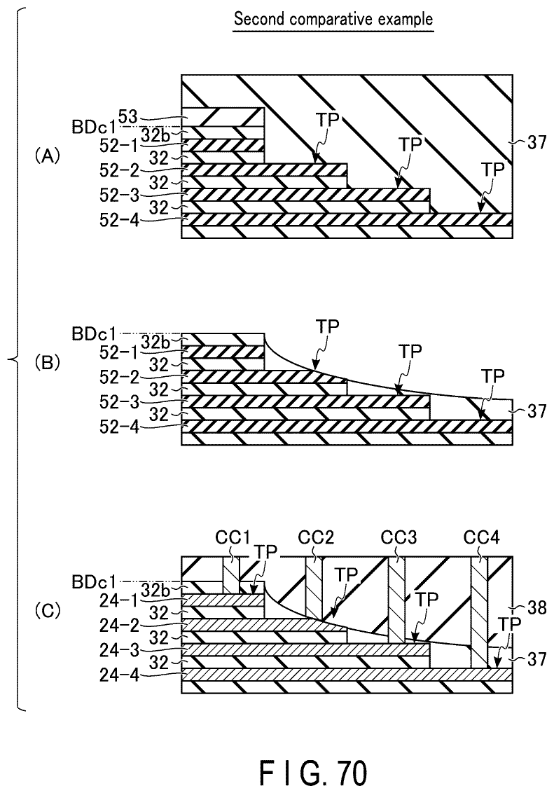

Advantageous effects of the memory device 1 according to the fifth embodiment will now be described using a second comparative example. FIG. 70 is a cross-sectional view showing an example of a cross-sectional structure in the vicinity of a boundary BDc1 of a layer stack in a process of manufacturing a memory device 1 according to the second comparative example. The second comparative example corresponds to a case where the terrace portions TP of all the sacrificial members 52 included in the lower tier T_{LCA} are formed in the processing of step ST501 of the flowchart shown in FIG. 61.

As shown in (A) of FIG. 70, in the second comparative example, the terrace portion TP of each of the plurality of sacrificial members 52 (for example, 52-2 to 52-4) in the upper portion of the lower tier T_{LCA} is formed at the point of time when embedding the step differences of the lower tier T_{LCA} is executed. In this state, flattening (CMP processing) of the lower tier T_{LCA} is executed, and the surface of the insulating layer 32b is processed. Then, as shown in (B) of FIG. 70, a part of the sacrificial member 52 (for example, the sacrificial member 52-2) in the upper portion of the lower tier T_{LCA} may be scraped by dishing. In this case, the thickness of the terrace portion TP of the sacrificial member 52-2 may be thinner than other terrace portions TP. Then, the sacrificial member 52 and the like of the upper tier T_{UCA} are formed, and as shown in (C) of FIG. 70, the contact plug CC is formed after the WL replacement. In this example, the sacrificial members 52-1 to 52-4 are replaced with conductive layers 24-1 to 24-4, respectively.

In the second comparative example, the contact plugs CC1 to CC4 are connected to the conductive layers 24-1 to 24-4, respectively. In the second comparative example, there is a possibility that the contact plug CC2 penetrates the conductive layer 24-2 due to the insufficient thickness of the terrace portion TP of the conductive layer 24-2 by dishing. The contact plug CC2 penetrating the conductive layer 24-2 may cause a short circuit between the adjacent conductive layers 24-2 and 24-3 of two layers. In order to suppress the influence of dishing on the conductive layer 24 in the upper portion of the lower tier T_{LCA}, it is conceivable to thicken the insulating layer 32b in contact with the boundary BDc1. However, as described in the first embodiment, increasing the thickness of the insulating layer 32b in contact with the boundary BDc1 causes an increase in the channel resistance of the memory pillar MP.

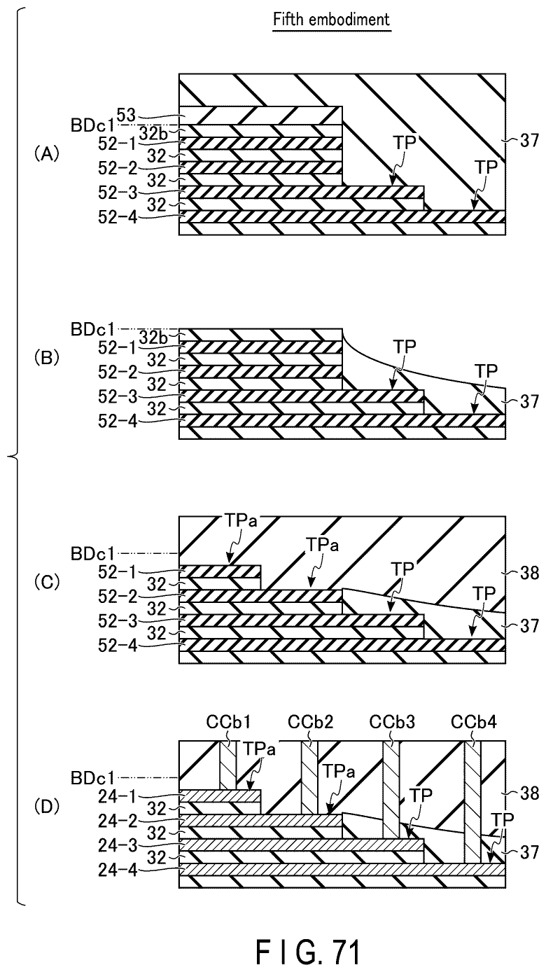

FIG. 71 is a cross-sectional view showing an example of a cross-sectional structure in the vicinity of a boundary BDc1 of a layer stack in a process of manufacturing the memory device 1 according to the fifth embodiment. As shown in (A) of FIG. 71, in the fifth embodiment, at the point of time when embedding step differences of the lower tier T_{LCA} is executed, the terrace portion TP of the sacrificial member 52 of at least two layers (for example, 52-1 and 52-2) from the upper layer side among the plurality of sacrificial members 52 in the upper portion of the lower tier T_{LCA} is not formed. In this state, flattening (CMP processing) of the lower tier T_{LCA} is executed, and the surface of the target insulating layer 32b is processed. In the fifth embodiment, spacing between the target of the CMP processing and the uppermost sacrificial member 52-3 among the sacrificial members 52 in which the terrace portion TP is formed is wider than that in the second comparative example. Therefore, even if the CMP processing reaches the surface of the target insulating layer 32b, the influence of dishing does not reach each of the terrace portions TP that have been formed as shown in (B) of FIG. 71. Thereafter, the sacrificial member 52c and the like of the upper tier T_{UCA} are formed, and the terrace portion TPa of each of the sacrificial members 52-1 and 52-2 is formed at the time of staircase shaping of the upper tier T_{UCA}. Then, as shown in (C) of FIG. 71, embedding step differences of the upper tier T_{UCA} is executed. Then, as shown in (D) of FIG. 71, the contact plug CCb is formed after the WL replacement.

In the memory device 1 according to the fifth embodiment, since the influence of the dishing on the conductive layer 24 is suppressed, it is possible to suppress the penetration of the contact plug CCb. As a result, the memory device 1 according to the fifth embodiment can suppress the occurrence of a defect caused by the penetration of the contact plug CCb, and can reduce the manufacturing cost of the memory device 1. Then, in the memory device 1 according to the fifth embodiment, similarly to the first embodiment, the insulating layer 32b in contact with the boundary BDc1 can be formed to have substantially the same thickness as the other insulating layers 32. As a result, an increase in the channel resistance of the memory pillar MP between the conductive layers 24b and 24c adjacent to each other with the boundary BDc1 interposed therebetween can be suppressed. As a result, the memory device 1 according to the fifth embodiment can improve the operation characteristics of the NAND string NS.

In the memory device 1 according to the fifth embodiment, the case where the terrace portions TP and TPa are not thickened has been exemplified, but the configuration is not limited thereto. In the memory device 1 according to the fifth embodiment, each of the terrace portions TP and TPa may be thickened similarly to the first embodiment. In this case, at the time of processing the holes corresponding to the contact plugs CCb, it can be suppressed from penetrating the terrace portion TP or TPa of the conductive layer 24 with which these holes are associated. As a result, in the two conductive layers 24 adjacent to each other in the Z direction, the occurrence of the short circuit failure caused by the contact plug CCb can be suppressed.

### <6> Sixth Embodiment

The sixth embodiment relates to a case where a stopper insulating film is used at the time of formation of the contact plug CCb described in the fifth embodiment and a stopper film covering the terrace portion TPa is collectively formed with a stopper film of the upper tier T_{UCA}. Hereinafter, the memory device 1 according to the sixth embodiment will be described focusing on differences from the first to fifth embodiments.

### <6-1> Configuration

First, a configuration of the memory device 1 according to the sixth embodiment is described.

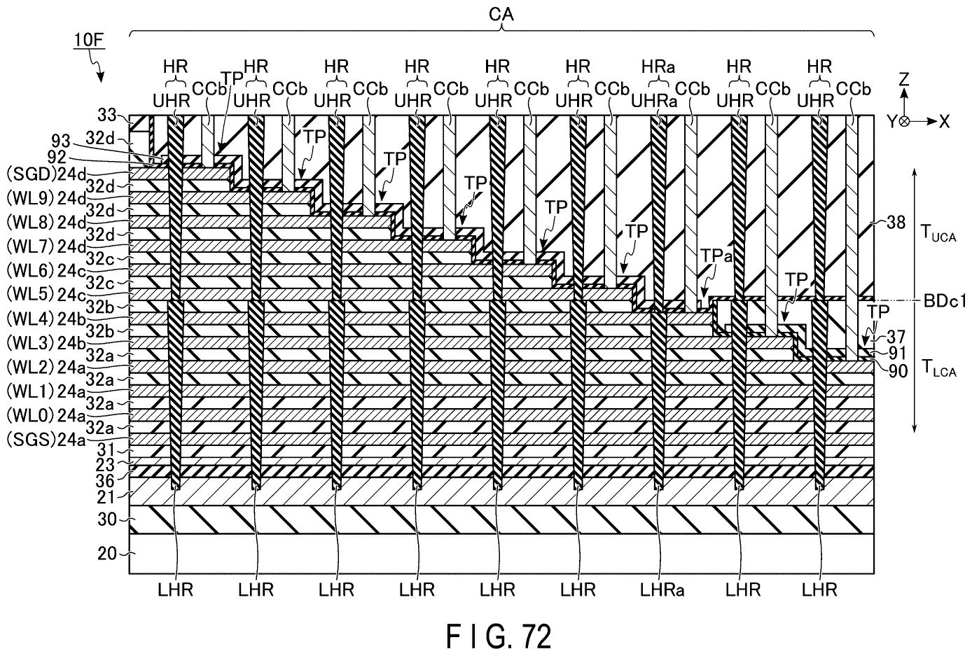

FIG. 72 is a cross-sectional view showing an example of a cross-sectional structure of the contact area CA of the memory cell array 10F included in the memory device 1 according to the sixth embodiment. The contact area CA of the memory cell array 10F includes, for example, a configuration in which insulating films 90 to 93 are added to the memory cell array 10E of the fifth embodiment. In the sixth embodiment, at least one conductive layer 24b having the terrace portion TPa may be provided from the side closer to the boundary BDc1. Hereinafter, as shown in FIG. 72, a case where the memory cell array 10F includes the conductive layer 24b of one layer having the terrace portion TPa will be described.

The insulating film 90 is provided so as to cover the plurality of terrace portions TP of the plurality of conductive layers 24 included in the lower tier T_{LCA}. In other words, the insulating film 90 is provided along the stair shape formed by the plurality of terrace portions TP of the plurality of conductive layers 24 included in the lower tier T_{LCA}. The insulating film 90 is located below the boundary BDc1. The insulating film 90 is continuously provided between two adjacent terrace portions TP. The insulating film 90 contains, for example, silicon oxide.

The insulating film 91 is provided on the insulating film 90 and is provided so as to overlap the plurality of terrace portions TP of the plurality of conductive layers 24 included in the lower tier T_{LCA} in the Z direction. The insulating film 91 is continuously provided between two adjacent terrace portions TP. Specifically, the insulating film 91 is provided so that its upper surface has step differences along the stair shape formed by the plurality of terrace portions TP of the plurality of conductive layers 24 included in the lower tier T_{LCA}. The insulating film 91 is used as a stopper film when hole processing corresponding to the contact plug CCb is performed. The insulating film 91 contains a material different from those of the insulating layers 37 and 38, and includes, for example, silicon nitride.

The insulating film 92 is provided so as to cover the plurality of terrace portions TP of the plurality of conductive layers 24 included in the upper tier T_{UCA} and the terrace portion TPa of the conductive layer 24 of at least one layer included in the lower tier T_{LCA}. The insulating film 92 is located above the lowermost terrace portion TPa among at least one terrace portion TPa included in each block BLK of the memory cell array 10F. The insulating film 92 is continuously provided between two adjacent terrace portions TP or TPa. More specifically, the insulating film 92 is formed along the stair shape formed by the plurality of terrace portions TP of the plurality of conductive layers 24 included in the upper tier T_{UCA} and the terrace portion TPa of the conductive layer 24 of at least one layer included in the lower tier T_{LCA} over both sides of the boundary BDc1 between the upper tier T_{UCA} and the lower tier T_{LCA}. The insulating film 92 may have a portion provided on the insulating layer 37. The insulating film 92 contains, for example, silicon oxide.

The insulating film 93 is provided on the insulating film 92 and is provided so as to overlap the terrace portions TP of the plurality of conductive layers 24 included in the upper tier T_{UCA} and the terrace portion TPa of the conductive layer 24 of at least one layer included in the lower tier T_{LCA} in the Z direction. The insulating film 93 is continuously provided between two adjacent terrace portions TP or TPa. More specifically, the insulating film 93 is formed so that the upper surface has step differences along the stair shape formed by the plurality of terrace portions TP of the plurality of conductive layers 24 included in the upper tier T_{UCA} and the terrace portion TPa of the conductive layer 24 of at least one layer included in the lower tier T_{LCA} over both sides of the boundary BDc1 between the upper tier T_{UCA} and the lower tier T_{LCA}. The insulating film 91 and the insulating film 93 are separated from each other. The insulating film 93 is used as a stopper film when hole processing corresponding to the contact plug CCb is performed. The insulating film 93 contains a material different from that of the insulating layer 38, and includes, for example, silicon nitride.

In a case where the insulating films 91 and 93 contain the same material as the sacrificial member 52, the insulating films 90 and 92 and the insulating films 91 and 93 contain different materials. In a case where each of the insulating films 91 and 93 contains a material different from that of the sacrificial member 52, the insulating films 90 and 92 may be omitted. As the insulating films 91 and 93, a material that can take an etching selection ratio with the insulating layers 37 and 38 at the time of etching processing for forming a hole corresponding to the contact plug CCb may be used.

The configuration of the other parts of the memory device 1 according to the sixth embodiment is similar to that of the fifth embodiment.

### <6-2> Manufacturing Method

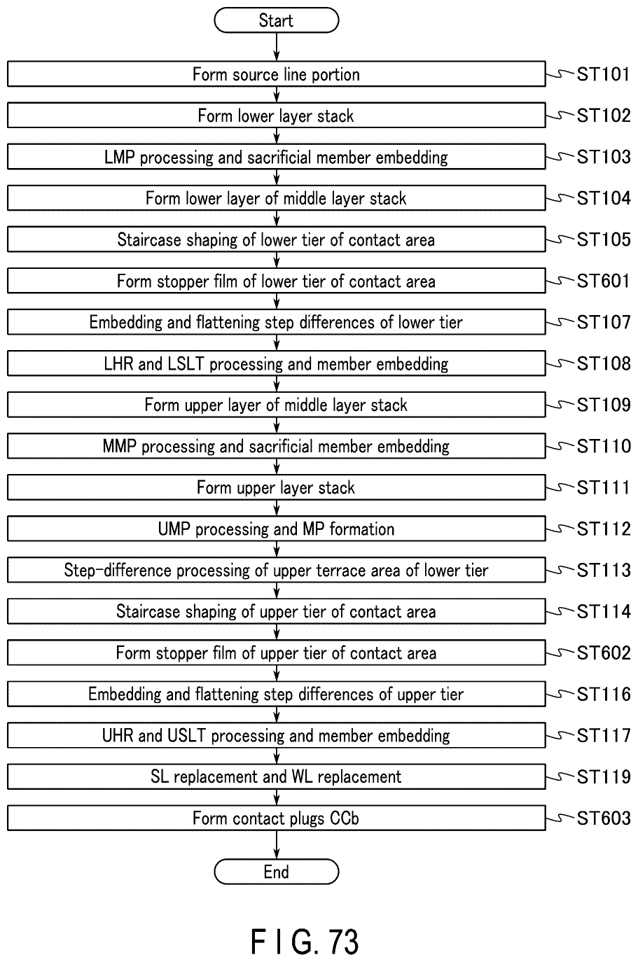

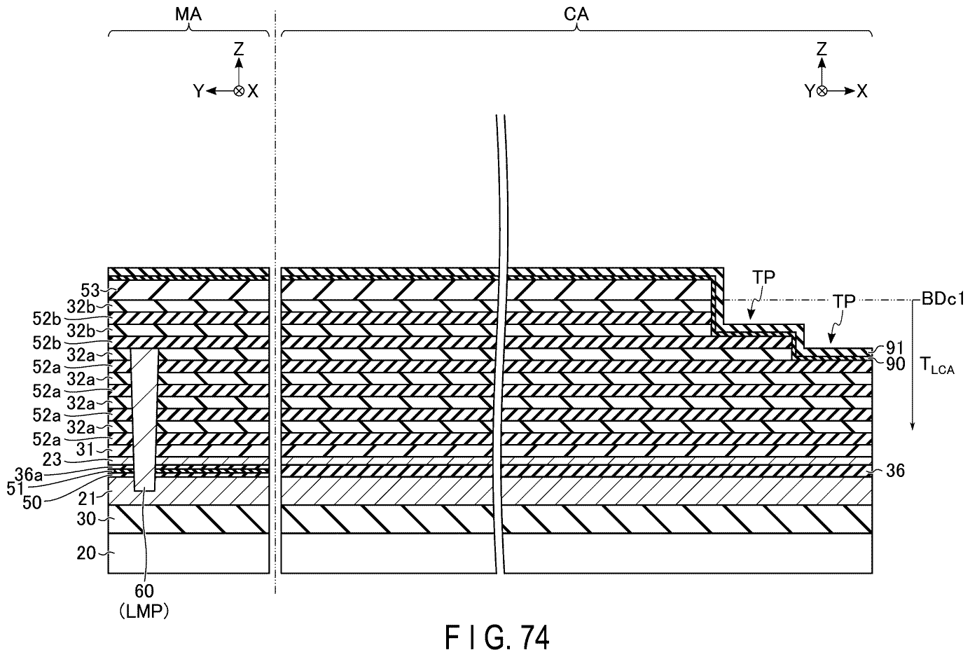

Next, as a method of manufacturing the memory device 1 according to the sixth embodiment, a method of forming the stacked wiring line and the contact plug CC corresponding to the memory cell array 10F will be described with reference to FIG. 73 as appropriate. FIG. 73 is a flowchart showing an example of a method of manufacturing the memory device 1 according to the sixth embodiment. Each of FIGS. 74, 75, 76, 77, 78, 79, 80, 81, 82, 83, and 84 is a cross-sectional view showing an example of cross-sectional structure in the manufacturing process of the memory device 1 according to the sixth embodiment. Each of FIGS. 74 to 84 shows an area where the memory pillar MP and the member SLT are formed and a part of the contact area CA.

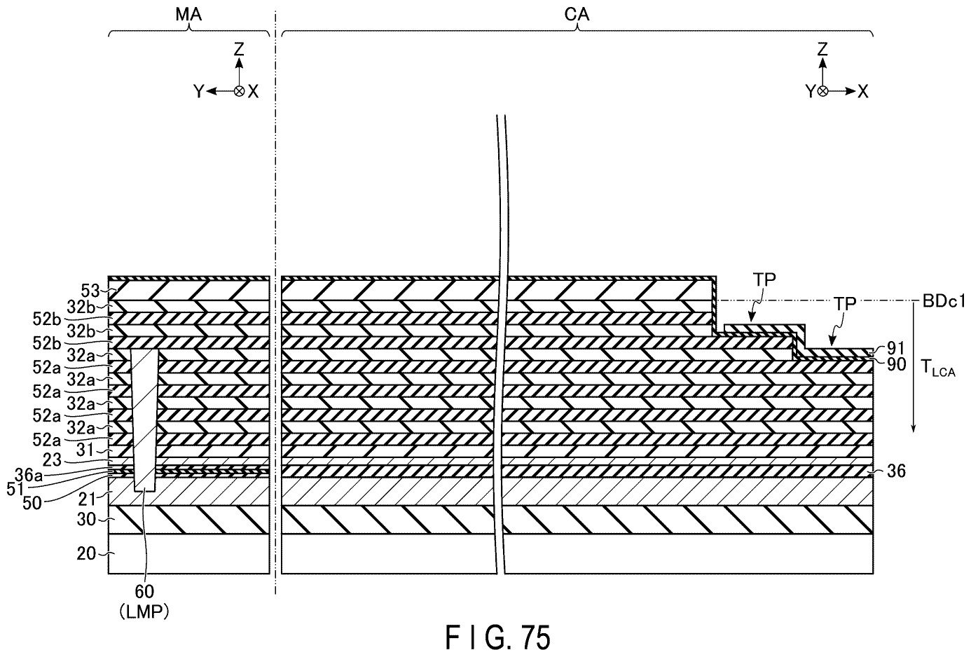

First, similarly to the first embodiment, the processing of steps ST101, ST102, ST103, ST104, and ST105 is executed in this order. That is, a source line portion is formed (step ST101), a lower layer stack is formed (step ST102), LMP processing and sacrificial member embedding are executed (step ST103), the lower layer of the middle layer stack is formed (step ST104), and the staircase shaping of the lower tier T_{LCA} of the contact area CA is executed (step ST105). Then, a stopper film (insulating film 91) of the lower tier T_{LCA} of the contact area CA is formed (step ST601). Specifically, first, as shown in FIG. 74, the insulating films 90 and 91 are formed in this order. Then, as shown in FIG. 75, the insulating film 91 is processed so as to cover the plurality of terrace portions TP of the plurality of sacrificial members 52 (52a and 52b) of the lower tier T_{LCA}. In other words, the insulating film 91 is removed except for the portion covering the plurality of terrace portions TP of the plurality of sacrificial members 52 (52a and 52b) of the lower tier T_{LCA}. At this time, the insulating film 91 formed in the area where the member SLT is formed is also removed.

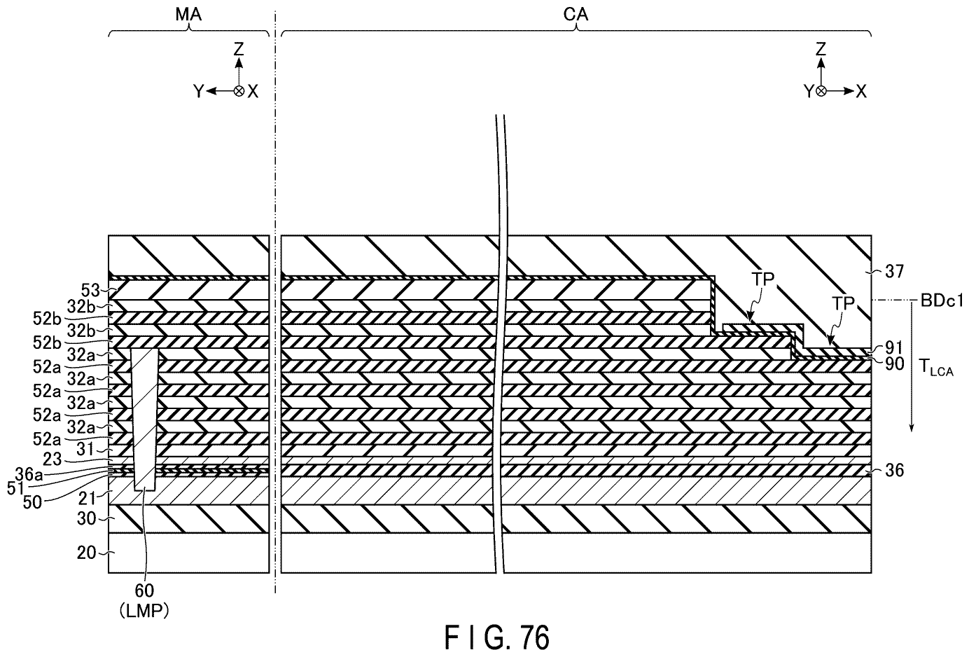

Next, embedding and flattening step differences of the lower tier T_{LCA} are executed similarly to the first embodiment (step ST107). First, as shown in FIG. 76, the insulating layer 37 is formed so that the staircase structure formed in the lower tier T_{LCA} is embedded. Then, for example, the member 53, a part of the insulating layer 37, and a part of the insulating film 90 are removed by CMP processing. As a result, the upper surface of the uppermost insulating layer 32b in the memory area MA and the upper surface of the insulating layer 37 in the contact area CA are aligned (flattened).

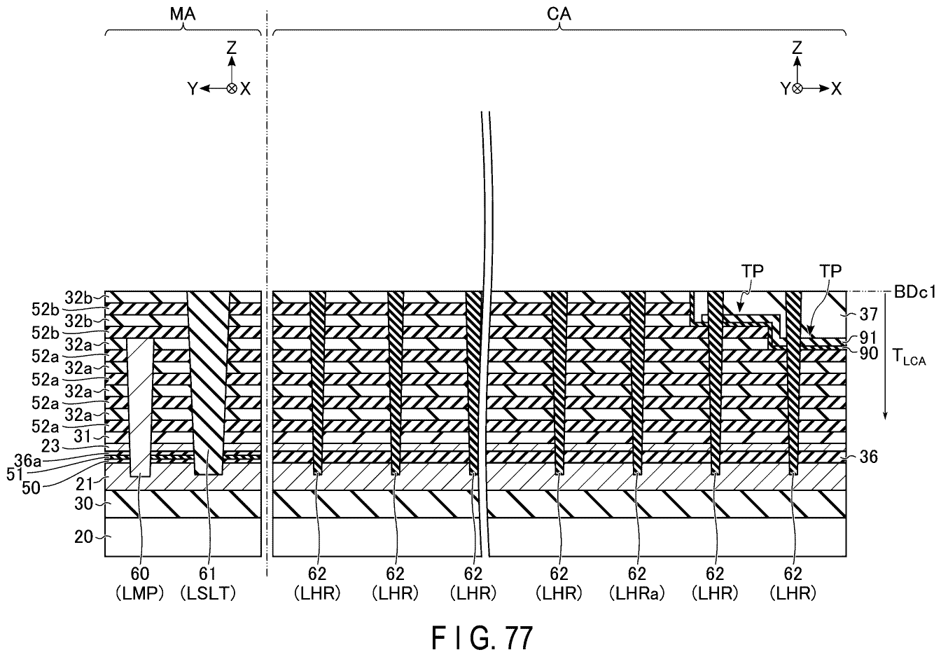

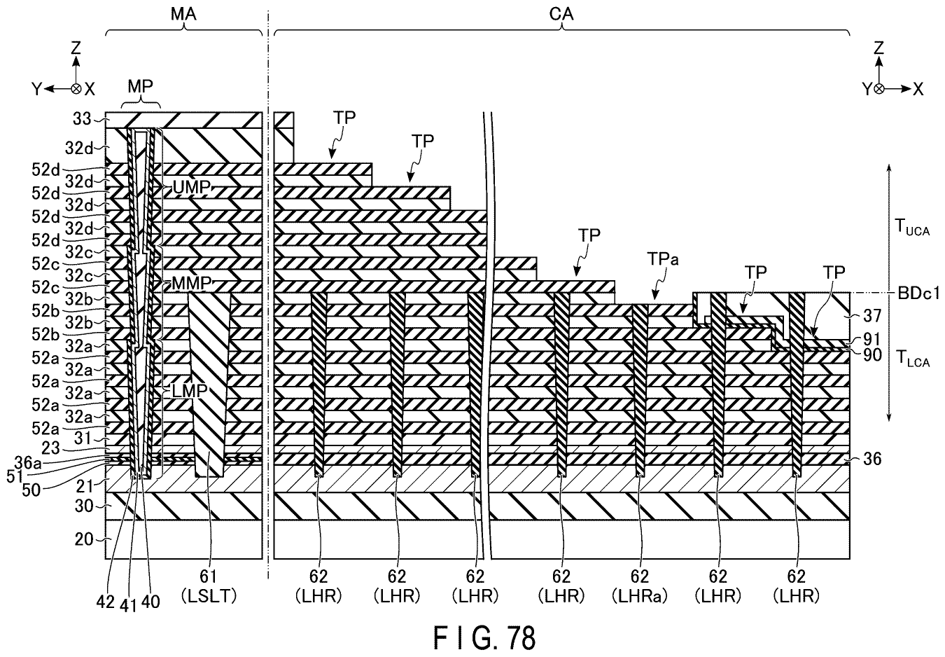

Next, as shown in FIG. 77, LHR and LSLT processing, and member embedding are executed similarly to the first embodiment (step ST108). For example, in the sixth embodiment, a plurality of holes corresponding to the plurality of lower support pillars LHR overlapping the plurality of terrace portions TP of the lower tier T_{LCA} further penetrate the insulating films 90 and 91. Thereafter, similarly to the first embodiment, the processing of steps ST109, ST110, ST111, ST112, ST113, and ST114 is executed in this order. That is, the upper layer of the middle layer stack is formed (step ST109), MMP processing and sacrificial member embedding are executed (step ST110), the upper layer stack is formed (step ST111), UMP processing and MP formation are executed (step ST112), and step-difference processing of the upper terrace area of the lower tier T_{LCA} is executed (step ST113). Then, staircase shaping of the upper tier T_{UCA} of the contact area CA is executed (step ST114). Thereby, the structure shown in FIG. 78 is formed.

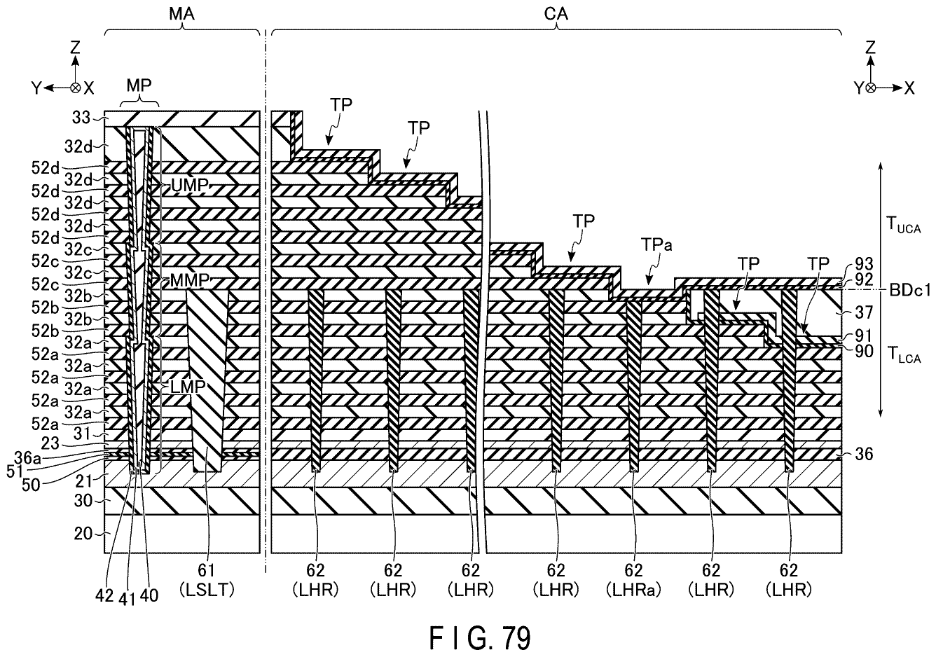

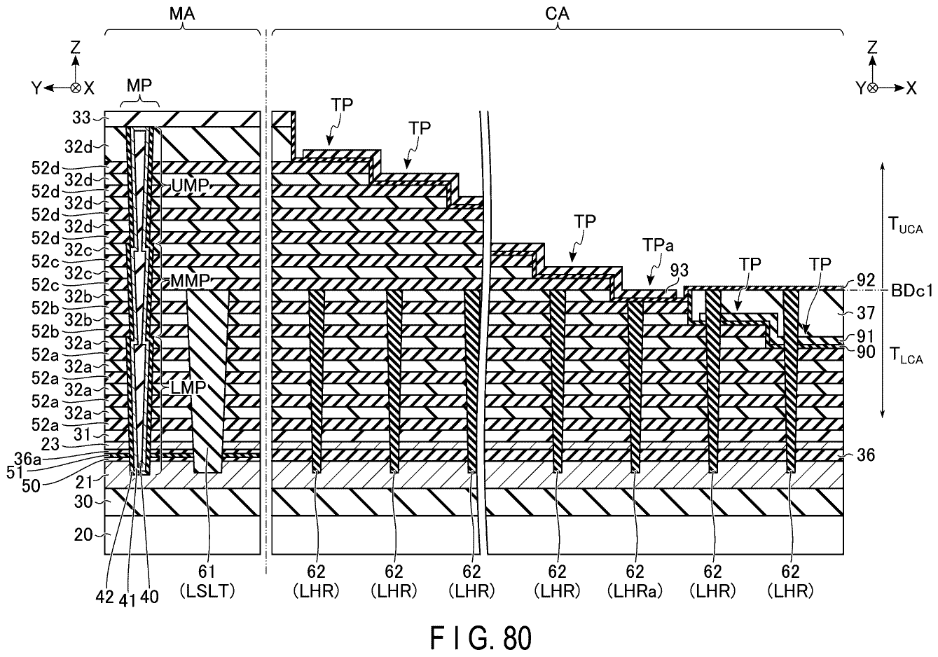

Next, a stopper film (insulating film 93) of the upper tier T_{UCA} of the contact area CA is formed (step ST602). Specifically, first, as shown in FIG. 79, the insulating films 92 and 93 are formed in this order. Then, as shown in FIG. 80, the insulating film 93 is processed so as to cover each of the plurality of terrace portions TP of the plurality of sacrificial members 52 (52c and 52d) of the upper tier T_{UCA} and the terrace portion TPa of the sacrificial member 52b. In other words, the insulating film 93 is removed except for the portion covering each of the plurality of terrace portions TP of the plurality of sacrificial members 52 (52c and 52d) of the upper tier T_{UCA} and the terrace portion TPa of the sacrificial member 52b. At this time, the insulating film 93 formed in the area where the member SLT is formed is also removed.

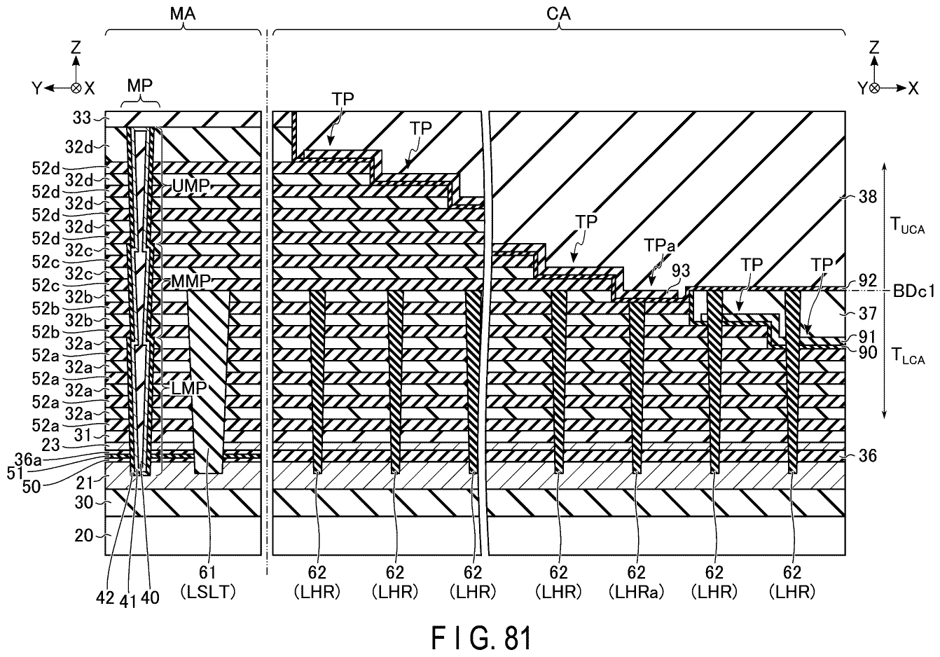

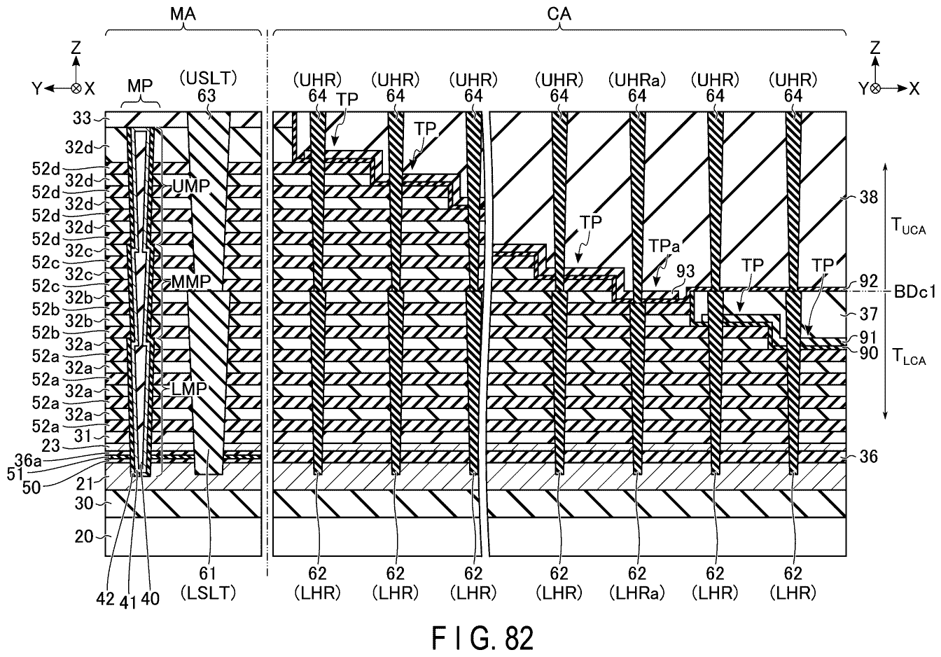

Next, embedding and flattening step differences of the upper tier T_{UCA} are executed similarly to the first embodiment (step ST116). That is, as shown in FIG. 81, the insulating layer 38 is formed so that the staircase structure formed in the upper tier T_{UCA} is embedded. Then, for example, a part of the insulating layer 38 is removed by CMP processing. As a result, the upper surface of the insulating layer 33 in the memory area MA and the upper surface of the insulating layer 38 in the contact area CA are aligned (flattened). Then, as shown in FIG. 82, UHR and USLT processing, and member embedding are executed similarly to the first embodiment (step ST117). For example, in the sixth embodiment, a plurality of holes corresponding to the plurality of upper support pillars UHR overlapping the plurality of terrace portions TP of the lower tier T_{LCA} further penetrate the insulating film 92. In addition, a hole corresponding to the upper support pillar UHRa, and a plurality of holes corresponding to the plurality of upper support pillars UHR overlapping the plurality of terrace portions TP of the upper tier T_{UCA} further penetrate the insulating films 92 and 93.

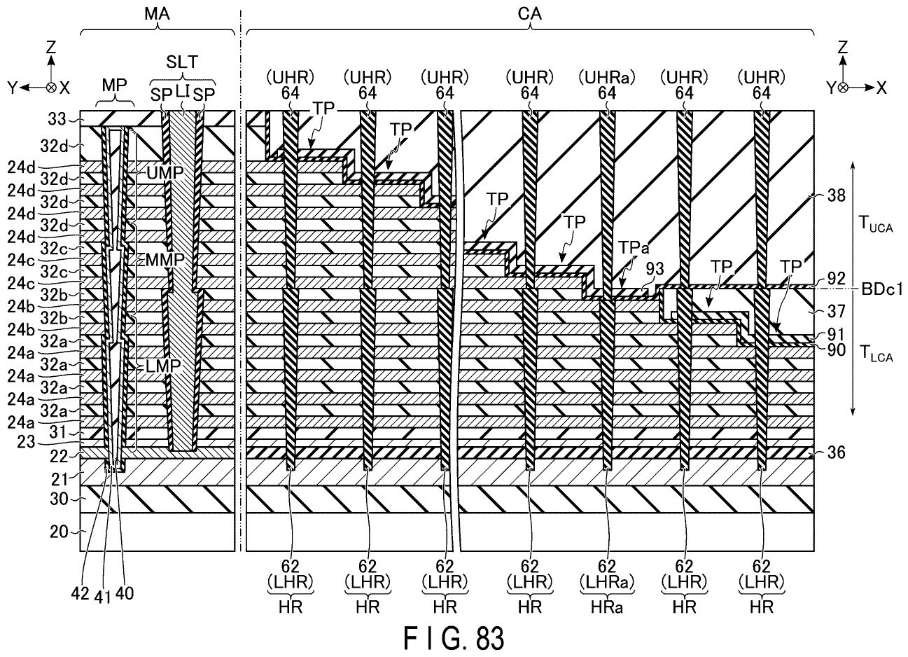

Next, as shown in FIG. 83, similarly to the first embodiment, the SL replacement and WL replacement are executed (step ST119). By the SL replacement, the insulating layers 50 and 36a and the sacrificial member 51 of the memory area MA are replaced with the semiconductor layer 22, and the semiconductor layer 22 and the semiconductor film 41 in the memory pillar MP are connected. The sacrificial members 52a, 52b, 52c, and 52d of the memory area MA and the contact area CA are replaced with the conductive layer 24 by the WL replacement. Thereafter, the spacer SP and the conductive member LI are formed in the slit corresponding to the member SLT.

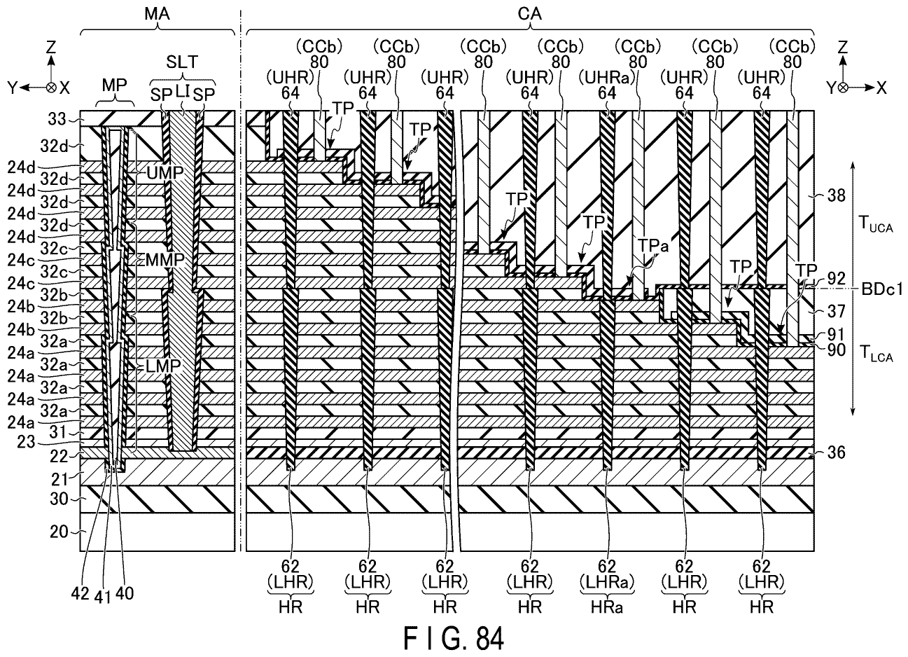

Next, as shown in FIG. 84, the plurality of contact plugs CCb is formed (step ST603). Specifically, first, a plurality of holes corresponding to the plurality of contact plugs CCb is formed, for example, so as to penetrate the insulating layer 38 and insulating film 92, or the insulating layers 37 and 38 and the insulating films 90 and 92, and reach the terrace portion TP or TPa of the conductive layer 24 with which the bottom thereof is associated. At this time, each of the insulating films 91 and 93 is used as a stopper film, and is used for adjusting the positions of the bottoms of the plurality of holes. Then, the conductive member 80 is embedded in the plurality of holes corresponding to the plurality of contact plugs CCb. As a result, each contact plug CCb is electrically connected to the terrace portion TP or TPa of the associated conductive layer 24, and the structure of the memory cell array 10F described with reference to FIG. 72 is completed.

Other processing of method of manufacturing the memory device 1 according to the sixth embodiment is similar to that of the first embodiment.

### <6-3> Advantageous Effects of the Sixth Embodiment

In a case where the staircase structure of the stacked wiring line in the contact area CA is provided in a plurality of layers and the contact plug CCb that does not penetrate the terrace portion TP of the conductive layer 24 is used, it is preferable to take measures against the penetration of the contact plug CCb into the conductive layer 24. For example, it is conceivable to form a stopper film so as to cover the terrace portion TP in each of the staircase portion of the lower tier T_{LCA} and the staircase portion of the upper tier T_{UCA}. However, the formation of the stopper film on the entire surface of the staircase portion of the lower tier T_{LCA} may interfere with the flattening process of the lower tier T_{LCA}.

Therefore, in the memory device 1 according to the sixth embodiment, the stopper film (insulating film 91) for the staircase structure of the lower tier T_{LCA} is formed within a range not interfering with the flattening process of the lower tier T_{LCA}. As a result, the stopper film for the staircase structure of the lower tier T_{LCA} which is missing (insufficient) is formed together with the stopper film (insulating film 93) for the staircase structure of the upper tier T_{UCA}. As a result, a desired stopper film can be formed for the terrace portions TP and TPa of all the conductive layers 24 in the contact area CA.

Furthermore, in the memory device 1 according to the sixth embodiment, the structure between the terrace portion TP of each conductive layer 24 included in the lower tier T_{LCA} and the insulating film 91 and the structure between the terrace portion TP of each conductive layer 24 included in the upper tier T_{UCA} and the insulating film 93 are substantially the same as the structure between the terrace portion TPa of the conductive layer 24 of at least one layer included in the lower tier T_{LCA} and the insulating film 93. Therefore, in the hole processing step used for forming the contact plug CCb (step ST603), process variation can be suppressed until the bottom portion of the hole is temporarily stopped by the stopper film (insulating films 91 and 93) and then reaches the terrace portion TP or TPa of each conductive layer 24.

As a result, in the memory device 1 according to the sixth embodiment, the penetration of the contact plug CCb into the conductive layer 24 is suppressed, and in the two conductive layers 24 adjacent to each other in the Z direction, the occurrence of the short circuit failure caused by the contact plug CCb can be suppressed. Therefore, the memory device 1 according to the sixth embodiment can suppress the manufacturing cost of the memory device 1.

### <6-4> Modification Example of the Sixth Embodiment

The memory device 1 according to the sixth embodiment can be variously modified.

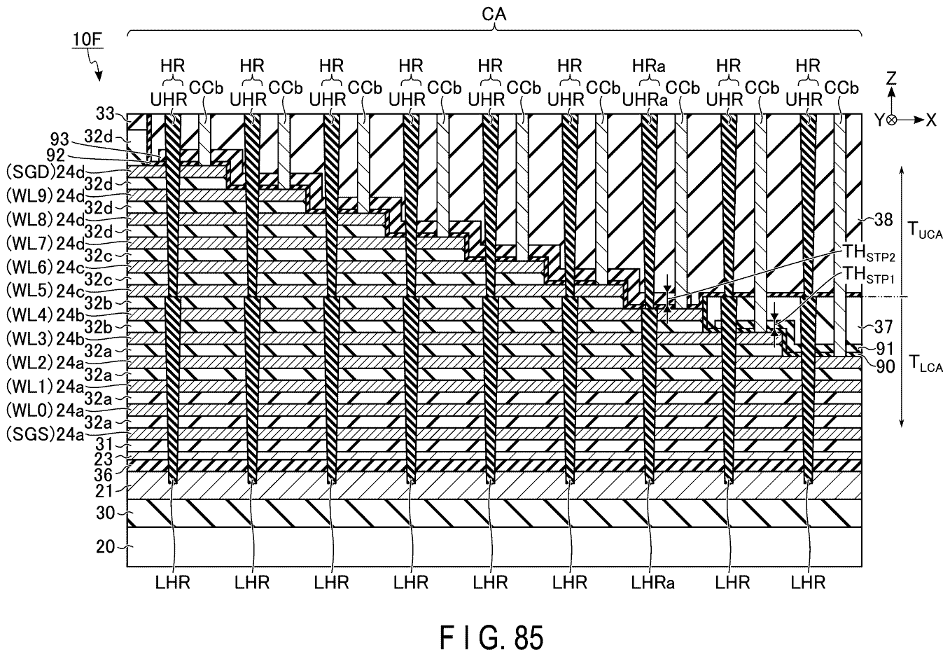

FIG. 85 is a cross-sectional view showing an example of a cross-sectional structure of the contact area CA of the memory cell array 10F included in the memory device 1 according to a first modification of the sixth embodiment. As shown in FIG. 85, in the first modification of the sixth embodiment, the film thickness TH_{STP1} of the insulating film 91 is different from the film thickness TH_{STP2} of the insulating film 93. FIG. 85 shows a case where the film thickness TH_{STP2} of the insulating film 93 is larger than the film thickness TH_{STP1} of the insulating film 91. In the processing steps of the plurality of holes for forming the plurality of contact plugs CCb (for example, step ST603 in FIG. 73), the bottoms of the plurality of holes reach the insulating film 93 located above the insulating film 91 first. Therefore, the function as the stopper film is preferably enhanced in the insulating film 93 rather than in the insulating film 91. That is, the insulating film 93 is preferably formed to be thicker than the insulating film 91. The configuration is not limited thereto, and the film thickness TH_{STP1} of the insulating film 91 may be formed to be thicker than the film thickness TH_{STP2} of the insulating film 93.

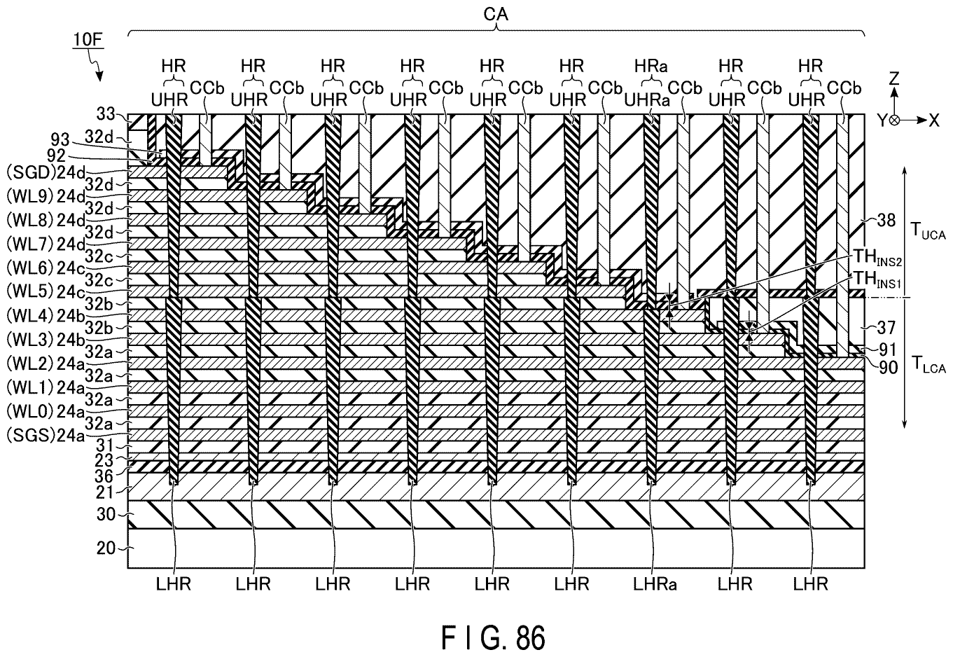

FIG. 86 is a cross-sectional view showing an example of a cross-sectional structure of the contact area CA of the memory cell array 10F included in the memory device 1 according to a second modification of the sixth embodiment. As shown in FIG. 86, in the second modification of the sixth embodiment, the film thickness TH_{INS1} of the insulating film 90 is different from the film thickness TH_{INS2} of the insulating film 92. FIG. 86 shows a case where the film thickness TH_{INS2} of the insulating film 92 is larger than the film thickness TH_{INS1} of the insulating film 90. The configuration is not limited thereto, and the film thickness TH_{INS1} of the insulating film 90 may be formed to be thicker than the film thickness TH_{INS2} of the insulating film 92. That is, spacing in the Z direction between the staircase shape formed by the plurality of terrace portions TP of the plurality of conductive layers 24 included in the lower tier T_{LCA} and the insulating film 91, and spacing in the Z direction between the staircase shape formed by the plurality of terrace portions TP of the plurality of conductive layers 24 included in the upper tier T_{UCA} and the insulating film 93 may be different.

In the sixth embodiment, the case where the terrace portion TP of the sacrificial member 52 in the second layer from the side closer to the boundary BDc1 in the lower tier T_{LCA} is formed in the processing of step ST105 has been exemplified, but the configuration is not limited thereto. In the sixth embodiment, the processing of step ST501 of the fifth embodiment may be executed instead of step ST105. That is, in the staircase shaping of the lower tier T_{LCA}, the staircase shaping may be executed so as not to form the terrace portion TP of the sacrificial member 52b of at least two layers from above. As a result, the sixth embodiment can realize the same effects as those of the fifth embodiment.

### <7> Modification Examples, Etc.

The memory device 1 described hereinabove can be variously modified.

In the above embodiment, each of the circuit configuration, the planar layout, and the cross-sectional structure of the memory device 1 can be changed as appropriate. A plurality of conductive layers 24 functioning as the select gate lines SGS or SGD may be provided. The numbers of wiring layers and contact plugs included in the memory device 1 can be changed according to circuit design as appropriate. The XY cross-sectional structures of the memory pillar MP, the support pillar HR, and the contact plug CC may be substantially circular or substantially elliptical. In the above embodiment, the case where the semiconductor film 41 of the memory pillar MP and the source line SL (semiconductor layer 22) are connected via the side surface of the memory pillar MP has been exemplified, but the configuration is not limited thereto. The semiconductor film 41 of the memory pillar MP and the source line SL (semiconductor layer 22) may be electrically connected via the bottom of the memory pillar MP. The memory device 1 may have a structure in which a chip provided with the memory cell array 10 and a chip provided with circuits and the like other than the memory cell array 10 are bonded to each other.

In the above embodiment, the case where each of the lower memory pillar LMP, the middle memory pillar MMP, and the upper memory pillar UMP has a normal tapered shape in which a diameter (XY cross-sectional area) of an upper end is larger than a diameter (XY cross-sectional area) of a lower end has been described, however, the shape of each sub-pillar of the memory pillar MP is not limited thereto. For example, each sub-pillar may have a straight shape provided with a substantially constant diameter, may have an inverse tapered shape in which the diameter (XY cross-sectional area) of the lower end is larger than the diameter (XY cross-sectional area) of the upper end, or may have a bowing shape in which the diameter (XY cross-sectional area) of the intermediate portion in the Z direction is maximized. Similarly to the memory pillar MP, each sub-member of the member SLT, each sub-pillar of the support pillar HR, the contact plug CC, and each sub-contact plug of the contact plug CC may also have a straight shape, an inverse tapered shape, or a bowing shape.

In the above embodiment, the case where the diameter D_{LMP2} (XY cross-sectional area) of the upper end of the lower memory pillar LMP is larger than the diameter D_{MMP1} (XY cross-sectional area) of the lower end of the middle memory pillar MMP has been described, however, the configuration is not limited thereto. The diameter D_{LMP2} (XY cross-sectional area) of the upper end of the lower memory pillar LMP may be equal to the diameter D_{MMP1} (XY cross-sectional area) of the lower end of the middle memory pillar MMP. In addition, the diameter D_{MMP2} (XY cross-sectional area) of the upper end of the middle memory pillar MMP may be equal to the diameter M_{UMP1} (XY cross-sectional area) of the lower end of the upper memory pillar UMP. Each sub-member of the member SLT, each sub-pillar of the support pillar HR, and each sub-contact plug of the contact plug CC may also have a relationship between layers similar to that of the memory pillar MP.

In the above embodiment, the case where a two-tier staircase structure is formed is exemplified, but each embodiment may also be applied to a staircase structure of three or more tiers. The memory pillar MP may have a structure of two tiers or four or more tiers. That is, the memory pillar MP may be processed by being divided twice or four times or more. The member SLT may have a structure of three or more tiers. That is, the member SLT may be processed by being divided three times or more. The support pillar HR may have a structure of three or more tiers. That is, the support pillar HR may be processed by being divided three times or more. The idea described in the above embodiment may be applied as long as the support pillar HR has a multi-tier structure and a multi-tier staircase structure is formed. For example, the number of tiers of the support pillar HR and the number of tiers of the memory pillar MP may be the same. In this case, an effect other than an advantage in which the number of tiers of the support pillars HR and the number of tiers of the memory pillars MP are different from each other can be obtained.

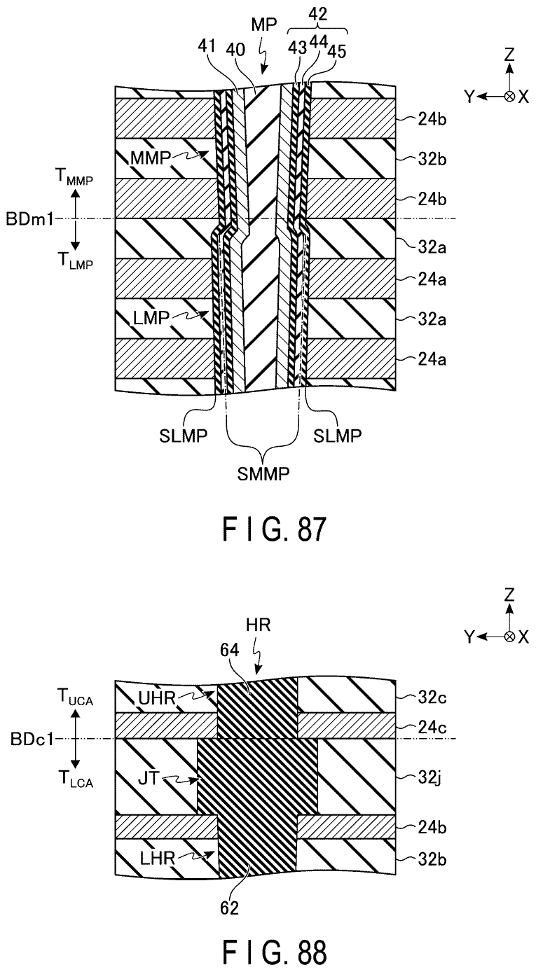

FIG. 87 is a cross-sectional view showing an example of a cross-sectional structure in the vicinity of a boundary of a layer stack in the memory device 1 according to the first embodiment. FIG. 87 depicts the vicinity of the boundary BDm1 between the lower tier T_{LMP} and the middle tier T_{MMP} extracted. As shown in FIG. 87, for example, in the YZ cross section, the upper end of the lower memory pillar LMP may have a rounded shape instead of an angular shape. In this case, it cannot be said that the XY cross-sectional area of the upper end of the lower memory pillar LMP is clearly larger than the XY cross-sectional area of the lower end of the middle memory pillar MMP. However, the shape of the side surface of the memory pillar MP is discontinuous in a boundary portion between the lower memory pillar LMP and the middle memory pillar MMP. Specifically, for example, in the YZ cross section, the side surface SLMP of the lower memory pillar LMP deviates from the extension line of the side surface SMMP of the middle memory pillar MMP indicated by the one-dot chain line in FIG. 87. The misalignment of the two side surfaces SLMP and SMMP may occur for any cross-section including the Z direction, such as an XZ cross-section. In the present specification, the boundary portion of the memory pillar MP in two tiers adjacent in the Z direction can be specified based on a discontinuous portion in the shape of the side surface of the memory pillar MP. The memory pillar MP may have a structure in which two or four or more sub-pillars each provided to extend along the Z direction are coupled. Also in such a case, the memory pillar MP can have a structure like that shown in FIG. 87 in a boundary portion between adjacent tiers. For the support pillar HR, the contact plug CC, and the member SLT, similarly to the memory pillar MP, boundary portions in two tiers adjacent in the Z direction can be specified.

FIG. 88 is a cross-sectional view showing an example of a cross-sectional structure in the vicinity of a boundary of a layer stack in the memory device 1 according to the third embodiment. FIG. 88 depicts the vicinity of the boundary BDc1 between the lower tier T_{LCA} and the upper tier T_{UCA} extracted. As shown in FIG. 88, for example, in the YZ cross section, the support pillar HR of the third embodiment may have a joint portion JT. The joint portion JT corresponds to an intersection portion between the support pillar HR (specifically, the upper portion of the lower support pillar LHR) and the insulating layer 32j. A diameter (XY cross-sectional area) of the support pillar HR at the joint portion JT is larger than a diameter (XY cross-sectional area) of the support pillar HR at a portion penetrating the conductive layer 24 or the insulating layer 32 adjacent to the joint portion JT in the support pillar HR. In other words, in the XY cross section, the cross-sectional area of the support pillar HR at the intersection portion with the insulating layer 32j is larger than each cross-sectional area of the support pillar HR at the respective portions passing through two conductive layers 24 adjacent in the Z direction via the insulating layer 32j among the plurality of conductive layers 24. By forming the joint portion JT, the difficulty of overlapping the lower support pillar LHR and the upper support pillar UHR can be reduced. A structure similar to the joint portion JT of the support pillar HR may also be formed in each of the lower member LSLT and the lower contact plug LCC.

In the present specification, “connection” refers to being electrically connected, and does not exclude, for example, being connected via another element. “Electrically coupled” may be via an insulator as long as it can operate in the same manner as electrically coupled. The “area” may be regarded as a configuration included by a substrate. For example, in a case where it is defined that a substrate 20 (semiconductor substrate) includes a memory area MA and a contact area CA, the memory area MA and the contact area CA are associated with different areas above the substrate 20. The “height” corresponds to, for example, the spacing in the Z direction between a configuration of a measurement object and the substrate 20. As a reference of “height”, a configuration other than the substrate 20 may be used. The “top (planar) view” corresponds to, for example, viewing the surface of the substrate 20 from the vertical direction of the substrate 20. The “diameter” indicates an inner diameter of the hole or an outer diameter of the pillar in a cross section (XY cross section) parallel to the surface of the substrate 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device, comprising:
a plurality of conductive layers provided in a first region and a second region arranged in a first direction, the conductive layers being provided apart from each other in a second direction intersecting the first direction in the first region and the second region, and arranged over a plurality of tiers including a first tier and a second tier;
a memory pillar provided to pass through the conductive layers in the second direction in the first region, in which a portion where the memory pillar and one of the conductive layers intersect each other functions as a memory cell;
a plurality of contact plugs respectively connected to the conductive layers in the second region; and
a plurality of pillars, each of the pillars being provided to pass through one or more conductive layers of the conductive layers in the second direction in the second region, each of the pillars including a first sub-pillar and a second sub-pillar, the first sub-pillar having a portion that passes through the first tier, and the second sub-pillar having a portion that passes through the second tier, wherein
the pillars include a first pillar and a second pillar,
a position of a boundary between the first sub-pillar and the second sub-pillar in the first pillar substantially coincides with a first boundary between the first tier and the second tier, and
a position of a boundary between the first sub-pillar and the second sub-pillar in the second pillar is separated from the first boundary.

2. The memory device according to claim 1, wherein
each of the conductive layers has a terrace portion that does not overlap a conductive layer arranged in an upper layer in a same tier among the conductive layers in the second region,
the conductive layers include a plurality of first conductive layers, a second conductive layer of at least one layer, and a plurality of third conductive layers, the first conductive layers being included in the first tier, the second conductive layer of at least one layer being included in the first tier and arranged closer to the first boundary than the first conductive layers, and the third conductive layers being included in the second tier,
the first pillar includes a portion that passes through the terrace portion of one layer of the third conductive layers, and
the second pillar has a portion that passes through the terrace portion of the second conductive layer of one layer.

3. The memory device according to claim 2, wherein
the conductive layers are arranged at substantially equal spacing in the second direction.

4. The memory device according to claim 2, wherein
a thickness of the terrace portion of each of the conductive layers in the second direction is thicker than a thickness of a portion included in the first region of each of the conductive layers in the second direction.

5. The memory device according to claim 2, wherein
the boundary between the first sub-pillar and the second sub-pillar in the second pillar is located between an upper surface and a lower surface of the terrace portion of the second conductive layer of one layer.

6. The memory device according to claim 2, wherein
each of the first pillar and the second pillar is an insulator containing silicon oxide.

7. The memory device according to claim 6, wherein
the first sub-pillar of the second pillar includes an insulating film provided on a side surface, and an insulating member embedded inside the insulating film and having a void.

8. The memory device according to claim 2, wherein
the pillars further include a third pillar, a position of a boundary between the first sub-pillar and the second sub-pillar in the third pillar being separated from the first boundary,
the conductive layers include second conductive layers of at least two layers,
the second pillar has the portion penetrating the terrace portion of one second conductive layer of the second conductive layers,
the third pillar has a portion penetrating the terrace portion of the other second conductive layer of the second conductive layers, and
in the second direction, the position of the boundary between the first sub-pillar and the second sub-pillar in the second pillar and the position of the boundary between the first sub-pillar and the second sub-pillar in the third pillar are different from each other.

9. The memory device according to claim 2, wherein
each of the contact plugs is provided to pass through one or more conductive layers of the conductive layers in the second direction in the second region, and is in contact with the terrace portion of the associated conductive layer via a side surface.

10. The memory device according to claim 9, further comprising:
a plurality of first insulating layers provided to separate each portion of the conductive layers passed by a contact plug of the contact plugs other than the terrace portion among the conductive layers from the contact plug.

11. The memory device according to claim 9, wherein
each of the contact plugs includes a first sub-contact plug and a second sub-contact plug, the first sub-contact plug having a portion that passes through the first tier, and the second sub-contact plug having a portion that passes through the second tier,
the contact plugs include a first contact plug and a second contact plug,
the first contact plug is connected to one of the first conductive layers, a position of a boundary between the first sub-contact plug and the second sub-contact plug in the first contact plug substantially coinciding with the first boundary, and
the second contact plug is connected to the second conductive layer of one layer, a position of a boundary between the first sub-contact plug and the second sub-contact plug in the second contact plug being separated from the first boundary.

12. The memory device according to claim 11, wherein
the boundary between the first sub-contact plug and the second sub-contact plug in the second contact plug is located between an upper surface and a lower surface of the terrace portion of the second conductive layer of one layer.

13. The memory device according to claim 2, wherein
spacing between the second conductive layer of one layer and a conductive layer adjacent to the second conductive layer of one layer in the second direction among the third conductive layers is wider than spacing between two conductive layers included in the first tier and adjacent to each other in the second direction among the conductive layers.

14. The memory device according to claim 13, further comprising:
a second insulating layer provided between the second conductive layer of one layer and the third conductive layers, wherein
in a cross section taken along a direction orthogonal to the second direction, a cross-sectional area of one of the pillars at an intersection portion with the second insulating layer is larger than each cross-sectional area of the one of the pillars at respective portions passing through two conductive layers adjacent to each other in the second direction via the second insulating layer among the conductive layers.

15. The memory device according to claim 1, wherein
a shape of a side surface of one of the pillars in a boundary portion between the first sub-pillar and the second sub-pillar is discontinuous.

16. A memory device, comprising:
a plurality of conductive layers provided in a first region and a second region arranged in a first direction, the conductive layers being provided apart from each other in a second direction intersecting the first direction in the first region and the second region, and arranged over a plurality of tiers including a first tier and a second tier, each of the conductive layers having a terrace portion that does not overlap a conductive layer arranged in an upper layer in a same tier among the conductive layers in the second region;
a memory pillar provided to pass through the conductive layers in the second direction in the first region in which a portion where the memory pillar and one of the conductive layers intersect each other functions as a memory cell;
a plurality of contact plugs respectively connected to a plurality of terrace portions included in the conductive layers in the second region; and
a first insulating film and a second insulating film whose each upper surface is provided to have a step difference along a stair shape formed by the terrace portions of the conductive layers, wherein
the conductive layers include a plurality of first conductive layers, a second conductive layer of at least one layer, and a plurality of third conductive layers, the first conductive layers being included in the first tier, the second conductive layer of at least one layer being included in the first tier and arranged closer to a boundary between the first tier and the second tier than the first conductive layers, and the third conductive layers being included in the second tier,
the first insulating film is provided along a first stair shape formed by a plurality of terrace portions of the first conductive layers and is separated from the second insulating film, and
the second insulating film is provided along a second stair shape formed by a plurality of terrace portions of the second conductive layer of at least one layer and the third conductive layers over both sides of the boundary between the first tier and the second tier.

17. The memory device according to claim 16, wherein
a film thickness of the second insulating film is larger than a film thickness of the first insulating film.

18. The memory device according to claim 16, further comprising:
an insulating layer provided to fill the step difference caused by the first stair shape and the second stair shape, the insulating layer having a portion through which the contact plugs pass, and the insulating layer including a different material from each of the first insulating film and the second insulating film.

19. The memory device according to claim 16, further comprising:
a plurality of pillars, each of the pillars being provided to pass through one or more conductive layers among the conductive layers in the second direction in the second region, each of the pillars including a first sub-pillar and a second sub-pillar, the first sub-pillar having a portion that passes through the first tier, and the second sub-pillar having a portion that passes through the second tier, wherein
the pillars include a first pillar and a second pillar,
a position of a boundary between the first sub-pillar and the second sub-pillar in the first pillar substantially coincides with the boundary between the first tier and the second tier, and
a position of a boundary between the first sub-pillar and the second sub-pillar in the second pillar is separated from the boundary between the first tier and the second tier.

20. The memory device according to claim 19, wherein
a shape of a side surface of one of the pillars in a boundary portion between the first sub-pillar and the second sub-pillar is discontinuous.
